(19) United States
(12) Patent Application Publication
(10) Pub. No.: US 2022/0081535 A1
(43) Pub. Date: Mar. 17, 2022

(54) NEAR-INFRARED ABSORBING COMPOSITION, METHOD FOR PRODUCING DISPERSION LIQUID, FILM, OPTICAL FILTER, METHOD FOR FORMING PATTERN, LAMINATE, SOLID-STATE IMAGING ELEMENT, IMAGE DISPLAY DEVICE, AND INFRARED SENSOR

(71) Applicant: FUJIFILM Corporation, Tokyo (JP)

(72) Inventors: Takuya TSURUTA, Haibara-gun (JP); Tokihiko MATSUMURA, Haibara-gun (JP); Kyohei ARAYAMA, Haibara-gun (JP)

(73) Assignee: FUJIFILM Corporation, Tokyo (JP)

(21) Appl. No.: 17/183,016

(22) Filed: Feb. 23, 2021

Related U.S. Application Data
(63) Continuation of application No. PCT/JP2019/035551, filed on Sep. 10, 2019.

(30) Foreign Application Priority Data
Sep. 14, 2018 (JP) 2018-172357

(51) Int. Cl. C08K 5/3492; H04N 5/33; H04N 5/335; C09D 179/02; C09D 153/00; C09D 165/00; C08K 5/55; G02B 5/20

(52) U.S. Cl. CPC C08K 5/34926; H04N 5/33; H04N 5/335; G02B 5/208; C09D 153/00; C09D 165/00; C08K 5/55; C09D 179/02

(57) ABSTRACT

Provided are a near-infrared absorbing composition including a near-infrared absorbing pigment having an oxocarbon skeleton, a coloring agent derivative, a resin, and a solvent, in which the coloring agent derivative is a compound having a cation and an anion in a molecule, and the near-infrared absorbing composition contains 0.5 to 25 parts by mass of the coloring agent derivative with respect to 100 parts by mass of the near-infrared absorbing pigment; a method for producing a dispersion liquid; a film; an optical filter; a method for forming a pattern; a laminate; a solid-state imaging element; an image display device; and an infrared sensor.

### CROSS-REFERENCE TO RELATED APPLICATIONS

This application is a Continuation of PCT International Application No. PCT/JP2019/035551 filed on Sep. 10, 2019, which claims priority under 35 U.S.C. § 119(a) to Japanese Patent Application No. 2018-172357 filed on Sep. 14, 2018. Each of the above application(s) is hereby expressly incorporated by reference, in its entirety, into the present application.

### BACKGROUND OF THE INVENTION

### 1. Field of the Invention

The present invention relates to a near-infrared absorbing composition including a near-infrared absorbing pigment having an oxocarbon skeleton. The present invention also relates to a method for producing a dispersion liquid, a film, an optical filter, a method for forming a pattern, a laminate, a solid-state imaging element, an image display device, and an infrared sensor.

### 2. Description of the Related Art

A charge coupled device (CCD) or a complementary metal-oxide semiconductor (CMOS), which are solid-state imaging elements of color images, has been used in video cameras, digital still cameras, mobile phones with camera function, and the like. Since silicon photodiodes having sensitivity to infrared light are used in a light receiving portion of these solid-state imaging elements, it is necessary to correct visual sensitivity and a near-infrared cut filter is often used for that purpose.

For example, WO2018/043185A, JP2017-198816A, JP2018-058980A, and JP2018-087939A disclose manufacturing a near-infrared cut filter and the like using a near-infrared absorbing composition including a squarylium compound.

### SUMMARY OF THE INVENTION

Generally, near-infrared absorbing pigments have a wide π-conjugated plane. Therefore, the near-infrared absorbing pigments tend to aggregate in the near-infrared absorbing composition, and in the near-infrared absorbing composition including the near-infrared absorbing pigments, further improvement in dispersion stability is desired.

In addition, in a film formed by using the near-infrared absorbing composition, it is desired to have few defects and excellent heat resistance and light resistance.

Therefore, an object of the present invention is to provide a near-infrared absorbing composition with which a film having good dispersion stability, few defects, and excellent heat resistance and light resistance can be formed. Another object of the present invention is to provide a method for producing a dispersion liquid, a film, an optical filter, a method for forming a pattern, a laminate, a solid-state imaging element, an image display device, and an infrared sensor.

The present invention provides the following.

<1> A near-infrared absorbing composition comprising:

a near-infrared absorbing pigment having an oxocarbon skeleton;

a coloring agent derivative;

a resin; and

a solvent,

in which the coloring agent derivative is a compound having a cation and an anion in a molecule, and

the near-infrared absorbing composition contains 0.5 to 25 parts by mass of the coloring agent derivative with respect to 100 parts by mass of the near-infrared absorbing pigment.

<2> The near-infrared absorbing composition according to <1>,

in which the near-infrared absorbing pigment has a maximum absorption wavelength in a range of 700 to 1200 nm.

<3> The near-infrared absorbing composition according to <1> or <2>,

in which an absolute value of a difference between an amount of the near-infrared absorbing pigment dissolved in 100 g of propylene glycol methyl ether acetate at 25° C. and an amount of the coloring agent derivative dissolved in 100 g of propylene glycol methyl ether acetate at 25° C. is 10 g or less.

<4> The near-infrared absorbing composition according to any one of <1> to <3>,

in which the near-infrared absorbing pigment is at least one selected from a compound represented by Formula (SQ1) or a compound represented by Formula (CR1),

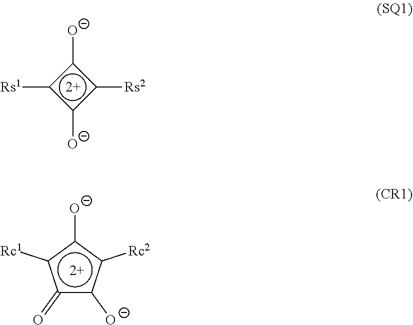

in Formula (SQ1), Rs¹ and Rs² each independently represent an organic group, and

in Formula (CR1), Rc¹ and Rc² each independently represent an organic group.

<5> The near-infrared absorbing composition according to <4>,

in which Rs¹ and Rs² in Formula (SQ1) each independently represent an aryl group, a heteroaryl group, or a group represented by Formula (R1), and

Rc¹ and Rc² in Formula (CR1) each independently represent an aryl group, a heteroaryl group, or a group represented by Formula (R1),

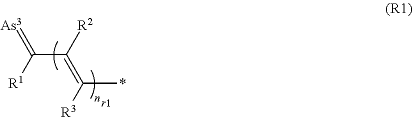

in Formula (R1), R¹ to R³ each independently represent a hydrogen atom or a substituent, As³ represents a heteroaryl group, nᵣ₁ represents an integer of 0 or more, R¹ and R² may be bonded to each other to form a ring, R¹ and As³ may be bonded to each other to form a ring, R² and R³ may be bonded to each other to form a ring, in which in a case where nᵣ₁ is 2 or more, a plurality of R²'s and R³'s each may be the same or different from each other, and * represents a bonding hand.

<6> The near-infrared absorbing composition according to <4>,

in which at least one of Rs¹ or Rs² in Formula (SQ1) is a group represented by Formula (1), and

at least one of Rc¹ or Rc² in Formula (CR1) is a group represented by Formula (1),

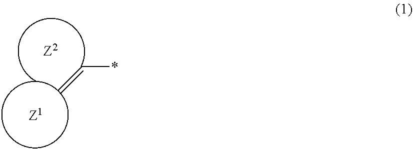 [SMILES: *C=C]

in Formula (1), a ring Z¹ represents an aromatic heterocyclic ring or a fused ring including an aromatic heterocyclic ring, which may have one or a plurality of substituents,

a ring Z² represents a 4-membered to 9-membered hydrocarbon ring or heterocyclic ring, which may have one or a plurality of substituents,

in a case where the ring Z¹ and the ring Z² have a plurality of substituents, the plurality of substituents may be the same or different from each other, and

* represents a bonding hand.

<7> The near-infrared absorbing composition according to <4>,

in which at least one of Rs¹ or Rs² in Formula (SQ1) is a group represented by Formula (10), and

at least one of Rc¹ or Rc² in Formula (CR1) is a group represented by Formula (10),

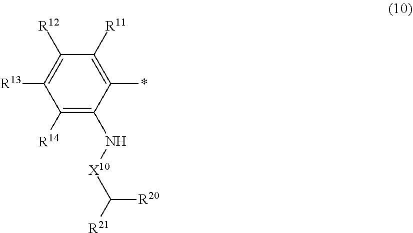

in Formula (10), R¹¹ to R¹⁴ each independently represent a hydrogen atom or a substituent, and two adjacent groups of R¹¹ to R¹⁴ may be bonded to each other to form a ring,

R²⁰ represents an aryl group or a heteroaryl group,

R²¹ represents a substituent, and

X¹⁰ represents CO or SO₂.

<8> The near-infrared absorbing composition according to <4>,

in which at least one of Rs¹ or Rs² of Formula (SQ1) represents a group represented by Formula (20), and

at least one of Rc¹ or Rc² of Formula (CR1) represents a group represented by Formula (20),

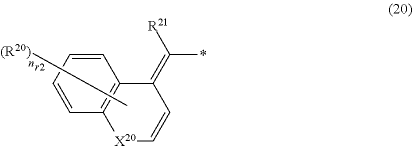

in Formula (20), R²⁰ and R²¹ each independently represent a hydrogen atom or a substituent, and R²⁰ and R²¹ may be bonded to each other to form a ring,

X²⁰ represents an oxygen atom, a sulfur atom, NR²², a selenium atom, or a tellurium atom, in which R²² represents a hydrogen atom or a substituent, and in a case where X²⁰ is NR²², R²² and R²⁰ may be bonded to each other to form a ring,

nᵣ₂ represents an integer of 0 to 5,

in a case where nᵣ₂ is 2 or more, a plurality of R²⁰'s may be the same or different from each other, and two R²⁰'s of the plurality of R²⁰'s may be bonded to each other to form a ring, and

* represents a bonding hand.

<9> The near-infrared absorbing composition according to <4>,

in which at least one of Rs¹ or Rs² in Formula (SQ1) represents a group represented by Formula (30) or Formula (40), and

at least one of Rc¹ or Rc² in Formula (CR1) represents a group represented by Formula (30) or Formula (40),

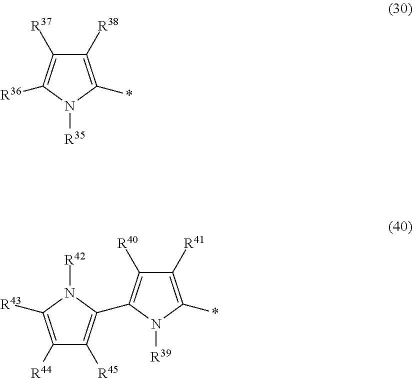

in Formula (30), R³⁵ to R³⁸ each independently represent a hydrogen atom or a substituent, R³⁵ and R³⁶, R³⁶ and R³⁷, or R³⁷ and R³⁸ may be bonded to each other to form a ring, and * represents a bonding hand; and

in Formula (40), R³⁹ to R⁴⁵ each independently represent a hydrogen atom or a substituent, R³⁹ and R⁴⁵, R⁴⁰ and R⁴¹, R⁴⁰ and R⁴², R⁴² and R⁴³, R⁴³ and R⁴⁴, or R⁴⁴ and R⁴⁵ may be bonded to each other to form a ring, and * represents a bonding hand.

<10> The near-infrared absorbing composition according to <1>,

in which the near-infrared absorbing pigment is a compound represented by Formula (SQ2) or Formula (SQ3),

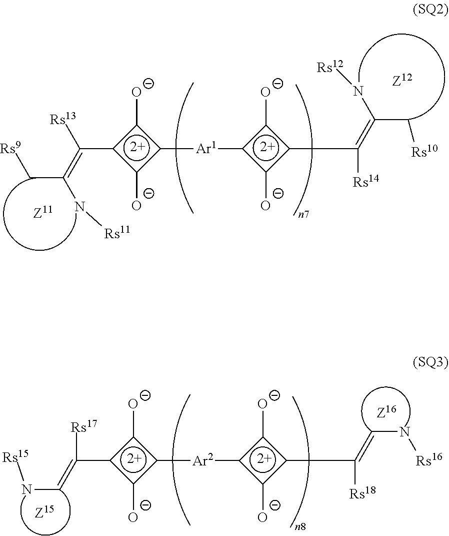

in Formula (SQ2), a ring Z¹¹ and a ring Z¹² each independently represent a polycyclic aromatic ring having a nitrogen-containing heterocyclic ring, which may have one or a plurality of substituents,

in a case where the ring Z¹¹ and the ring Z¹² have a plurality of substituents, the plurality of substituents may be the same or different from each other,

Rs⁹ to Rs¹⁴ each independently represent a hydrogen atom or a substituent,

Ar¹ represents a group represented by any one of Formulae (Ar-1) to (Ar-4),

n⁷ represents an integer of 0 to 2, and

Rs⁹ and Rs¹³, or Rs¹⁰ and Rs¹⁴ may be bonded to each other to form a ring; and

in Formula (SQ3), a ring Z¹⁵ and a ring Z¹⁶ each independently represent a polycyclic aromatic ring having a nitrogen-containing heterocyclic ring, which may have one or a plurality of substituents,

in a case where the ring Z¹⁵ and the ring Z¹⁶ have a plurality of substituents, the plurality of substituents may be the same or different from each other,

Rs¹⁵ to Rs¹⁸ each independently represent a hydrogen atom or a substituent,

Ar² represents a group represented by any one of Formulae (Ar-1) to (Ar-4),

n8 represents an integer of 0 to 2, and

Rs¹⁵ and Rs¹⁷, or Rs¹⁶ and Rs¹⁸ may be bonded to each other to form a ring,

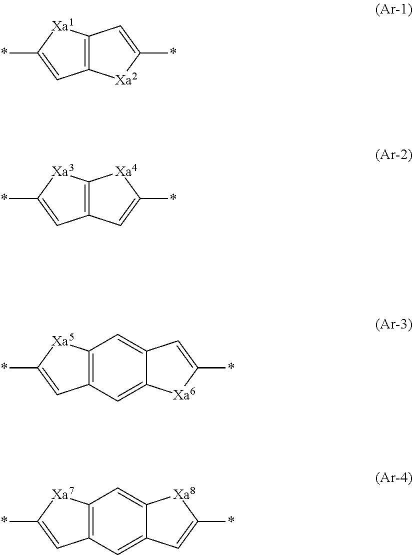

in the formulae, Xa¹ to Xa⁸ each independently represent a sulfur atom, an oxygen atom, or NRx^{a}, in which Rx^{a} represents a hydrogen atom or a substituent, and * represents a bonding hand.

<11> The near-infrared absorbing composition according to <1>,

in which the near-infrared absorbing pigment is a compound represented by Formula (SQ10),

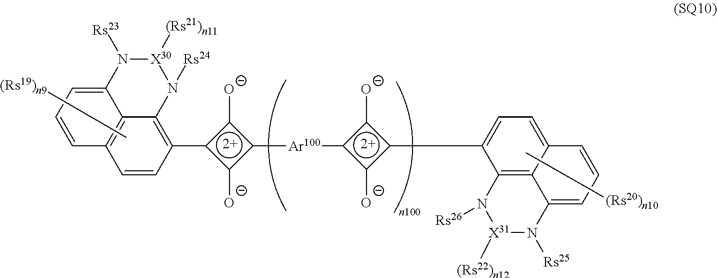

in Formula (SQ10), Rs¹⁹ and Rs²⁰ each independently represent a substituent,

Rs²¹ to Rs²⁶ each independently represent a hydrogen atom or a substituent,

X³⁰ and X³¹ each independently represent a carbon atom, a boron atom, or C(═O),

n11 is 2 in a case where X³⁰ is a carbon atom, n11 is 1 in a case where X³⁰ is a boron atom, and n11 is 0 in a case where X³⁰ is C(═O),

n12 is 2 in a case where X³¹ is a carbon atom, n12 is 1 in a case where X³¹ is a boron atom, and n12 is 0 in a case where X³¹ is C(═O),

n9 and n10 each independently represent an integer of 0 to 5,

in a case where n9 is 2 or more, a plurality of Rs¹⁹'s may be the same or different from each other, and two Rs¹⁹'s of the plurality of Rs¹⁹'s may be bonded to each other to form a ring,

in a case where n10 is 2 or more, a plurality of Rs²⁰'s may be the same or different from each other, and two Rs²⁰'s of the plurality of Rs²⁰'s may be bonded to each other to form a ring,

in a case where n11 is 2, two Rs²¹'s may be the same or different from each other and may be bonded to each other to form a ring,

in a case where n12 is 2, two Rs²²'s may be the same or different from each other and may be bonded to each other to form a ring,

Ar¹⁰⁰ represents a group represented by any one of Formulae (Ar-1) to (Ar-4), and

n100 represents an integer of 0 to 2,

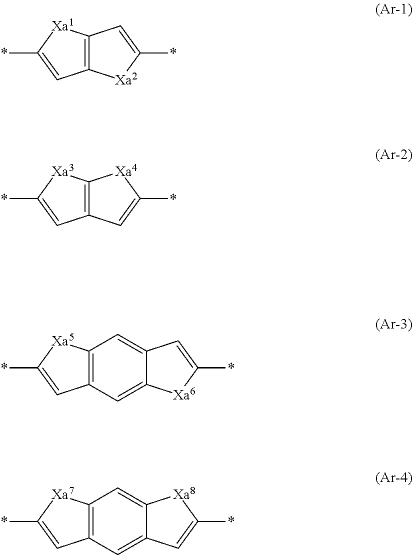

in the formulae, Xa¹ to Xa⁸ each independently represent a sulfur atom, an oxygen atom, or NRx^{a}, in which Rx^{a} represents a hydrogen atom or a substituent, and * represents a bonding hand.

<12> The near-infrared absorbing composition according to <1>,

in which the near-infrared absorbing pigment is a compound represented by Formula (SQ20),

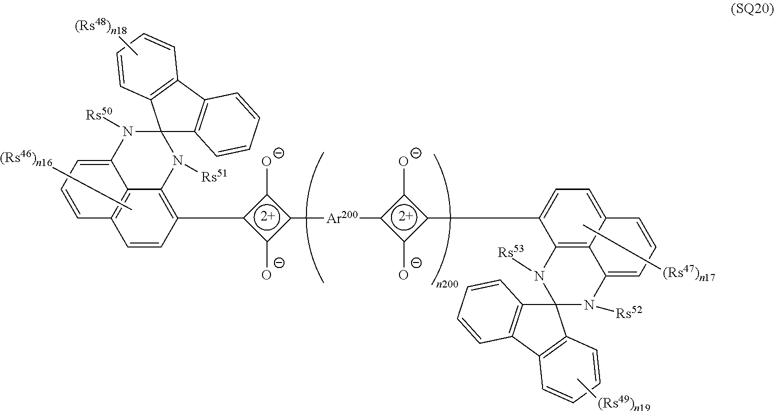

in Formula (SQ20), Rs⁴⁶ and Rs⁴⁹ each independently represent a substituent,

Rs⁵⁰ to Rs⁵³ each independently represent a hydrogen atom or a substituent,

n16 and n17 each independently represent an integer of 0 to 5,

n18 and n19 each independently represent an integer of 0 to 6,

in a case where n16 is 2 or more, a plurality of Rs⁴⁶'s may be the same or different from each other, and two Rs⁴⁶'s of the plurality of Rs⁴⁶'s may be bonded to each other to form a ring,

in a case where n17 is 2 or more, a plurality of Rs⁴⁷'s may be the same or different from each other, and two Rs⁴⁷'s of the plurality of Rs⁴⁷'s may be bonded to each other to form a ring,

in a case where n18 is 2 or more, a plurality of Rs⁴⁸'s may be the same or different from each other, and two Rs⁴⁸'s of the plurality of Rs⁴⁸'s may be bonded to each other to form a ring,

in a case where n19 is 2 or more, a plurality of Rs⁴⁹'s may be the same or different from each other, and two Rs⁴⁹'s of the plurality of Rs⁴⁹'s may be bonded to each other to form a ring,

Ar²⁰⁰ represents a group represented by any one of Formulae (Ar-1) to (Ar-4), and

n200 represents an integer of 0 to 2,

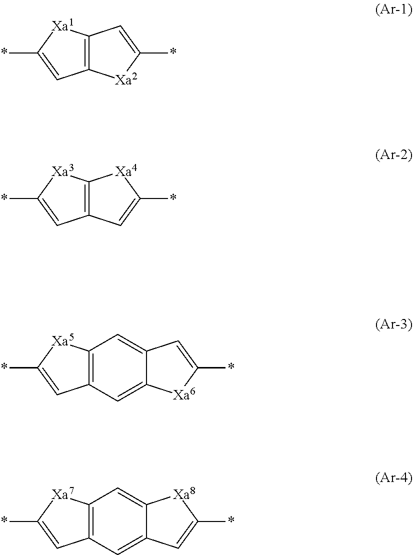

in the formulae, Xa¹ to Xa⁸ each independently represent a sulfur atom, an oxygen atom, or NRx^{a}, in which Rx^{a} represents a hydrogen atom or a substituent, and * represents a bonding hand.

<13> The near-infrared absorbing composition according to <1>,

in which the near-infrared absorbing pigment is a compound represented by Formula (SQ30),

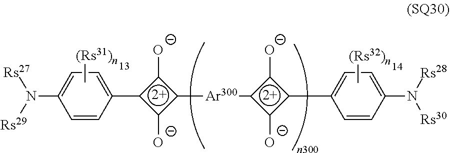

in Formula (SQ30), Rs²⁷ to Rs³⁰ each independently represent a hydrogen atom or a substituent,

Rs³¹ and Rs³² each independently represent a substituent or a group represented by Formula (100),

Rs²⁷ and Rs²⁹, Rs²⁷ and Rs³¹, Rs²⁹ and Rs³¹, Rs²⁸ and Rs³⁰, Rs²⁸ and Rs³², or Rs³⁰ and Rs³² may be bonded to each other to form a ring,

Rs³¹ and Rs³² may be linked through a single bond or a linking group,

n13 and n14 each independently represent an integer of 0 to 4,

in a case where n13 is 2 or more, a plurality of Rs³¹, s may be the same or different from each other, and two Rs³¹'s of the plurality of Rs³¹'s may be bonded to each other to form a ring,

in a case where n14 is 2 or more, a plurality of Rs³²'s may be the same or different from each other, and two Rs³²'s of the plurality of Rs³²'s may be bonded to each other to form a ring,

Ar³⁰⁰ represents a group represented by any one of Formulae (Ar-1) to (Ar-4), and

n300 represents an integer of 0 to 2;

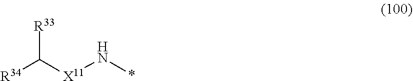

in Formula (100), R³³ represents an aryl group or a heteroaryl group, R³⁴ represents a hydrogen atom or a substituent, and X¹¹ represents CO or SO₂; and

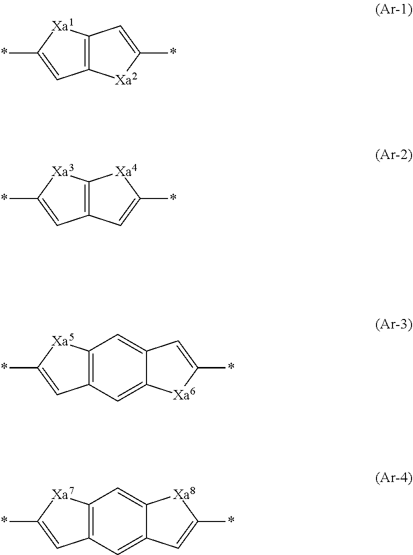

in the formulae, Xa¹ to Xa⁸ each independently represent a sulfur atom, an oxygen atom, or NRx^{a}, in which Rx^{a} represents a hydrogen atom or a substituent, and * represents a bonding hand.

<14> The near-infrared absorbing composition according to <11>,

in which the compound represented by Formula (SQ30) is a compound represented by Formula (SQ30-1),

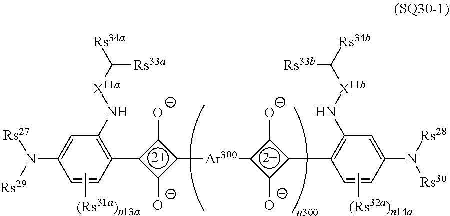

in Formula (SQ30-1), Rs²⁷ to Rs³⁰ each independently represent a hydrogen atom or a substituent,

Rs^{31a} and Rs^{32a} each independently represent a substituent,

Rs^{33a} and Rs^{33b} each independently represent an aryl group or a heteroaryl group,

Rs^{34a} and Rs^{34b} each independently represent a hydrogen atom or a substituent,

Rs²⁷ and Rs²⁹, Rs²⁷ and Rs^{31a}, Rs²⁹ and Rs^{31a}, Rs²⁷ and Rs^{34a}, Rs²⁹ and Rs^{34a}, Rs²⁸ and Rs³⁰, Rs²⁸ and Rs^{32a}, Rs³⁰ and Rs^{32a}, Rs²⁸ and Rs^{34b}, or Rs³⁰ and Rs^{34b} may be bonded to each other to form a ring,

Rs^{34a} and Rs^{34b} may be linked through a single bond or a linking group,

X^{11a} and X^{11b} each independently represent CO or SO₂,

n13a and n14a each independently represent an integer of 0 to 3,

in a case where n13a is 2 or more, a plurality of Rs^{31a}'s may be the same or different from each other, and two Rs^{31a}'s of the plurality of Rs^{31a}'s may be bonded to each other to form a ring,

in a case where n14a is 2 or more, a plurality of Rs^{32a}'s may be the same or different from each other, and two Rs^{32a}'s of the plurality of Rs^{32a}'s may be bonded to each other to form a ring,

Ar³⁰⁰ represents a group represented by any one of Formulae (Ar-1) to (Ar-4), and

n300 represents an integer of 0 to 2.

<15> The near-infrared absorbing composition according to any one of <1> to <14>,

in which the coloring agent derivative is a compound having at least one group selected from an acid group, a basic group, and a hydrogen-bonding group.

<16> The near-infrared absorbing composition according to any one of <1> to <15>,

in which the coloring agent derivative has at least one group selected from a sulfo group, a carboxyl group, a phosphoric acid group, a boronic acid group, a sulfonimide group, a sulfonamide group, an amino group, a pyridinyl group, salts of these groups, and a desalted structure of these salts.

<17> The near-infrared absorbing composition according to any one of <1> to <16>,

in which the near-infrared absorbing pigment and the coloring agent derivative have the same π-conjugated plane.

<18> The near-infrared absorbing composition according to any one of <1> to <17>,

in which the near-infrared absorbing pigment and the coloring agent derivative respectively have a π-conjugated plane including a partial structure represented by Formula (SQ-a), or respectively have a π-conjugated plane including a partial structure represented by Formula (CR-a),

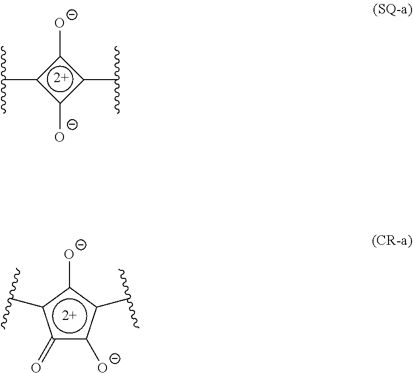

in the formulae, a wavy line represents a bonding hand.

<19> The near-infrared absorbing composition according to any one of <1> to <18>, further comprising:

a polymerizable compound; and

a photopolymerization initiator.

<20> The near-infrared absorbing composition according to any one of <1> to <19>,

in which the resin includes a resin having an acid group.

<21> A method for producing a dispersion liquid, comprising:

a step of dispersing a near-infrared absorbing pigment having an oxocarbon skeleton in a presence of a coloring agent derivative, a resin, and a solvent,

in which the coloring agent derivative is a compound having a cation and an anion in a molecule, and

0.5 to 25 parts by mass of the coloring agent derivative is used with respect to 100 parts by mass of the near-infrared absorbing pigment.

<22> A film formed by using the near-infrared absorbing composition according to any one of <1> to <20>.

<23> An optical filter comprising:

the film according to <22>.

<24> The optical filter according to <23>,

in which the optical filter is a near-infrared cut filter or a near-infrared transmitting filter.

<25> A method for forming a pattern, comprising:

a step of forming a composition layer on a support using the near-infrared absorbing composition according to any one of <1> to <20>; and

a step of forming a pattern on the composition layer by a photolithography method or a dry etching method.

<26> A laminate comprising:

the film according to <22>; and

a color filter including a chromatic colorant.

<27> A solid-state imaging element comprising:

the film according to <22>.

<28> An image display device comprising:

the film according to <22>.

<29> An infrared sensor comprising:

the film according to <22>.

According to the present invention, it is possible to provide a near-infrared absorbing composition with which a film having good dispersion stability, few defects, and excellent heat resistance and light resistance can be formed. In addition, it is possible to provide a method for producing a dispersion liquid, a film, an optical filter, a method for forming a pattern, a laminate, a solid-state imaging element, an image display device, and an infrared sensor.

### BRIEF DESCRIPTION OF THE DRAWINGS

FIG. 1 is a schematic diagram indicating an embodiment of an infrared sensor.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, a weight-average molecular weight and a number-average molecular weight are defined as values in terms of polystyrene measured by gel permeation chromatography (GPC).

In the present specification, the weight-average molecular weight (Mw) and the number-average molecular weight (Mn) can be obtained, for example, by using HLC-8220 GPC (manufactured by Tosoh Corporation), using, as a column, a column connecting TOSOH TSKgel Super HZM-H, TOSOH TSKgel Super HZ4000, and TOSOH TSKgel Super HZ2000, and using tetrahydrofuran as a developing solvent.

In the present specification, in a chemical formula, Me represents a methyl group, Et represents an ethyl group, Bu represents a butyl group, and Ph represents a phenyl group.

In the present specification, near infrared light denotes light (electromagnetic wave) having a wavelength in a range of 700 to 2500 nm.

In the present specification, a total solid content denotes the total mass of all the components of the composition excluding a solvent.

In the present specification, the term “step” denotes not only an individual step but also a step which is not clearly distinguishable from another step as long as an effect expected from the step can be achieved.

<Near-Infrared Absorbing Composition>

A near-infrared absorbing composition according to an embodiment of the present invention includes a near-infrared absorbing pigment having an oxocarbon skeleton, a coloring agent derivative, a resin, and a solvent, in which the coloring agent derivative is a compound having a cation and an anion in a molecule, and the near-infrared absorbing composition contains 0.5 to 25 parts by mass of the coloring agent derivative with respect to 100 parts by mass of the near-infrared absorbing pigment.

Since the near-infrared absorbing composition according to the embodiment of the present invention includes the near-infrared absorbing pigment having an oxocarbon skeleton, and the compound, as the coloring agent derivative, having a cation and an anion in a molecule, dispersion stability of the near-infrared absorbing pigment in the composition is good. Although the detailed reason is not clear, but it is assumed that, by using in combination a near-infrared absorbing pigment having an oxocarbon skeleton, and a compound, as a coloring agent derivative, having a cation and an anion in a molecule, the oxocarbon skeleton of the near-infrared absorbing pigment and the coloring agent derivative easily interact with each other, and as a result, the dispersion stability of the near-infrared absorbing pigment in the composition can be improved.

In addition, since the near-infrared absorbing composition according to the embodiment of the present invention contains 0.5 to 25 parts by mass of the coloring agent derivative with respect to 100 parts by mass of the near-infrared absorbing pigment, it is assumed that it is easy to form associations between the near-infrared absorbing pigments while suppressing occurrence of cross-linking of the resins through the coloring agent derivative during film formation, and as a result, it is possible to form a film which has excellent light resistance and heat resistance, and in which defects are suppressed.

In the near-infrared absorbing composition according to the embodiment of the present invention, the absolute value of the difference between an amount of the near-infrared absorbing pigment dissolved in 100 g of propylene glycol methyl ether acetate at 25° C. and an amount of the coloring agent derivative dissolved in 100 g of propylene glycol methyl ether acetate at 25° C. is preferably 10 g or less, more preferably 7.5 g or less, and still more preferably 5 g or less. The lower limit is preferably 1 mg or more and more preferably 5 mg or more. In a case where the absolute value of the difference in the amount of dissolution is within the above-described range, the interaction between the near-infrared absorbing pigment and the coloring agent derivative in the near-infrared absorbing composition can be sufficiently obtained, and the dispersion stability of the near-infrared absorbing pigment in the composition can be further improved.

In the near-infrared absorbing composition according to the embodiment of the present invention, it is also preferable that the near-infrared absorbing pigment and the coloring agent derivative have π-conjugated planes having the same structure. According to this aspect, the interaction between the near-infrared absorbing pigment and the coloring agent derivative in the near-infrared absorbing composition can be sufficiently obtained, and the dispersion stability of the near-infrared absorbing pigment in the composition can be further improved. In addition, in a case where the near-infrared absorbing pigment and the coloring agent derivative have two or more π-conjugated planes, it is preferable that the widest π-conjugated planes have the same structure. Here, the case where the near-infrared absorbing pigment and the coloring agent derivative have π-conjugated planes having the same structure means that, in a case where a substituent is bonded to the π-conjugated plane included in both, a structure of a site excluding the substituent is the same.

In addition, the difference between the number of n electrons included in the π-conjugated plane of the near-infrared absorbing pigment and the number of π electrons included in the π-conjugated plane of the coloring agent derivative is preferably 6 or less, more preferably 4 or less, and still more preferably 2 or less.

In the near-infrared absorbing composition according to the embodiment of the present invention, it is also preferable that the near-infrared absorbing pigment and the coloring agent derivative respectively have a π-conjugated plane including a partial structure represented by Formula (SQ-a), or respectively have a π-conjugated plane including a partial structure represented by Formula (CR-a). According to this aspect, the interaction between the near-infrared absorbing pigment and the coloring agent derivative in the near-infrared absorbing composition can be sufficiently obtained, and the dispersion stability of the near-infrared absorbing pigment in the composition can be further improved.

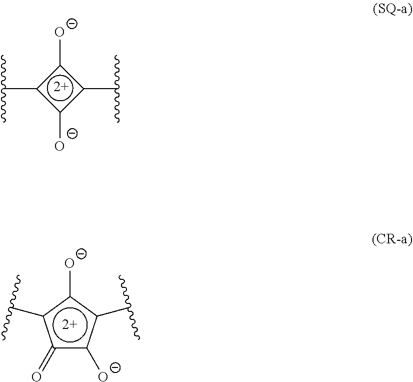

In the formulae, a wavy line represents a bonding hand.

Hereinafter, respective components of the near-infrared absorbing composition according to the embodiment of the present invention will be described.

<<Near-Infrared Absorbing Pigment A>>

The near-infrared absorbing composition according to the embodiment of the present invention contains a near-infrared absorbing pigment having an oxocarbon skeleton.

Hereinafter, the near-infrared absorbing pigment having an oxocarbon skeleton is also referred to as a near-infrared absorbing pigment A.

The near-infrared absorbing pigment A preferably has the maximum absorption wavelength in a range of 700 to 1200 nm, more preferably has the maximum absorption wavelength in a range of 700 to 1100 nm, and still more preferably has the maximum absorption wavelength in a range of 700 to 1000 nm.

The amount of the near-infrared absorbing pigment A dissolved in 100 g of propylene glycol methyl ether acetate at 25° C. is preferably 1 g or less, more preferably 0.5 g or less, and still more preferably 0.1 g or less.

The near-infrared absorbing pigment A is preferably a compound having a cation and an anion in a molecule. According to this aspect, the effects of the present invention are easily obtained more remarkably.

The near-infrared absorbing pigment A is preferably a compound having a π-conjugated plane including a monocyclic or fused aromatic ring. The number of monocyclic or fused aromatic rings in the π-conjugated plane included in the near-infrared absorbing pigment A is preferably 2 or more, more preferably 3 or more, and still more preferably 4 or more. Examples of the aromatic ring include a benzene ring, a naphthalene ring, a pentalene ring, an indene ring, an azulene ring, a heptalene ring, an indacene ring, a perylene ring, a pentacene ring, a quaterrylene ring, an acenaphthene ring, a phenanthrene ring, an anthracene ring, a naphthacene ring, a chrysene ring, a triphenylene ring, a fluorene ring, a pyridine ring, a quinoline ring, an isoquinoline ring, an imidazole ring, a benzimidazole ring, a pyrazole ring, a thiazole ring, a benzothiazole ring, a triazole ring, a benzotriazole ring, an oxazole ring, a benzoxazole ring, an imidazoline ring, a pyrazine ring, a quinoxaline ring, a pyrimidine ring, a quinazoline ring, a pyridazine ring, a triazine ring, a pyrrole ring, an indole ring, an isoindole ring, a carbazole ring, and a fused ring including the above-described ring.

From the reason that the effects of the present invention are easily obtained more remarkably, it is more preferable that the near-infrared absorbing pigment A is at least one compound selected from a squarylium compound or a croconium compound. In addition, it is also preferable that the near-infrared absorbing pigment A is at least one compound selected from a compound (compound (SQ1)) represented by Formula (SQ1) or a compound (compound (CR1)) represented by Formula (CR1).

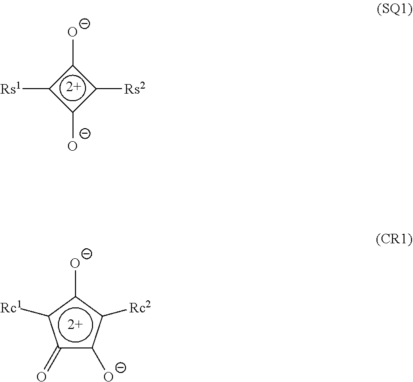

In Formula (SQ1), Rs¹ and Rs² each independently represent an organic group; and

in Formula (CR1), Rc¹ and Rc² each independently represent an organic group.

As shown below, cations in Formula (SQ1) are present without being localized.

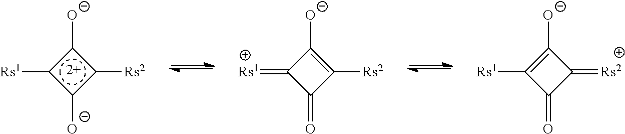

In addition, cations in Formula (CR1) are present without being localized as shown below.

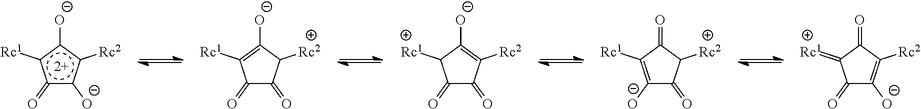

First, the compound (SQ1) (compound represented by Formula (SQ1)) will be described.

In Formula (SQ1), Rs¹ and Rs² each independently represent an organic group. Examples of the organic group represented by Rs¹ and Rs² include an aryl group, a heteroaryl group, or a group represented by Formula (R1).

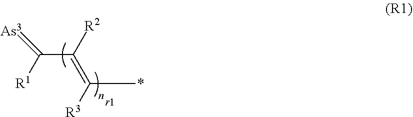

In Formula (R1), R¹ to R³ each independently represent a hydrogen atom or a substituent, As³ represents a heteroaryl group, nᵣ₁ represents an integer of 0 or more, R¹ and R² may be bonded to each other to form a ring, R¹ and As³ may be bonded to each other to form a ring, R² and R³ may be bonded to each other to form a ring, in which in a case where nᵣ₁ is 2 or more, a plurality of R²'s and R³'s each may be the same or different from each other, and * represents a bonding hand.

The number of carbon atoms in the aryl group represented by Rs¹ and Rs² is preferably 6 to 48, more preferably 6 to 22, and particularly preferably 6 to 12. The number of carbon atoms constituting a ring of the heteroaryl group represented by Rs¹ and Rs² is preferably 1 to 30 and more preferably 1 to 12. Examples of the type of the heteroatom constituting the ring of the heteroaryl group include a nitrogen atom, an oxygen atom, and a sulfur atom. The number of heteroatoms constituting the heteroaryl group is preferably 1 to 3 and more preferably 1 or 2. The heteroaryl group is preferably a monocyclic ring or a fused ring, more preferably a monocyclic ring or a fused ring composed of 2 to 8 rings, and still more preferably a monocyclic ring or a fused ring composed of 2 to 4 rings. The aryl group and heteroaryl group represented by Rs¹ and Rs² may have a substituent. Examples of the substituent include the substituent T described later and a group represented by Formula (R-SQ). In Formula (R-SQ), R_{sq}¹ represents an organic group. Examples of the organic group represented by R_{sq}¹ include an aryl group, a heteroaryl group, a group represented by Formula (R1), a group represented by Formula (1) described later, a group represented by Formula (10) described later, a group represented by Formula (20) described later, a group represented by Formula (30) described later, and a group represented by Formula (40) described later.

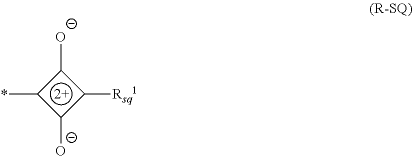

[Group Represented by Formula (R1)]

Next, a group represented by Formula (R1) will be described. In Formula (R1), R¹ to R³ each independently represent a hydrogen atom or a substituent. Examples of the substituent include the substituent T described later. The substituent represented by R¹ to R³ is preferably an alkyl group. The number of carbon atoms in the alkyl group is preferably 1 to 20, more preferably 1 to 15, and still more preferably 1 to 8. The alkyl group may be linear, branched, or cyclic, and is preferably linear or branched. R¹ to R³ are preferably hydrogen atoms. In Formula (R1), As³ represents a heteroaryl group. Examples of the heteroaryl group represented by As³ include the heteroaryl groups described in the section of Rs¹ and Rs², and the preferred range is also the same.

In Formula (R1), R¹ and R² may be bonded to each other to form a ring, R¹ and As³ may be bonded to each other to form a ring, and R² and R³ may be bonded to each other to form a ring. As a linking group in a case of forming the above-described ring, —CO—, —O—, —NH—, —CH₂—, or a divalent linking group selected from a group consisting of a combination thereof is preferable.

In Formula (R1), nᵣ₁ represents an integer of 0 or more. nᵣ₁ is preferably an integer of 0 to 2, more preferably 0 or 1, and still more preferably 0. In Formula (R1), in a case where nᵣ₁ is 2 or more, a plurality of R²'s and R³'s each may be the same or different from each other.

(Substituent T)

Examples of a substituent T include a halogen atom, a cyano group, a nitro group, an alkyl group, an alkenyl group, an alkynyl group, an aryl group, a heteroaryl group, —ORt¹, —CORt¹, —COORt¹, —OCORt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Rt¹ and Rt² each independently represent a hydrogen atom, an alkyl group, an alkenyl group, an alkynyl group, an aryl group, or a heteroaryl group. Rt¹ and Rt² may be bonded to each other to form a ring.

Examples of the halogen atom include a fluorine atom, a chlorine atom, a bromine atom, and an iodine atom.

The number of carbon atoms in the alkyl group is preferably 1 to 20, more preferably 1 to 15, and still more preferably 1 to 8. The alkyl group may be linear, branched, or cyclic, and is preferably linear or branched.

The number of carbon atoms in the alkenyl group is preferably 2 to 20, more preferably 2 to 12, and particularly preferably 2 to 8. The alkenyl group may be linear, branched, or cyclic, and is preferably linear or branched.

The number of carbon atoms in the alkynyl group is preferably 2 to 40, more preferably 2 to 30, and particularly preferably 2 to 25. The alkynyl group may be linear, branched, or cyclic, and is preferably linear or branched.

The number of carbon atoms in the aryl group is preferably 6 to 30, more preferably 6 to 20, and still more preferably 6 to 12.

As the heteroaryl group, a heteroaryl group of a monocyclic ring or a fused ring composed of 2 to 8 rings is preferable, and a heteroaryl group of a monocyclic ring or a fused ring composed of 2 to 4 rings is more preferable. The number of heteroatoms constituting a ring of the heteroaryl group is preferably 1 to 3. As the heteroatom constituting the ring of the heteroaryl group, a nitrogen atom, an oxygen atom, or a sulfur atom is preferable. It is preferable that the heteroaryl group is a 5-membered or 6-membered ring. The number of carbon atoms constituting the ring of the heteroaryl group is preferably 3 to 30, more preferably 3 to 18, and still more preferably 3 to 12.

The alkyl group, the alkenyl group, the alkynyl group, the aryl group, and the heteroaryl group may have a substituent or may be unsubstituted. Examples of the substituent include the substituents described in the substituent T.

At least one of Rs¹ or Rs² in Formula (SQ1) is also preferably a group represented by Formula (1). According to this aspect, a film having excellent moisture resistance is easily obtained.

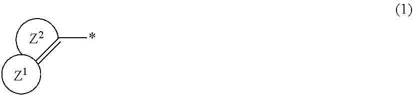 [SMILES: *C=C]

In Formula (1), a ring Z¹ represents an aromatic heterocyclic ring or a fused ring including an aromatic heterocyclic ring, which may have one or a plurality of substituents,

a ring Z² represents a 4-membered to 9-membered hydrocarbon ring or heterocyclic ring, which may have one or a plurality of substituents,

in a case where the ring Z¹ and the ring Z² have a plurality of substituents, the plurality of substituents may be the same or different from each other, and

* represents a bonding hand.

In Formula (1), the ring Z¹ represents an aromatic heterocyclic ring or a fused ring including an aromatic heterocyclic ring, which may have one or a plurality of substituents. Examples of the aromatic heterocyclic ring include an imidazole ring, an oxazole ring, a thiazole ring, a pyridine ring, a pyrazine ring, a pyrrole ring, a furan ring, a thiophene ring, a pyrazole ring, an isoxazole ring, an isothiazole ring, a pyridazine ring, and a pyrimidine ring. Among these, and an imidazole ring, an oxazole ring, a thiazole ring, a pyridine ring, a pyrazine ring, or a pyrrole ring is preferable. Examples of the fused ring including an aromatic heterocyclic ring include a fused ring of one or more rings (in a case of two or more rings, the two or more rings may be the same or different from each other) selected from an imidazole ring, an oxazole ring, a thiazole ring, a pyridine ring, a pyrazine ring, a pyrrole ring, a furan ring, a thiophene ring, a pyrazole ring, an isoxazole ring, an isothiazole ring, a pyridazine ring, and a pyrimidine ring, and a ring (preferably a benzene ring or a naphthalene ring) selected from a benzene ring, a naphthalene ring, an anthracene ring, a tetracene ring, a phenanthrene ring, a triphenylene ring, a tetraphene ring, and a pyrene ring; and a fused ring of two or more rings (in a case of two or more rings, the two or more rings may be the same or different from each other) selected from an imidazole ring, an oxazole ring, a thiazole ring, a pyridine ring, a pyrazine ring, a pyrrole ring, a furan ring, a thiophene ring, a pyrazole ring, an isoxazole ring, an isothiazole ring, a pyridazine ring, and a pyrimidine ring. From the reason that more excellent spectral characteristics are easily obtained, the fused number of the fused ring is preferably 2 to 6 and more preferably 2 to 4.

In Formula (1), the ring Z² represents a 4-membered to 9-membered hydrocarbon ring or heterocyclic ring, which may have one or a plurality of substituents. The hydrocarbon ring and heterocyclic ring represented by the ring Z² are preferably a 5-membered to 7-membered ring and more preferably a 5-membered or 6-membered ring. Specific examples of the hydrocarbon ring includes cycloalkene rings such as a cyclobutene ring, a cyclopentene ring, a cyclopentadiene ring, a cyclohexene ring, a cyclohexadiene ring, a cycloheptene ring, a cycloheptadiene ring, a cycloheptatriene ring, a cyclooctene ring, a cyclooctadiene ring, a cyclooctatriene ring, a cyclononene ring, a cyclononadiene ring, a cyclononatriene ring, and a cyclononatetraene ring. Among these, a cyclopentene ring, a cyclohexene ring, a cycloheptene ring, or a cyclooctene ring is preferable and a cyclopentene ring or a cyclohexene ring is more preferable. The heterocyclic ring represented by the ring Z² is preferably a nitrogen-containing heterocyclic ring.

Examples of the substituent which may be included in the ring Z¹ and the ring Z² include the above-described substituent T. In addition, it is also preferable that the substituent which may be included in the ring Z¹ is an electron-withdrawing group. A substituent having a positive Hammett's substituent constant σ value (sigma value) acts as an electron-withdrawing group. Here, the substituent constant obtained by Hammett's rule includes a op value and a cm value. These values can be found in many common books. In the present invention, a substituent having the Hammett's substituent constant σ value of 0.1 or more can be exemplified as the electron-withdrawing group, σ value is preferably 0.15 or more, more preferably 0.2 or more, and still more preferably 0.3 or more. The upper limit is not particularly limited, but is preferably 1.0 or less. Specific examples of the electron-withdrawing group include a halogen atom, an alkyl group in which at least a part of hydrogen atoms is replaced by a halogen atom, an aryl group in which at least a part of hydrogen atoms is replaced by a halogen atom, a nitro group, a cyano group, a cyanomethyl group, —CH═C(CN)₂, —C(CN)═C(CN)₂, —P(CN)₂, —N═NCN, —CORz, —COORz, —OCORz, —NHCORz, —CONHRz, —SORz, —SO₂Rz, —SO₂ORz, —NHSO₂Rz, and —SO₂NHRz. Rz represents an alkyl group in which at least a part of hydrogen atoms is replaced by a fluorine atom, an aryl group in which at least a part of hydrogen atoms is replaced by a fluorine atom, an amino group, a halogen atom, a cyano group, or a cyanomethyl group. Here, the cyanomethyl group includes a monocyanomethyl group (—CH₂CN), a dicyanomethyl group (—CH(CN)₂), and a tricyanomethyl group (—C(CN)₃). The alkyl group in which at least a part of hydrogen atoms is replaced by a fluorine atom preferably has 1 to 6 carbon atoms, more preferably has 1 to 5 carbon atoms, and still more preferably has 1 to 4 carbon atoms. The aryl group in which at least a part of hydrogen atoms is replaced by a fluorine atom preferably has 6 to 14 carbon atoms and more preferably has 6 to 10 carbon atoms. In these alkyl groups and aryl groups, all of the hydrogen atoms may be replaced by fluorine atoms, a part of hydrogen atoms may be replaced by a fluorine atom, or these alkyl groups and aryl groups may not be substituted with a fluorine atom.

The group represented by Formula (1) is preferably a group represented by Formula (1-1) or Formula (1-2).

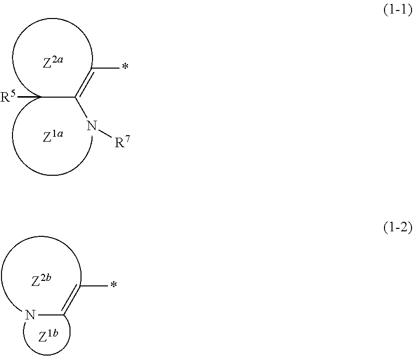

In Formula (1-1), a ring Z^{1a} is a polycyclic aromatic ring having a 5-membered or 6-membered nitrogen-containing heterocyclic ring, which may have one or a plurality of substituents, and a ring Z^{2a} is a 4-membered to 9-membered hydrocarbon ring or heterocyclic ring, which may have one or a plurality of substituents. In a case where the ring Z^{1a} and the ring Z^{2a} have a plurality of substituents, the plurality of substituents may be the same or different from each other. R⁵ and R⁷ each independently represent a hydrogen atom or a substituent.

In Formula (1-1), examples of the polycyclic aromatic ring represented by the ring Z^{1a} include a fused ring including a 5-membered or 6-membered nitrogen-containing heterocyclic ring selected from an imidazole ring, an oxazole ring, a thiazole ring, a pyridine ring, a pyrazine ring, a pyrrole ring, a furan ring, a thiophene ring, a pyrazole ring, an isoxazole ring, an isothiazole ring, a pyridazine ring, and a pyrimidine ring. In addition, examples of the polycyclic aromatic ring include a fused ring of one or more rings (in a case of two or more nitrogen-containing heterocyclic rings, the two or more nitrogen-containing heterocyclic rings may be the same or different from each other) selected from the above-described nitrogen-containing heterocyclic ring, and a benzene ring or a naphthalene ring; and a fused ring of two or more rings (in a case of two or more nitrogen-containing heterocyclic rings, the two or more nitrogen-containing heterocyclic rings may be the same or different from each other) selected from the above-described nitrogen-containing heterocyclic ring. From the reason that more excellent spectral characteristics are easily obtained, the number of rings included in the polycyclic aromatic ring (fused number of the fused ring) is preferably 2 to 6 and more preferably 2 to 4.

In Formula (1-1), examples of the 4-membered to 9-membered hydrocarbon ring and heterocyclic ring represented by the ring Z^{2a} include those described in the section of the ring Z² in Formula (1).

In Formula (1-1), examples of the substituent which may be included in the ring Z^{1a} and the ring Z^{2a}, and the substituent represented by R⁵ and R⁷ include the above-described substituent T. In addition, it is also preferable that the substituent which may be included in the ring Z^{1a} is an electron-withdrawing group. Examples of the electron-withdrawing group include the above-described groups.

In Formula (1-2), a ring Z^{1b} represents a polycyclic aromatic ring having a 5-membered or 6-membered nitrogen-containing heterocyclic ring, which may have one or a plurality of substituents, a ring Z^{2b} represents a 4-membered to 9-membered nitrogen-containing heterocyclic ring which may have one or a plurality of substituents, and in a case where the ring Z^{1a} and the ring Z^{2a} have a plurality of substituents, the plurality of substituents may be the same or different from each other.

In Formula (1-2), examples of the polycyclic aromatic ring represented by the ring Z^{1b} include a fused ring including a 5-membered or 6-membered nitrogen-containing heterocyclic ring selected from an imidazole ring, an oxazole ring, a thiazole ring, a pyridine ring, a pyrazine ring, a pyrrole ring, a furan ring, a thiophene ring, a pyrazole ring, an isoxazole ring, an isothiazole ring, a pyridazine ring, and a pyrimidine ring. In addition, examples of the polycyclic aromatic ring include a fused ring of one or more rings (in a case of two or more nitrogen-containing heterocyclic rings, the two or more nitrogen-containing heterocyclic rings may be the same or different from each other) selected from the above-described nitrogen-containing heterocyclic ring, and a benzene ring or a naphthalene ring; and a fused ring of two or more rings (in a case of two or more nitrogen-containing heterocyclic rings, the two or more nitrogen-containing heterocyclic rings may be the same or different from each other) selected from the above-described nitrogen-containing heterocyclic ring. From the reason that more excellent spectral characteristics are easily obtained, the number of rings included in the polycyclic aromatic ring (fused number of the fused ring) is preferably 2 to 6 and more preferably 2 to 4.

In Formula (1-2), the nitrogen-containing heterocyclic ring represented the ring Z^{2b} is preferably a 5-membered to 7-membered ring and more preferably a 5-membered or 6-membered ring.

In Formula (1-2), examples of the substituent which may be included in the ring Z^{1b} and the ring Z^{2b} include the above-described substituent T. In addition, it is also preferable that the substituent which may be included in the ring Z^{1b} is an electron-withdrawing group. Examples of the electron-withdrawing group include the above-described groups.

At least one of Rs¹ or Rs² in Formula (SQ1) is also preferably a group represented by Formula (10). According to this aspect, a film having excellent light resistance is easily obtained.

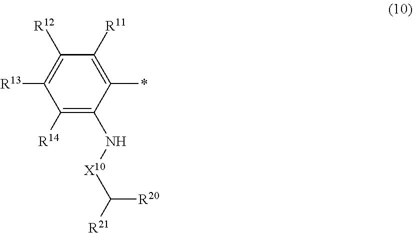

In Formula (10), R¹¹ to R¹⁴ each independently represent a hydrogen atom or a substituent, and two adjacent groups of R¹¹ to R¹⁴ may be bonded to each other to form a ring; R²⁰ represents an aryl group or a heteroaryl group; R²¹ represents a substituent; and X¹⁰ represents CO or SO₂.

In Formula (10), R¹¹ to R¹⁴ each independently represent a hydrogen atom or a substituent, and two adjacent groups of R¹¹ to R¹⁴ may be bonded to each other to form a ring. Examples of the substituent represented by R¹¹ to R¹⁴ include the above-described substituent T.

In Formula (10), R²⁰ represents an aryl group or a heteroaryl group, and an aryl group is preferable. The number of carbon atoms in the aryl group is preferably 6 to 48, more preferably 6 to 22, and particularly preferably 6 to 12. The number of carbon atoms constituting a ring of the heteroaryl group is preferably 1 to 30 and more preferably 1 to 12.

Examples of the type of the heteroatom constituting the ring of the heteroaryl group include a nitrogen atom, an oxygen atom, and a sulfur atom. The number of heteroatoms constituting the heteroaryl group is preferably 1 to 3 and more preferably 1 or 2. The heteroaryl group is preferably a monocyclic ring or a fused ring, more preferably a monocyclic ring or a fused ring composed of 2 to 8 rings, and still more preferably a monocyclic ring or a fused ring composed of 2 to 4 rings. The aryl group and heteroaryl group may have a substituent. Examples of the substituent include the substituent T described above. It is preferable that the aryl group and the heteroaryl group do not have a substituent.

In Formula (10), R²¹ represents a substituent. Examples of the substituent represented by R²¹ include the above-described substituent T, and an alkyl group, an aryl group, a heteroaryl group, —OCORt¹, or —NHCORt¹ is preferable. Rt¹ is preferably an alkyl group, an aryl group, or a heteroaryl group and more preferably an alkyl group.

In Formula (10), X¹⁰ represents CO or SO₂. In a case where X¹⁰ is CO, more excellent heat resistance is easily obtained. In a case where X¹⁰ is SO₂, more excellent visible transparency is easily obtained.

At least one of Rs¹ or Rs² in Formula (SQ1) is also preferably a group represented by Formula (20). According to this aspect, an effect of improving heat resistance can be expected.

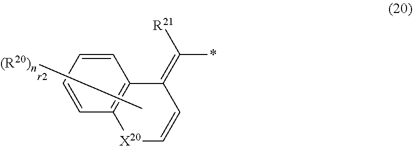

In Formula (20), R²⁰ and R²¹ each independently represent a hydrogen atom or a substituent, and R²⁰ and R²¹ may be bonded to each other to form a ring,

X²⁰ represents an oxygen atom, a sulfur atom, NR²², a selenium atom, or a tellurium atom, in which R²² represents a hydrogen atom or a substituent, and in a case where X²⁰ is NR²², R²² and R²⁰ may be bonded to each other to form a ring,

nᵣ₂ represents an integer of 0 to 5,

in a case where nᵣ₂ is 2 or more, a plurality of R²⁰'s may be the same or different from each other, and two R²⁰'s of the plurality of R²⁰'s may be bonded to each other to form a ring, and

* represents a bonding hand.

In Formula (20), examples of the substituent represented by R²⁰ and R²¹ include the above-described substituent T.

R²⁰ is preferably an alkyl group, a halogenated alkyl group (preferably a fluorinated alkyl group), an aryl group, or a halogen atom, more preferably an alkyl group or a halogenated alkyl group, and still more preferably a halogenated alkyl group. R²¹ is preferably a hydrogen atom or an alkyl group and more preferably a hydrogen atom.

In Formula (20), X²⁰ is preferably an oxygen atom, a sulfur atom, or NR²² and more preferably NR²². R²² represents a hydrogen atom or a substituent. Examples of the substituent include the above-described substituent T, and an alkyl group is preferable. In a case where X²⁰ is NR²², R²² and R²⁰ may be bonded to each other to form a ring. Examples of the ring formed by bonding R²² and R²⁰ to each other include a 4-membered to 9-membered hydrocarbon ring or heterocyclic ring, and a 5-membered to 7-membered hydrocarbon ring or heterocyclic ring is preferable, a 5-membered or 6-membered hydrocarbon ring or heterocyclic ring is more preferable, a 5-membered or 6-membered hydrocarbon ring is still more preferable, and a 6-membered hydrocarbon ring is particularly preferable.

In Formula (20), nᵣ₂ represents an integer of 0 to 5, and is preferably an integer of 0 to 3, more preferably an integer of 0 to 2, and still more preferably an integer of 1 or 2. In a case where nᵣ₂ is 2 or more, a plurality of R²⁰'s may be the same or different from each other, and two R²⁰'S of a plurality of R²⁰'s may be bonded to each other to form a ring. The ring formed by bonding R²⁰'s to each other may be a hydrocarbon ring or a heterocyclic ring. In addition, the ring formed by bonding these groups to each other may be a monocyclic ring or a fused ring.

At least one of Rs¹ or Rs² in Formula (SQ1) is also preferably a group represented by Formula (30) or Formula (40). According to this aspect, an effect of improving light resistance can be expected.

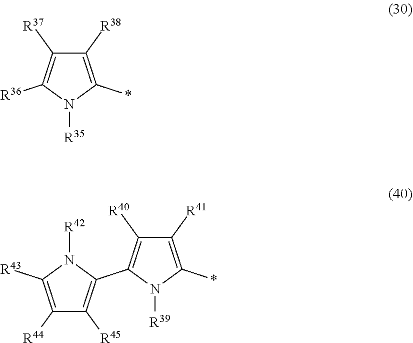

In Formula (30), R³⁵ to R³⁸ each independently represent a hydrogen atom or a substituent, R³⁵ and R³⁶, R³⁶ and R³⁷, or R³⁷ and R³⁸ may be bonded to each other to form a ring, and * represents a bonding hand; and

in Formula (40), R³⁹ to R⁴⁵ each independently represent a hydrogen atom or a substituent, R³⁹ and R⁴⁵, R⁴⁰ and R⁴¹, R⁴⁰ and R⁴², R⁴² and R⁴³, R⁴³ and R⁴⁴, or R⁴⁴ and R⁴⁵ may be bonded to each other to form a ring, and * represents a bonding hand.

Examples of the substituent represented by R³⁵ to R³⁸ in Formula (30) and the substituent represented by R³⁹ to R⁴⁵ in Formula (40) include the above-described substituent T, and an alkyl group or an aryl group is preferable and an alkyl group is more preferable.

In Formula (30), R³⁵ and R³⁶, R³⁶ and R³⁷, or R³⁷ and R³⁸ may be bonded to each other to form a ring. In addition, in Formula (40), R³⁹ and R⁴⁵, R⁴⁰ and R⁴¹, R⁴⁰ and R⁴², R⁴² and R⁴³, R⁴³ and R⁴⁴, or R⁴⁴ and R⁴⁵ may be bonded to each other to form a ring. Examples of the ring formed by bonding these groups to each other include a hydrocarbon ring and a heterocyclic ring, and a hydrocarbon ring is preferable. In addition, the ring formed by bonding these groups to each other may be a monocyclic ring or a fused ring, but a fused ring is preferable.

In Formula (30), it is preferable that R³⁵ and R³⁶ is bonded to each other to form a ring. In addition, in Formula (40), it is preferable that R⁴⁰ and R⁴¹, or R⁴⁴ and R⁴⁵ is respectively bonded to each other to form a ring.

The group represented by Formula (30) is preferably a group represented by Formula (30a). In addition, the group represented by Formula (40) is preferably a group represented by Formula (40a).

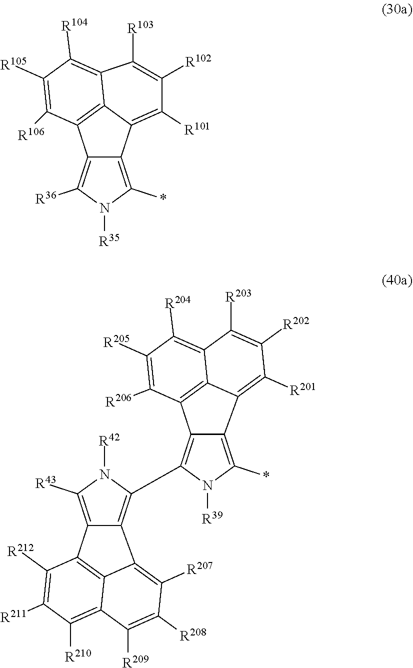

In Formula (30a), R³⁵, R³⁶, and R¹⁰¹ to R¹⁰⁶ each independently represent a hydrogen atom or a substituent, and * represents a bonding hand. In Formula (40a), R³⁹, R⁴², R⁴³, and R²⁰¹ to R²¹² each independently represent a hydrogen atom or a substituent, and * represents a bonding hand. Examples of the substituent represented by R³⁵, R³⁶, and R¹⁰¹ to R¹⁰⁶ and the substituent represented by R³⁹, R⁴², R⁴³, and R²⁰¹ to R²¹² include the above-described substituent T, and an alkyl group or an aryl group is preferable and an alkyl group is more preferable.

As the near-infrared absorbing pigment A used in the present invention, a compound represented by Formula (SQ2) or Formula (SQ3) is also preferable. According to this aspect, an effect of improving moisture resistance can be expected.

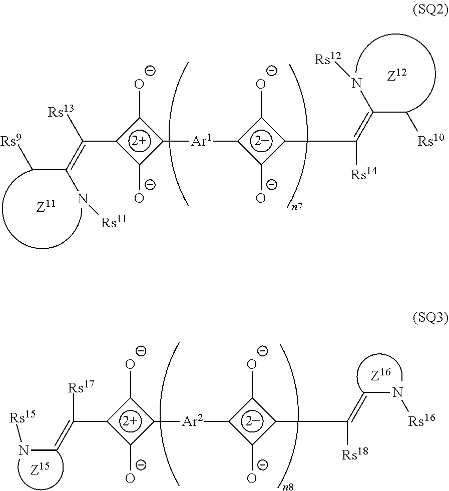

In Formula (SQ2), a ring Z¹¹ and a ring Z¹² each independently represent a polycyclic aromatic ring having a nitrogen-containing heterocyclic ring, which may have one or a plurality of substituents,

in a case where the ring Z¹¹ and the ring Z¹² have a plurality of substituents, the plurality of substituents may be the same or different from each other,

Rs⁹ to Rs¹⁴ each independently represent a hydrogen atom or a substituent,

Ar¹ represents a group represented by any one of Formulae (Ar-1) to (Ar-4),

n7 represents an integer of 0 to 2, and

Rs⁹ and Rs¹³, or Rs¹⁰ and Rs¹⁴ may be bonded to each other to form a ring; and

in Formula (SQ3), a ring Z¹⁵ and a ring Z¹⁶ each independently represent a polycyclic aromatic ring having a nitrogen-containing heterocyclic ring, which may have one or a plurality of substituents,

in a case where the ring Z¹⁵ and the ring Z¹⁶ have a plurality of substituents, the plurality of substituents may be the same or different from each other,

Rs¹⁵ to Rs¹⁸ each independently represent a hydrogen atom or a substituent,

Ar² represents a group represented by any one of Formulae (Ar-1) to (Ar-4),

n8 represents an integer of 0 to 2, and

Rs¹⁵ and Rs¹⁷, or Rs¹⁶ and Rs¹⁸ may be bonded to each other to form a ring.

In Formula (SQ2), the ring Z¹¹ and the ring Z¹² each independently represent a polycyclic aromatic ring having a nitrogen-containing heterocyclic ring, which may have one or a plurality of substituents. The ring Z¹¹ and ring Z¹² in Formula (SQ2) are the same as the ring Z^{1a} in Formula (1-1), and the preferred ranges are also the same.

In Formula (SQ2), examples of the substituent which may be included in the ring Z¹¹ and the ring Z¹², and the substituent represented by Rs⁹ to Rs¹⁴ include the above-described substituent T.

In Formula (SQ2), Rs⁹ and Rs¹³, or Rs¹⁰ and Rs¹⁴ may be bonded to each other to form a ring. Examples of the ring formed by bonding these groups to each other include a hydrocarbon ring and a heterocyclic ring, and a hydrocarbon ring is preferable. In addition, the ring formed by bonding these groups to each other is preferably a 4-membered to 9-membered ring, more preferably a 5-membered to 7-membered ring, and still more preferably a 5-membered or 6-membered ring. Specific examples of the hydrocarbon ring includes cycloalkene rings such as a cyclobutene ring, a cyclopentene ring, a cyclopentadiene ring, a cyclohexene ring, a cyclohexadiene ring, a cycloheptene ring, a cycloheptadiene ring, a cycloheptatriene ring, a cyclooctene ring, a cyclooctadiene ring, a cyclooctatriene ring, a cyclononene ring, a cyclononadiene ring, a cyclononatriene ring, and a cyclononatetraene ring. Among these, a cyclopentene ring, a cyclohexene ring, a cycloheptene ring, or a cyclooctene ring is preferable and a cyclopentene ring or a cyclohexene ring is more preferable. The heterocyclic ring is preferably a nitrogen-containing heterocyclic ring.

In Formula (SQ2), from the reason that it is easy to shift the maximum absorption wavelength of a compound to a longer wavelength side and to improve visible transparency and near infrared shielding properties, Ar¹ is preferably a group represented by any one of Formulae (Ar-2) to (Ar-4).

In Formula (SQ2), n7 represents an integer of 0 to 2, and is preferably 0 or 1.

In Formula (SQ3), the ring Z¹⁵ and the ring Z¹⁶ each independently represent a polycyclic aromatic ring having a nitrogen-containing heterocyclic ring, which may have one or a plurality of substituents. The ring Z¹⁵ and ring Z¹⁶ in Formula (SQ3) are the same as the ring Z^{1b} in Formula (1-2), and the preferred ranges are also the same.

In Formula (SQ3), examples of the substituent which may be included in the ring Z¹⁵ and the ring Z¹⁶, and the substituent represented by Rs¹⁵ to Rs¹⁸ include the above-described substituent T.

In Formula (SQ3), Rs¹⁵ and Rs¹⁷, or Rs¹⁶ and Rs¹⁸ may be bonded to each other to form a ring. The ring formed by bonding these groups to each other is preferably a 4-membered to 9-membered nitrogen-containing heterocyclic ring, more preferably a 5-membered to 7-membered nitrogen-containing heterocyclic ring, and still more preferably a 5-membered or 6-membered nitrogen-containing heterocyclic ring.

In Formula (SQ3), from the reason that it is easy to shift the maximum absorption wavelength of a compound to a longer wavelength side and to improve visible transparency and near infrared shielding properties, Ar² is preferably a group represented by any one of Formulae (Ar-2) to (Ar-4).

In Formula (SQ3), n8 represents an integer of 0 to 2, and is preferably 0 or 1.

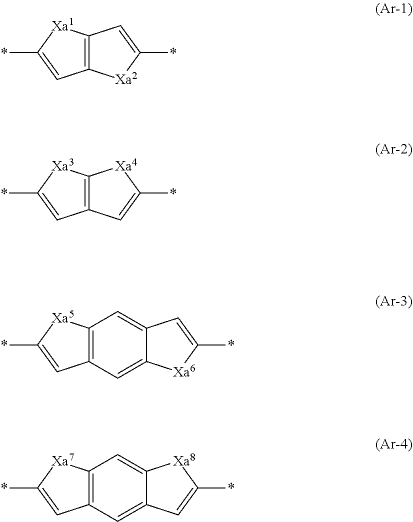

In the formulae, Xa¹ to Xa⁸ each independently represent a sulfur atom, an oxygen atom, or NRx^{a}, in which Rx^{a} represents a hydrogen atom or a substituent, and * represents a bonding hand. Examples of the substituent represented by Rx^{a} include the above-described substituent T, and an alkyl group is preferable. It is preferable that at least one of Xa¹ or Xa², at least one of Xa³ or Xa⁴, at least one of Xa⁵ or Xa⁶, and at least one of Xa⁷ or Xa⁸ each independently represent an oxygen atom or NRx^{a}.

As the near-infrared absorbing pigment A used in the present invention, a compound represented by Formula (SQ10) is also preferable. According to this aspect, heat resistance and light resistance can be further improved.

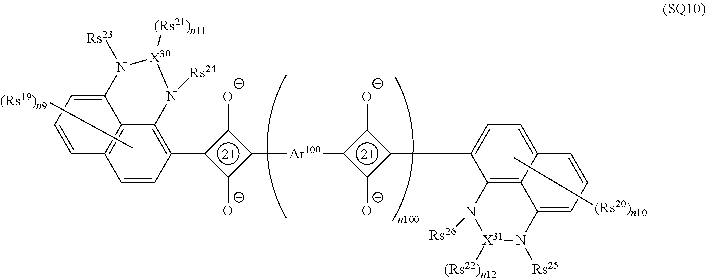

In Formula (SQ10), Rs¹⁹ and Rs²⁰ each independently represent a substituent,

Rs²¹ to Rs²⁶ each independently represent a hydrogen atom or a substituent,

X³⁰ and X³¹ each independently represent a carbon atom, a boron atom, or C(═O),

n11 is 2 in a case where X³⁰ is a carbon atom, n11 is 1 in a case where X³⁰ is a boron atom, and n11 is 0 in a case where X³⁰ is C(═O),

n12 is 2 in a case where X³¹ is a carbon atom, n12 is 1 in a case where X³¹ is a boron atom, and n12 is 0 in a case where X³¹ is C(═O),

n9 and n10 each independently represent an integer of 0 to 5,

in a case where n9 is 2 or more, a plurality of Rs¹⁹'s may be the same or different from each other, and two Rs¹⁹'s of the plurality of Rs¹⁹'s may be bonded to each other to form a ring,

in a case where n10 is 2 or more, a plurality of Rs²⁰'s may be the same or different from each other, and two Rs²⁰'s of the plurality of Rs²⁰'s may be bonded to each other to form a ring,

in a case where n11 is 2, two Rs²¹'s may be the same or different from each other and may be bonded to each other to form a ring,

in a case where n12 is 2, two Rs²²'s may be the same or different from each other and may be bonded to each other to form a ring,

Ar¹⁰⁰ represents a group represented by any one of Formulae (Ar-1) to (Ar-4), and

n100 represents an integer of 0 to 2.

In Formula (SQ10), examples of the substituent represented by Rs¹⁹ to Rs²⁶ include the above-described substituent T, and a halogen atom, an alkyl group, or an aryl group is preferable.

In Formula (SQ10), Rs²³ to Rs²⁶ are preferably hydrogen atoms.

In Formula (SQ10), in a case where n9 is 2 or more, a plurality of Rs¹⁹'s may be the same or different from each other, and two Rs¹⁹'s of the plurality of Rs¹⁹'s may be bonded to each other to form a ring. In addition, in a case where n10 is 2 or more, a plurality of Rs²⁰'s may be the same or different from each other, and two Rs²⁰'s of the plurality of Rs²⁰'s may be bonded to each other to form a ring. In addition, in a case where n11 is 2, two Rs²¹'s may be the same or different from each other and may be bonded to each other to form a ring. In addition, in a case where n12 is 2, two Rs²²'s may be the same or different from each other and may be bonded to each other to form a ring. Examples of the ring formed by bonding these groups to each other include a hydrocarbon ring and a heterocyclic ring, and a hydrocarbon ring is preferable. In addition, the ring formed by bonding these groups to each other is preferably a 4-membered to 9-membered ring, more preferably a 5-membered to 7-membered ring, and still more preferably a 5-membered or 6-membered ring.

In Formula (SQ10), Ar¹⁰⁰ is preferably a group represented by any one of Formulae (Ar-2) to (Ar-4).

In Formula (SQ10), n100 represents an integer of 0 to 2, and is preferably 0 or 1.

As the near-infrared absorbing pigment A used in the present invention, a compound represented by Formula (SQ20) is also preferable. According to this aspect, heat resistance and light resistance can be further improved.

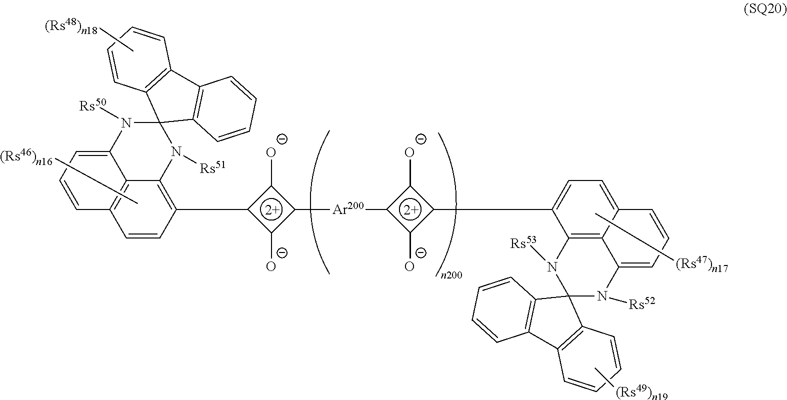

In Formula (SQ20), Rs⁴⁶ and Rs⁴⁹ each independently represent a substituent,

Rs⁵⁰ to Rs⁵³ each independently represent a hydrogen atom or a substituent,

n16 and n17 each independently represent an integer of 0 to 5,

n18 and n19 each independently represent an integer of 0 to 6,

in a case where n16 is 2 or more, a plurality of Rs⁴⁶'s may be the same or different from each other, and two Rs⁴⁶'s of the plurality of Rs⁴⁶'s may be bonded to each other to form a ring,

in a case where n17 is 2 or more, a plurality of Rs⁴⁷'s may be the same or different from each other, and two Rs⁴⁷'s of the plurality of Rs⁴⁷'s may be bonded to each other to form a ring,

in a case where n18 is 2 or more, a plurality of Rs⁴⁸'s may be the same or different from each other, and two Rs⁴⁸'s of the plurality of Rs⁴⁸'s may be bonded to each other to form a ring,

in a case where n19 is 2 or more, a plurality of Rs⁴⁹'s may be the same or different from each other, and two Rs⁴⁹'s of the plurality of Rs⁴⁹'s may be bonded to each other to form a ring,

Ar²⁰⁰ represents a group represented by any one of Formulae (Ar-1) to (Ar-4), and

n200 represents an integer of 0 to 2.

In Formula (SQ20), examples of the substituent represented by Rs⁴⁶ to Rs⁵³ include the above-described substituent T. As the substituent represented by Rs⁴⁶ and Rs⁴⁷, an electron-withdrawing group is also preferable. Examples of the electron-withdrawing group include the above-described groups.

In Formula (SQ20), Rs⁵⁰ to Rs⁵³ are preferably hydrogen atoms.

In Formula (SQ20), n16 and n17 each independently represent an integer of 0 to 5, and is preferably 0 to 4, more preferably 0 to 3, and still more preferably 0 or 2.

In Formula (SQ20), n18 and n19 each independently represent an integer of 0 to 6, and is preferably 1 to 4, more preferably 1 to 3, and still more preferably 1 or 2.

In Formula (SQ20), in a case where n16 is 2 or more, a plurality of Rs⁴⁶'s may be the same or different from each other, and two Rs⁴⁶'s of the plurality of Rs⁴⁶'s may be bonded to each other to form a ring. In addition, in a case where n17 is 2 or more, a plurality of Rs⁴⁷'s may be the same or different from each other, and two Rs⁴⁷'s of the plurality of Rs⁴⁷'s may be bonded to each other to form a ring. In addition, in a case where n18 is 2 or more, a plurality of Rs⁴⁸'S may be the same or different from each other, and two Rs⁴⁸'s of the plurality of Rs⁴⁸'s may be bonded to each other to form a ring. In addition, in a case where n19 is 2 or more, a plurality of Rs⁴⁹'s may be the same or different from each other, and two Rs⁴⁹'s of the plurality of Rs⁴⁹'s may be bonded to each other to form a ring. Examples of the ring formed by bonding these groups to each other include a hydrocarbon ring and a heterocyclic ring, and a hydrocarbon ring is preferable. In addition, the ring formed by bonding these groups to each other is preferably a 4-membered to 9-membered ring, more preferably a 5-membered to 7-membered ring, and still more preferably a 5-membered or 6-membered ring.

In Formula (SQ20), Ar²⁰⁰ is preferably a group represented by any one of Formulae (Ar-2) to (Ar-4).

In Formula (SQ20), n200 represents an integer of 0 to 2, and is preferably 0 or 1.

As the near-infrared absorbing pigment A used in the present invention, a compound represented by Formula (SQ30) is also preferable. According to this aspect, light resistance can be further improved.

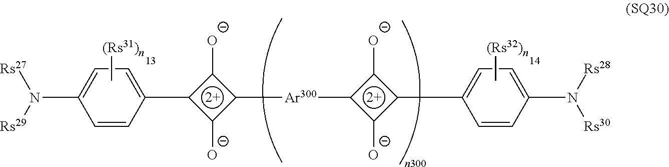

In Formula (SQ30), Rs²⁷ to Rs³⁰ each independently represent a hydrogen atom or a substituent,

Rs³¹ and Rs³² each independently represent a substituent or a group represented by Formula (100),

Rs²⁷ and Rs²⁹, Rs²⁷ and Rs³¹, Rs²⁹ and Rs³¹, Rs²⁸ and Rs³⁰, Rs²⁸ and Rs³², or Rs³⁰ and

Rs³² may be bonded to each other to form a ring,

Rs³¹ and Rs³² may be linked through a single bond or a linking group,

n13 and n14 each independently represent an integer of 0 to 4,

in a case where n13 is 2 or more, a plurality of Rs³¹'s may be the same or different from each other, and two Rs³¹'s of the plurality of Rs³¹'s may be bonded to each other to form a ring,

in a case where n14 is 2 or more, a plurality of Rs³²'s may be the same or different from each other, and two Rs³²'s of the plurality of Rs³²'s may be bonded to each other to form a ring,

Ar³⁰⁰ represents a group represented by any one of Formulae (Ar-1) to (Ar-4), and

n300 represents an integer of 0 to 2.

In Formula (SQ30), examples of the substituent represented by Rs²⁷ to Rs³² include the above-described substituent T. The substituent represented by Rs²⁷ to Rs³⁰ is preferably an alkyl group or an aryl group.

In Formula (SQ30), it is preferable that Rs³¹ and Rs³² are each independently a group represented by Formula (100).

In Formula (SQ30), Rs²⁷ and Rs²⁹, Rs²⁷ and Rs³¹, Rs²⁹ and Rs³¹, Rs²⁸ and Rs³⁰, Rs²⁸ and Rs³², or Rs³⁰ and Rs³² may be bonded to each other to form a ring. Examples of the ring formed by bonding these groups to each other include a hydrocarbon ring and a heterocyclic ring, and a hydrocarbon ring is preferable. In addition, the ring formed by bonding these groups to each other is preferably a 4-membered to 9-membered ring, more preferably a 5-membered to 7-membered ring, and still more preferably a 5-membered or 6-membered ring.

In Formula (SQ30), Rs³¹ and Rs³² may be linked through a single bond or a linking group. Examples of the linking group include —CH₂—, —CO—, —O—, —NH—, and a group selected from the group consisting of a combination thereof.

In Formula (SQ30), n13 and n14 each independently represent an integer of 0 to 4, and are preferably 1 to 4, more preferably 1 to 3, and still more preferably 1 or 2.

In Formula (SQ30), in a case where n13 is 2 or more, a plurality of Rs³¹'s may be the same or different from each other, and two Rs³¹'s of the plurality of Rs³¹'s may be bonded to each other to form a ring. In addition, in a case where n14 is 2 or more, a plurality of Rs³²'s may be the same or different from each other, and two Rs³²'s of the plurality of Rs³²'s may be bonded to each other to form a ring. Examples of the ring formed by bonding these groups to each other include a hydrocarbon ring and a heterocyclic ring, and a hydrocarbon ring is preferable. In addition, the ring formed by bonding these groups to each other is preferably a 4-membered to 9-membered ring, more preferably a 5-membered to 7-membered ring, and still more preferably a 5-membered or 6-membered ring.

In Formula (SQ30), Ar³⁰⁰ is preferably a group represented by any one of Formulae (Ar-2) to (Ar-4).

In Formula (SQ30), n300 represents an integer of 0 to 2, and is preferably 0 or 1.

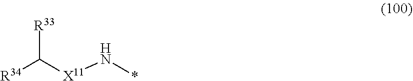

In Formula (100), R³³ represents an aryl group or a heteroaryl group, and an aryl group is preferable. The number of carbon atoms in the aryl group is preferably 6 to 30, more preferably 6 to 20, and still more preferably 6 to 12. As the heteroaryl group, a heteroaryl group of a monocyclic ring or a fused ring composed of 2 to 8 rings is preferable, and a heteroaryl group of a monocyclic ring or a fused ring composed of 2 to 4 rings is more preferable. The number of heteroatoms constituting a ring of the heteroaryl group is preferably 1 to 3. As the heteroatom constituting the ring of the heteroaryl group, a nitrogen atom, an oxygen atom, or a sulfur atom is preferable. It is preferable that the heteroaryl group is a 5-membered or 6-membered ring. The number of carbon atoms constituting the ring of the heteroaryl group is preferably 3 to 30, more preferably 3 to 18, and still more preferably 3 to 12. The aryl group and heteroaryl group may have a substituent. Examples of the substituent include the above-described substituent T.

In Formula (100), R³⁴ represents a hydrogen atom or a substituent. Examples of the substituent include the above-described substituent T, and an alkyl group, an aryl group, a heteroaryl group, —OCORt¹, or —NHCORt¹ is preferable. Rt¹ is preferably an alkyl group, an aryl group, or a heteroaryl group and more preferably an alkyl group. In a case where both Rs³¹ and Rs³² are the group represented by Formula (100), two R³⁴ in the groups of the both, which are represented by Formula (100), may be linked through a single bond or a linking group, and from the reason that more excellent light resistance is easily obtained, it is preferable to be linked. Examples of the linking group include —CH₂—, —CO—, —O—, —NH—, and a group selected from the group consisting of a combination thereof.

In Formula (100), X¹¹ represents CO or SO₂.

The compound represented by Formula (SQ30) is preferably a compound represented by Formula (SQ30-1). According to this aspect, an effect of improving visible transparency can be expected.

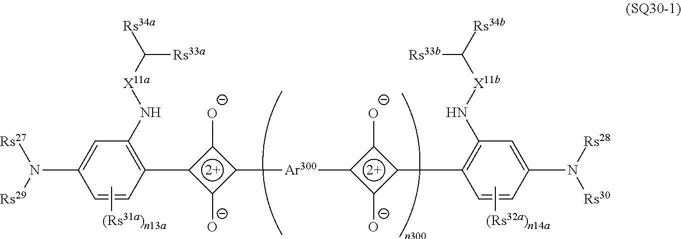

In Formula (SQ30-1), Rs²⁷ to Rs³⁰ each independently represent a hydrogen atom or a substituent,

Rs^{31a} and Rs^{32a} each independently represent a substituent,

Rs^{33a} and Rs^{33b} each independently represent an aryl group or a heteroaryl group,

Rs^{34a} and Rs^{34b} each independently represent a hydrogen atom or a substituent,

Rs²⁷ and Rs²⁹, Rs²⁷ and Rs^{31a}, Rs²⁹ and Rs^{31a}, Rs²⁷ and Rs^{34a}, Rs²⁹ and Rs^{34a}, Rs²⁸ and Rs³⁰, Rs²⁸ and Rs^{32a}, Rs³⁰ and Rs^{32a}, Rs²⁸ and Rs^{34b}, or Rs³⁰ and Rs^{34b} may be bonded to each other to form a ring,

Rs^{34a} and Rs^{34b} may be linked through a single bond or a linking group,

X^{11a} and X^{11b} each independently represent CO or SO₂,

n13a and n14a each independently represent an integer of 0 to 3,

in a case where n13a is 2 or more, a plurality of Rs^{31a}'s may be the same or different from each other, and two Rs^{31a}'s of the plurality of Rs^{31a}'s may be bonded to each other to form a ring,

in a case where n14a is 2 or more, a plurality of Rs^{32a}'s may be the same or different from each other, and two Rs^{32a}'s of the plurality of Rs^{32a}'s may be bonded to each other to form a ring,

Ar³⁰⁰ represents a group represented by any one of Formulae (Ar-1) to (Ar-4), and

n300 represents an integer of 0 to 2.

Rs²⁷ to Rs³⁰, Ar³⁰⁰, and n300 in Formula (SQ30-1) are the same as Rs²⁷ to Rs³⁰, Ar³⁰⁰, and n300 in Formula (SQ30), and the preferred ranges are also the same.

Rs^{31a} and Rs^{32a} in Formula (SQ30-1) are the same as Rs³¹ and Rs³² in Formula (SQ30), and the preferred ranges are also the same.

Rs^{33a} and Rs^{33b} in Formula (SQ30-1) are the same as Rs³³ in Formula (100), and the preferred ranges are also the same.

Rs^{34a} and Rs^{34b} in Formula (SQ30-1) are the same as Rs³⁴ in Formula (100), and the preferred ranges are also the same.

X^{11a} and X^{11b} in Formula (SQ30-1) are the same as X¹¹ in Formula (100), and the preferred ranges are also the same.

In Formula (SQ30-1), Rs²⁷ and Rs²⁹, Rs²⁷ and Rs^{31a}, Rs²⁹ and Rs^{31a}, Rs²⁷ and Rs^{34a}, Rs²⁹ and Rs^{34a}, Rs²⁸ and Rs³⁰, Rs²⁸ and Rs^{32a}, Rs³⁰ and Rs^{32a}, Rs²⁸ and Rs^{34b}, or Rs³⁰ and Rs^{34b} may be bonded to each other to form a ring. Examples of the ring formed by bonding these groups to each other include a hydrocarbon ring and a heterocyclic ring, and a hydrocarbon ring is preferable. In addition, the ring formed by bonding these groups to each other is preferably a 4-membered to 9-membered ring, more preferably a 5-membered to 7-membered ring, and still more preferably a 5-membered or 6-membered ring.

In Formula (SQ30-1), Rs^{34a} and Rs^{34b} may be linked through a single bond or a linking group, and from the reason that more excellent light resistance is easily obtained, it is preferable to be linked. Examples of the linking group include —CH₂—, —CO—, —O—, —NH—, and a group selected from the group consisting of a combination thereof.

In Formula (SQ30-1), n13a and n14a each independently represent an integer of 0 to 3, and are preferably 0 to 2, more preferably 0 or 1, still more preferably 1 or 2, and particularly preferably 1.

(Compound (CR1))

Next, the compound (CR1) (compound represented by Formula (CR1)) will be described.

In Formula (CR1), Rc¹ and Rc² each independently represent an organic group.

Examples of the organic group represented by Rc¹ and Rc² include an aryl group, a heteroaryl group, a group represented by Formula (R1) described above, a group represented by Formula (1) described above, a group represented by Formula (10) described above, a group represented by Formula (20) described above, a group represented by Formula (30) described above, and a group represented by Formula (40) described above.

In Formula (CR1), it is preferable that at least one of Rc¹ or Rc² is any one of a group represented by Formula (1) described above, a group represented by Formula (10) described above, a group represented by Formula (20) described above, a group represented by Formula (30) described above, or a group represented by Formula (40) described above.

The aryl group, heteroaryl group, group represented by Formula (R1), group represented by Formula (1), group represented by Formula (10), group represented by Formula (20), group represented by Formula (30), and group represented by Formula (40) represented by Rc¹ and Rc² are the same range as described in the section of Rs¹ and Rs² in Formula (SQ1), and the preferred ranges are also the same.

Specific examples of the near-infrared absorbing pigment A include compounds having the following structures.

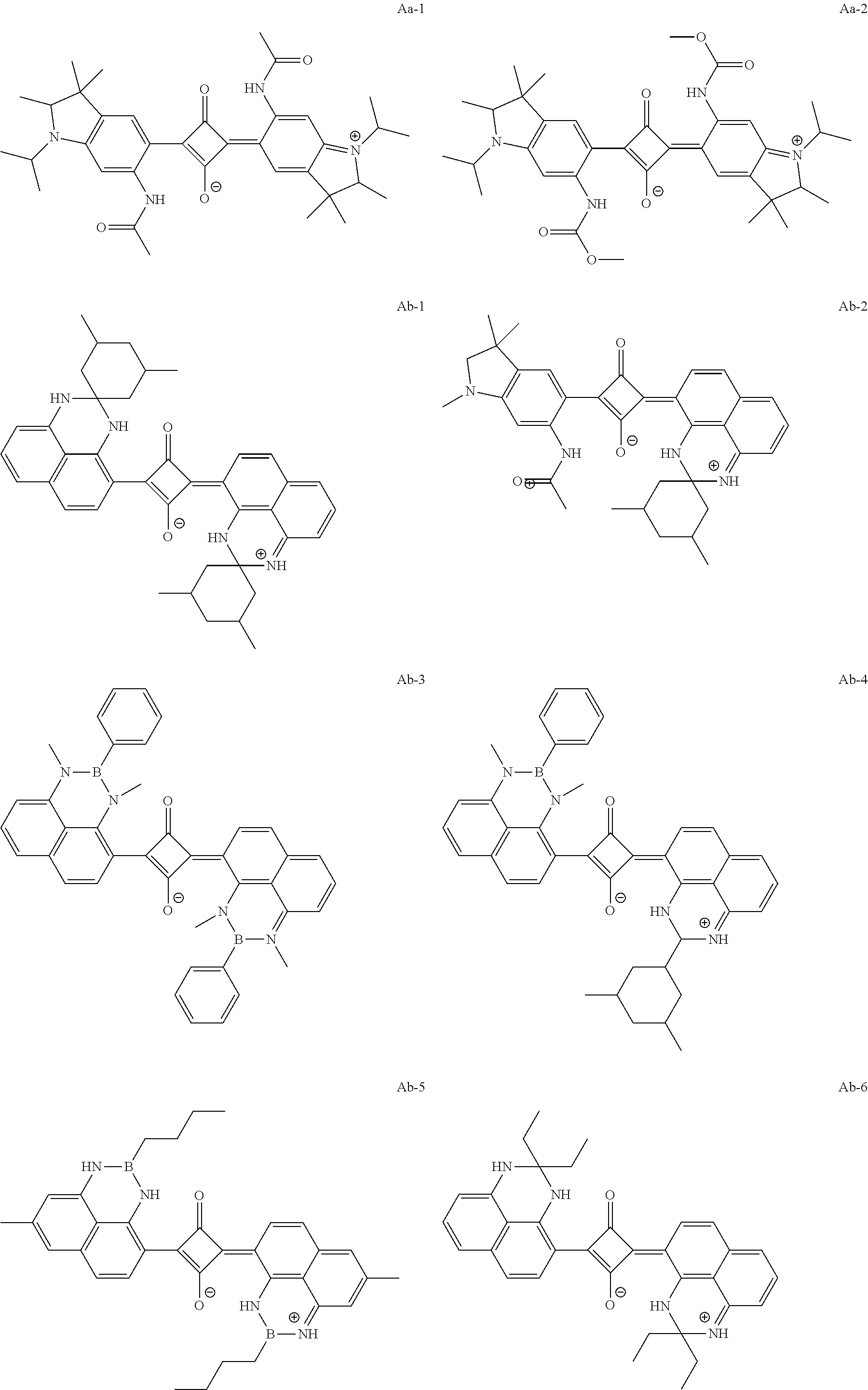

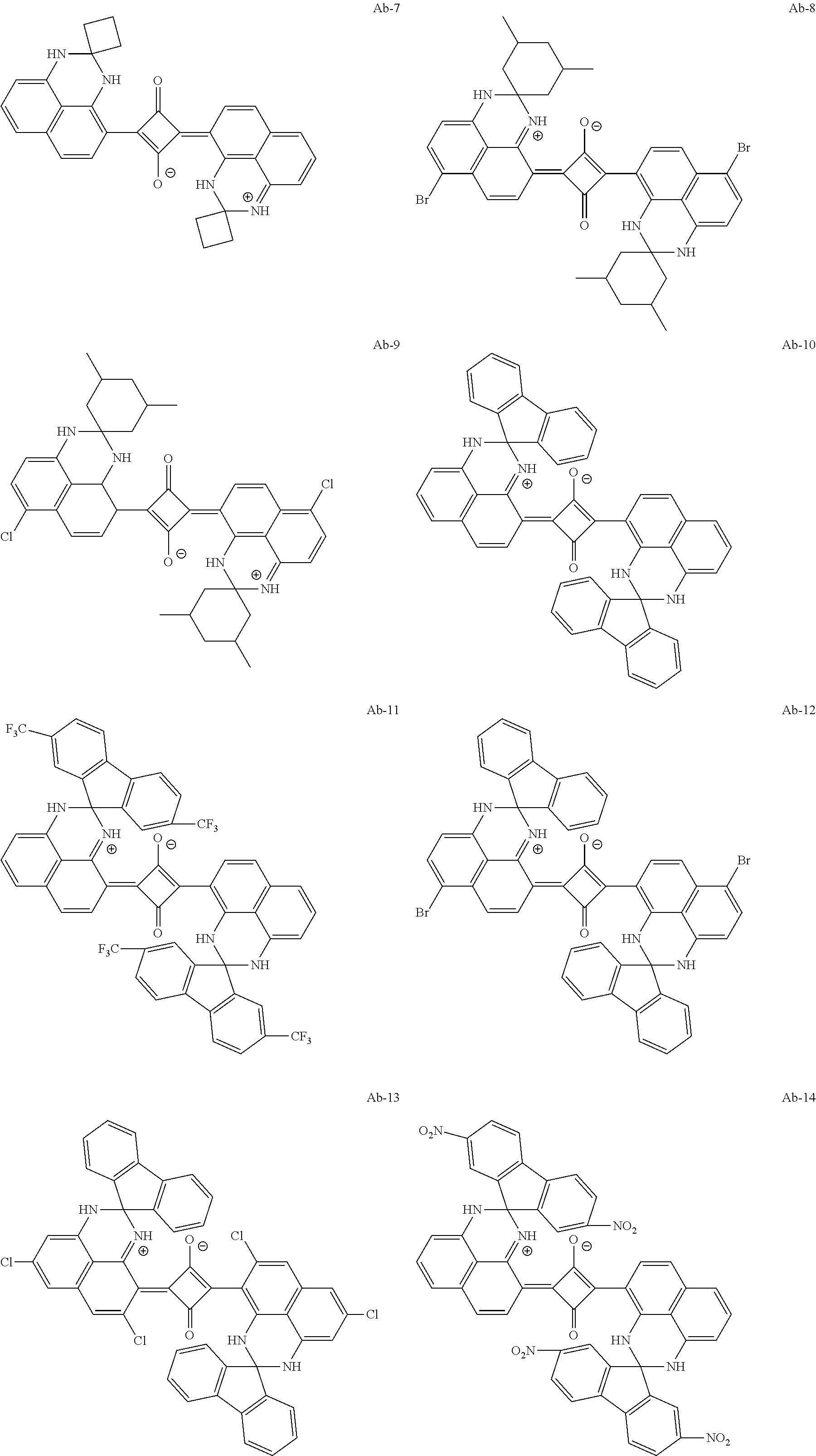

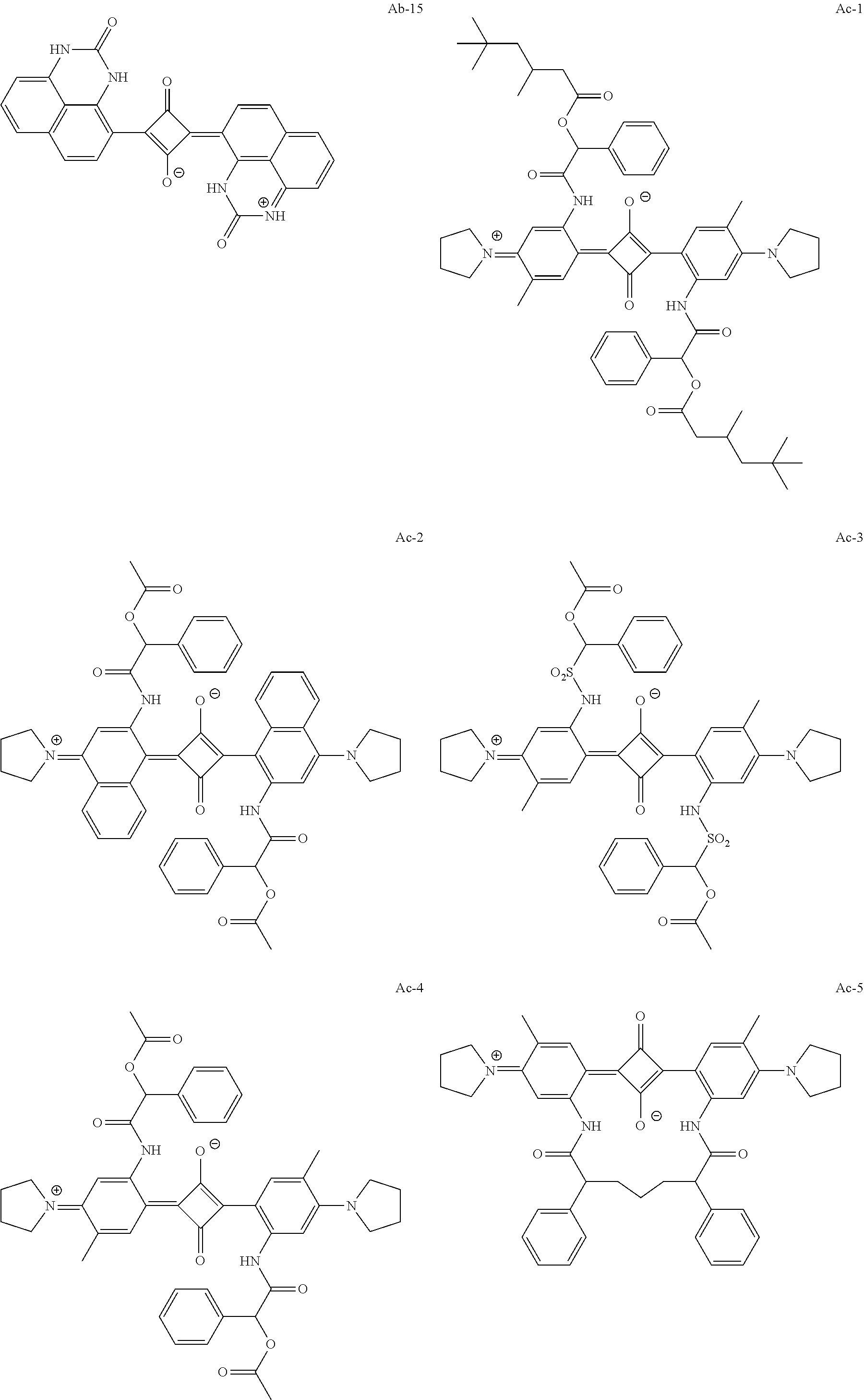

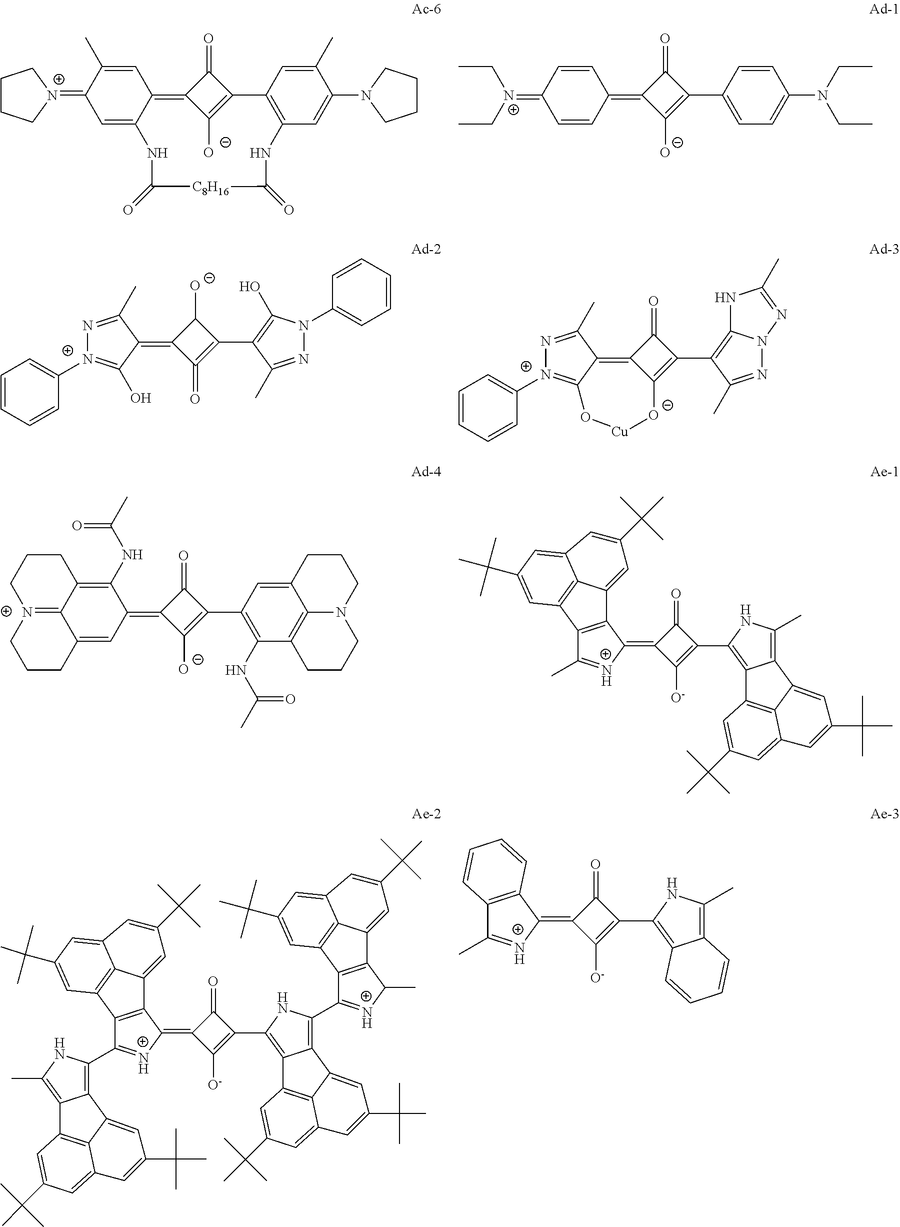

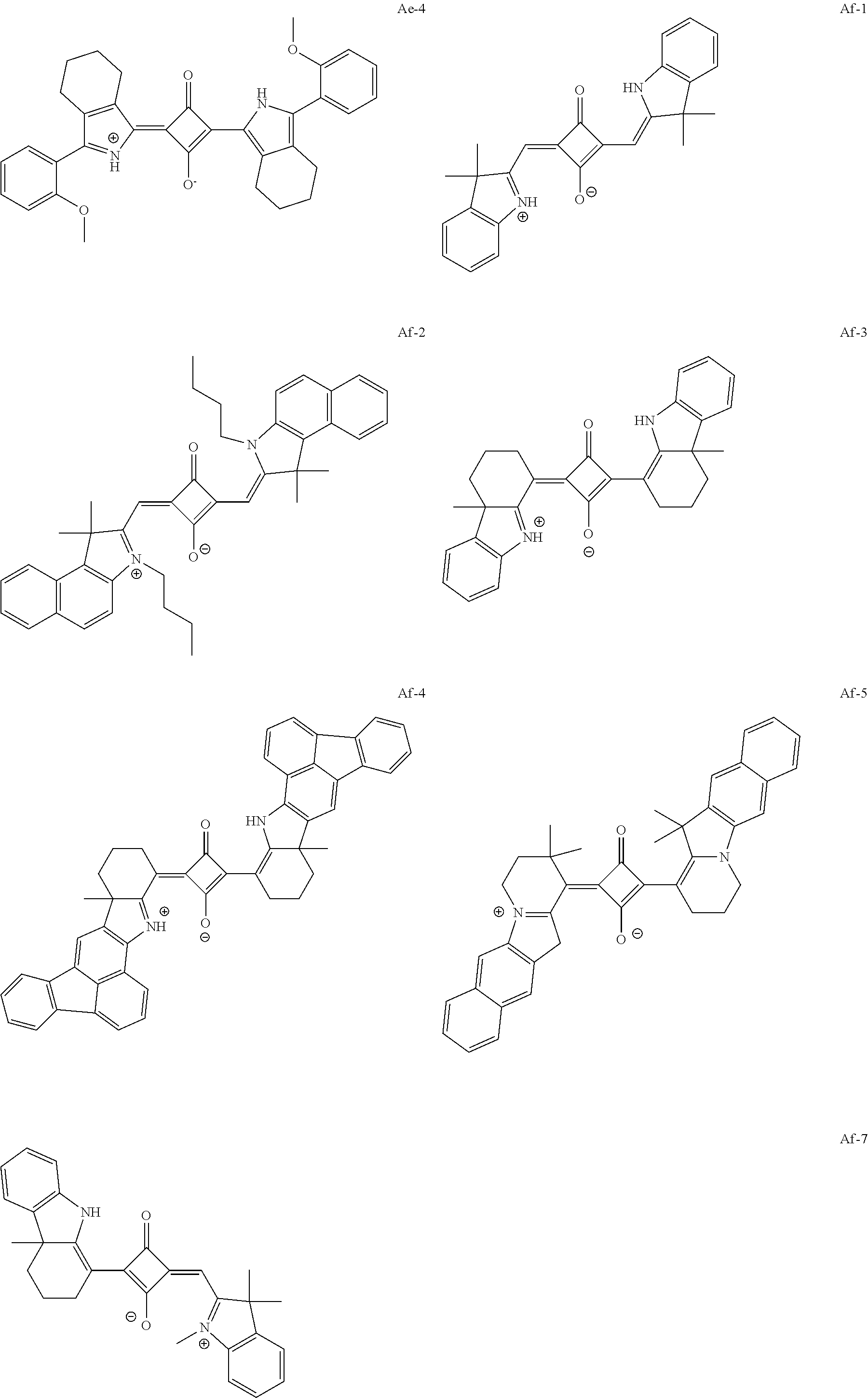

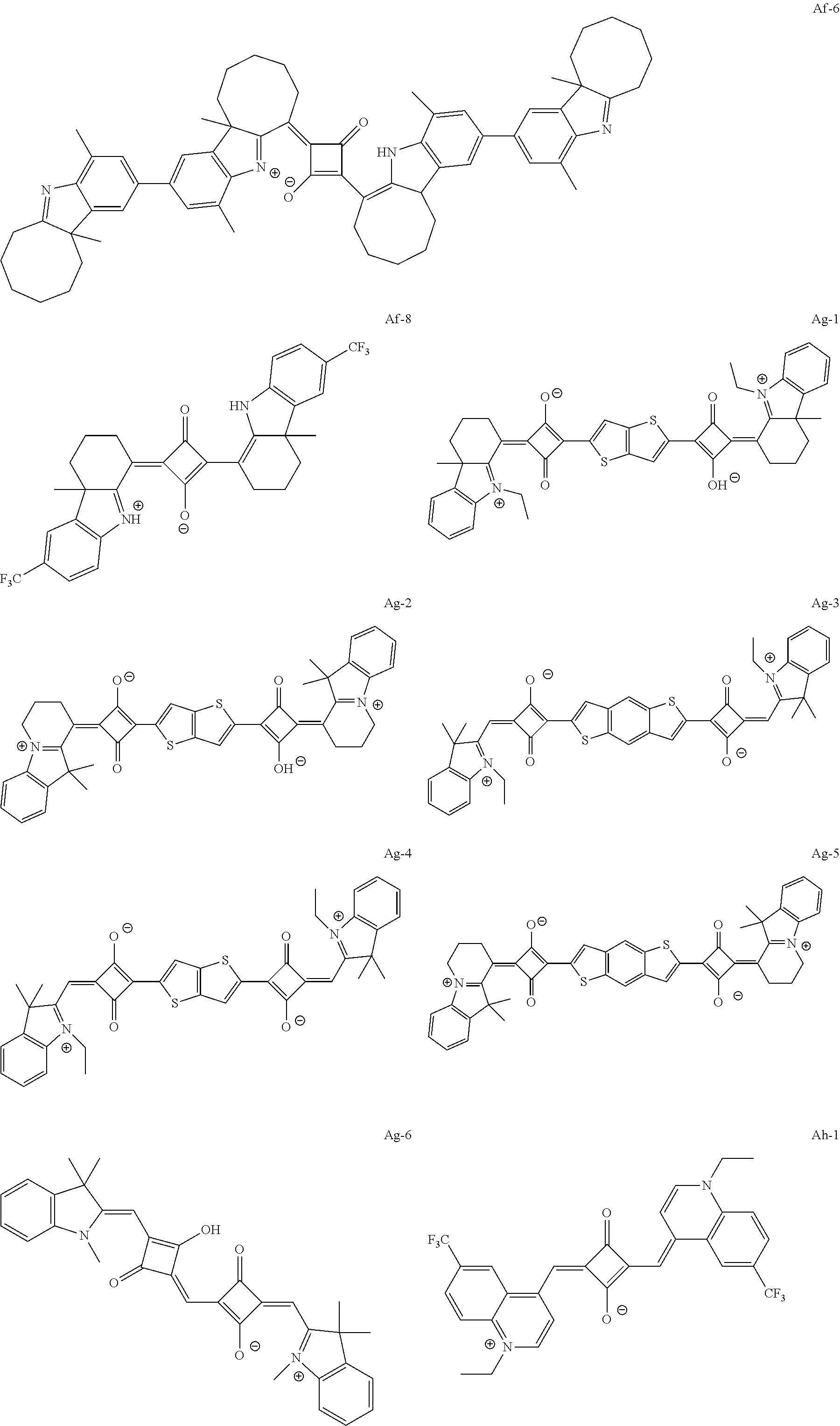

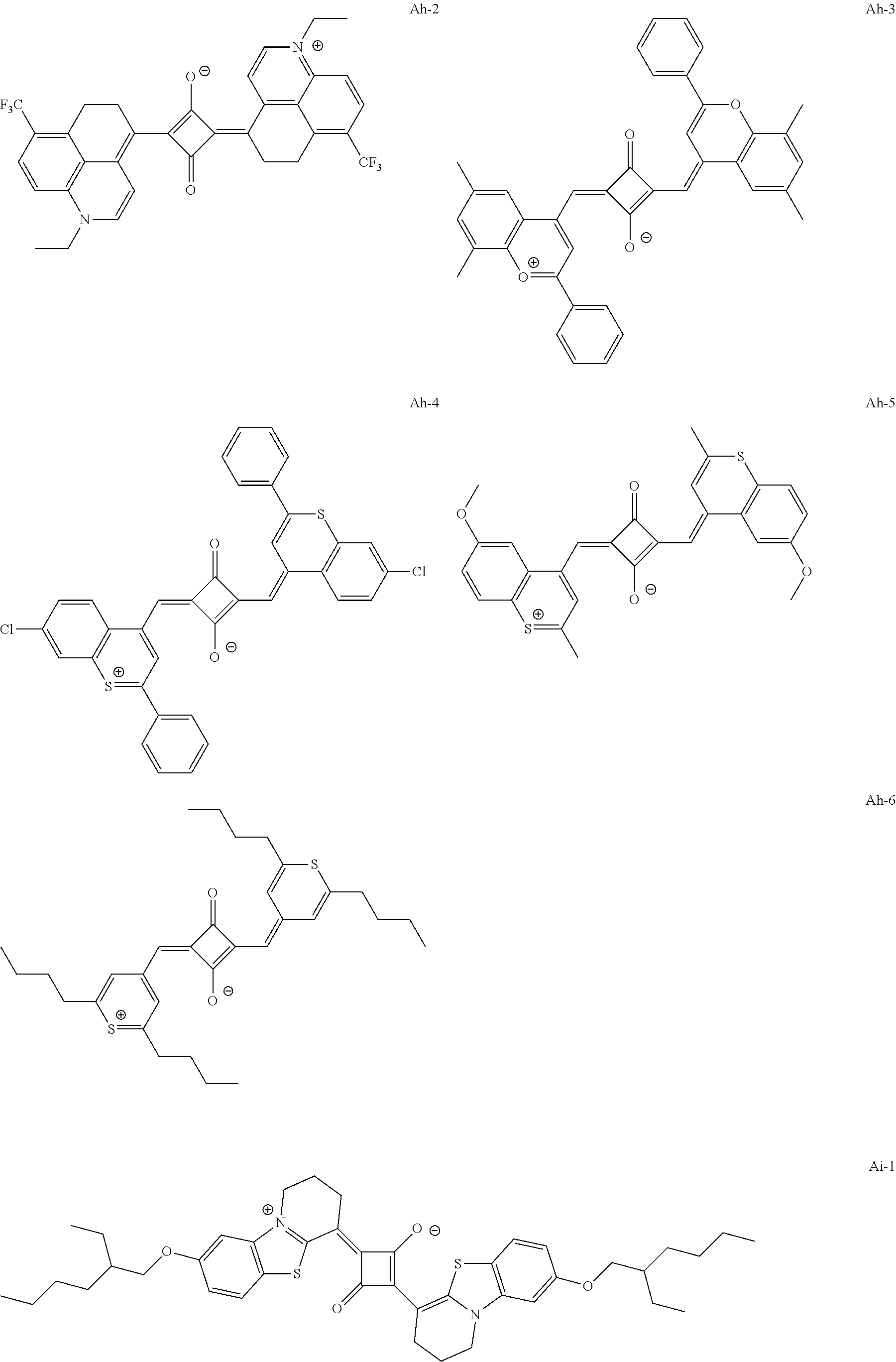

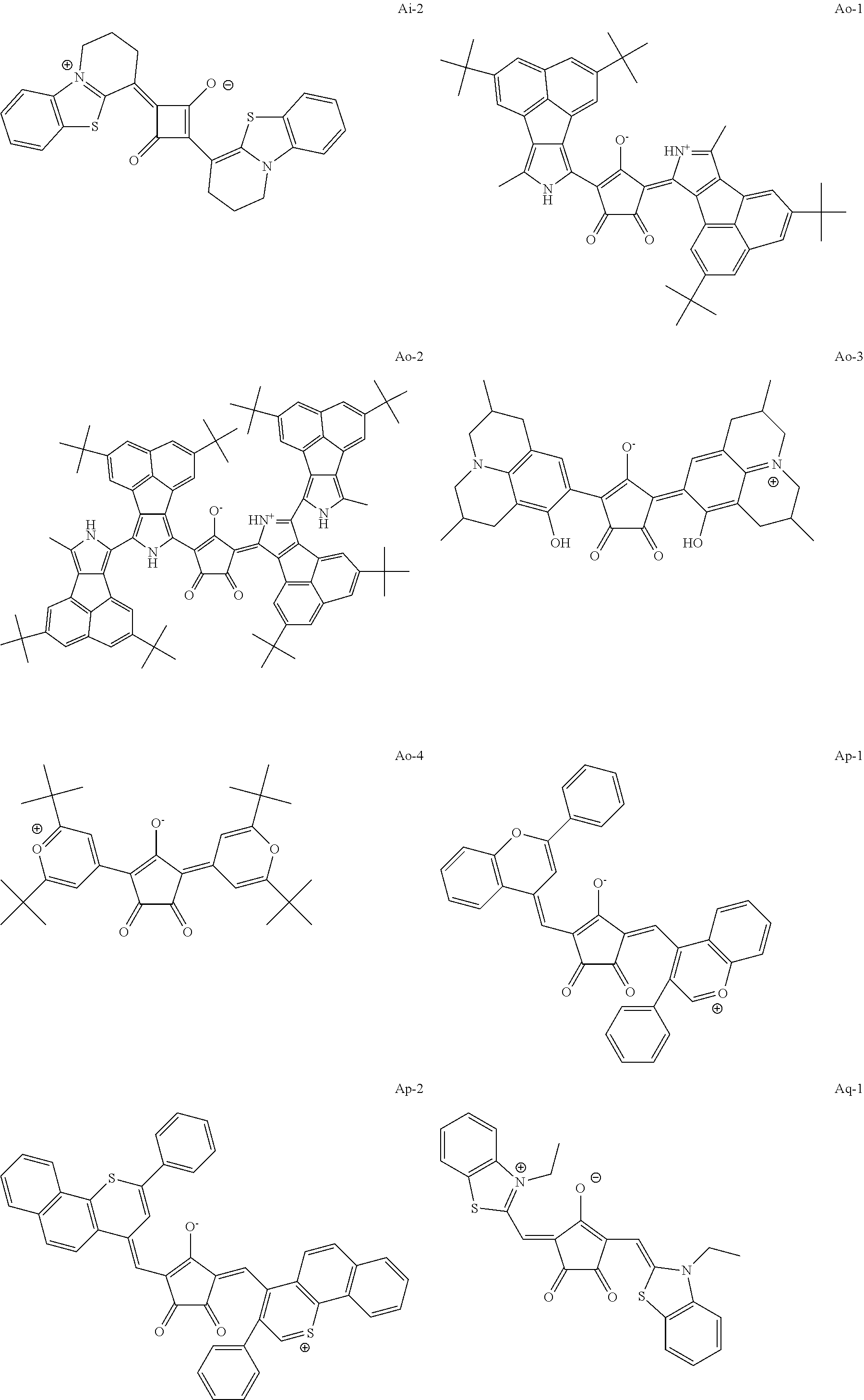

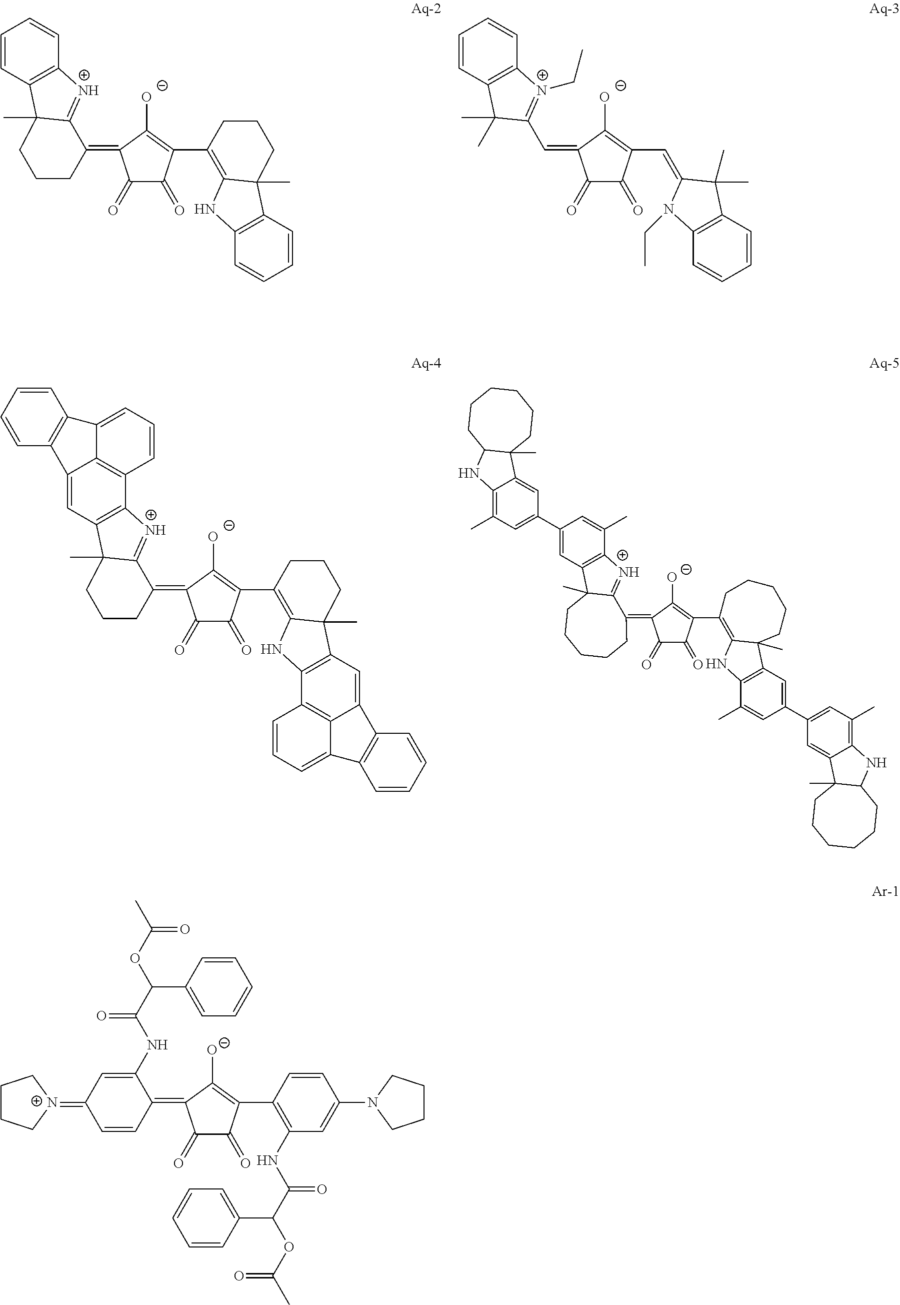

The content of the near-infrared absorbing pigment A in the total solid content of the near-infrared absorbing composition according to the embodiment of the present invention is preferably 0.1 to 70 mass %. The lower limit is preferably 0.5 mass % or more and more preferably 1.0 mass % or more. The upper limit is preferably 60 mass % or less and more preferably 50 mass % or less. In a case where the near-infrared absorbing composition according to the embodiment of the present invention includes two or more kinds of near-infrared absorbing pigments A, it is preferable that the total content thereof is within the above-described range.

<<Coloring Agent Derivative>>

The near-infrared absorbing composition according to the embodiment of the present invention includes a coloring agent derivative. The coloring agent derivative used in the present invention is a compound having a cation and an anion in a molecule. The coloring agent derivative is used, for example, as a dispersion aid for the near-infrared absorbing pigment A.

The amount of the coloring agent derivative dissolved in 100 g of propylene glycol methyl ether acetate at 25° C. is preferably 0.01 mg to 10 g. The upper limit is preferably 7.5 g or less and more preferably 5 g or less. The lower limit is preferably 0.05 mg or more and more preferably 0.1 mg or more. According to this aspect, dispersion stability of the near-infrared absorbing pigment in the composition can be further improved.

The molecular weight of the coloring agent derivative is preferably 160 to 4500. The upper limit is preferably 4000 or less and more preferably 3500 or less. The lower limit is preferably 200 or more and more preferably 250 or more. In a case where the molecular weight of the coloring agent derivative is within the above-described range, an effect of improving dispersion stability of the near-infrared absorbing pigment A can be expected.

The coloring agent derivative preferably has the maximum absorption wavelength in a range of 700 to 1200 nm, more preferably has the maximum absorption wavelength in a range of 700 to 1100 nm, and still more preferably has the maximum absorption wavelength in a range of 700 to 1000 nm. In a coloring agent derivative having a maximum absorption wavelength in the above-described wavelength range, a spread of n plane can be easily brought close to the near-infrared absorbing pigment A, adsorptivity of the near-infrared absorbing pigment A is improved, and more excellent dispersion stability can be easily obtained.

The coloring agent derivative is preferably a compound including an aromatic ring, and is more preferably a compound including a structure in which two or more aromatic rings are fused. By using such a compound, the effects of the present invention are more remarkably obtained.

The coloring agent derivative is preferably a compound having a π-conjugated plane, and is more preferably a compound having a π-conjugated plane having the same structure as the π-conjugated plane included in the near-infrared absorbing pigment A. In addition, the number of n electrons included in the π-conjugated plane of the coloring agent derivative is preferably 8 to 100. The upper limit is preferably 90 or less and more preferably 80 or less. The lower limit is preferably 10 or more and more preferably 12 or more. In addition, it is also preferable that the coloring agent derivative is a compound having a π-conjugated plane including a partial structure represented by Formula (SQ-a), or a compound having a π-conjugated plane including a partial structure represented by Formula (CR-a). By using such a compound, the effects of the present invention are more remarkably obtained.

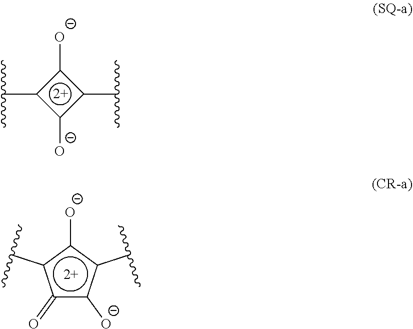

In the formulae, a wavy line represents a bonding hand.

The coloring agent derivative is also preferably a compound having an acid group, a basic group, or a hydrogen-bonding group. In a case where the coloring agent derivative has such a group, dispersion stability of the near-infrared absorbing pigment A can be further improved. Furthermore, it is possible to form a film having more excellent heat resistance and light resistance.

Examples of the acid group include a sulfo group, a carboxyl group, a phosphoric acid group, a boronic acid group, a sulfonimide group, a sulfonamide group, salts of these groups, and a desalted structure of these salts. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. In addition, examples of the desalted structure of the salt include groups in which an atom or an atomic group forming the salt has been eliminated from the above-described salt. For example, a desalted structure of a salt of a carboxyl group is a carboxylate group (—COO⁻)—.

Examples of the basic group include an amino group, a pyridinyl group, salts of these groups, and a desalted structure of these salts. Examples of an atom or atomic group constituting the salts include a hydroxide ion, a halogen ion, a carboxylate ion, a sulfonate ion, and a phenoxide ion. In addition, examples of the desalted structure of the salt include groups in which an atom or an atomic group forming the salt has been eliminated from the above-described salt.

The hydrogen-bonding group refers to a group which interacts with each other through a hydrogen atom. Specific examples of the hydrogen-bonding group include an amide group, a hydroxy group, —NHCONHR, —NHCOOR, and —OCONHR. R is preferably an alkyl group or an aryl group.

The coloring agent derivative preferably has at least one group selected from a sulfo group, a carboxyl group, a phosphoric acid group, a boronic acid group, a sulfonimide group, a sulfonamide group, an amino group, a pyridinyl group, salts of these groups, and a desalted structure of these salts, and more preferably has a sulfo group, a carboxyl group, and an amino group. In a case where the coloring agent derivative has such a group, dispersion stability of the near-infrared absorbing pigment A can be further improved.

It is also preferable that the coloring agent derivative is at least one compound selected from a compound represented by Formula (Syn1) or a compound represented by Formula (Syn2). By using such a compound, the effects of the present invention are more remarkably obtained.

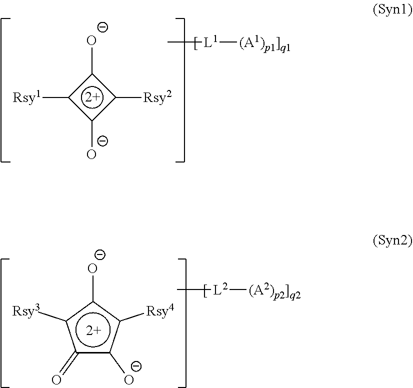

In Formula (Syn1), Rsy¹ and Rsy² each independently represent an organic group; L¹ represents a single bond or a p1+1-valent group; A¹ represents a group selected from a sulfo group, a carboxyl group, a phosphoric acid group, a boronic acid group, a sulfonimide group, a sulfonamide group, an amino group, a pyridinyl group, salts of these groups, and a desalted structure of these; and p1 and q1 each independently represent an integer of 1 or more. In a case where p1 is 2 or more, a plurality of A¹'s may be the same or different from each other. In a case where q1 is 2 or more, a plurality of L¹'s and A¹'s may be respectively the same or different from each other.

In Formula (Syn2), Rsy³ and Rsy⁴ each independently represent an organic group; L² represents a single bond or a p2+1-valent group; A² represents a group selected from a sulfo group, a carboxyl group, a phosphoric acid group, a boronic acid group, a sulfonimide group, a sulfonamide group, an amino group, a pyridinyl group, salts of these groups, and a desalted structure of these; and p2 and q2 each independently represent an integer of 1 or more. In a case where p2 is 2 or more, a plurality of A²'s may be the same or different from each other. In a case where q2 is 2 or more, a plurality of L²'s and A²'s may be respectively the same or different from each other.

Examples of the organic group represented by Rsy¹ and Rsy² in Formula (Syn1) and the organic group represented by Rsy³ and Rsy⁴ in Formula (Syn2) include an aryl group, a heteroaryl group, a group represented by Formula (R1) described above, a group represented by Formula (1) described above, a group represented by Formula (10) described above, a group represented by Formula (20) described above, a group represented by Formula (30) described above, and a group represented by Formula (40) described above. The details and preferred ranges of these are the same as those described in the section of the near-infrared absorbing pigment A described above.

Examples of the p1+1-valent group represented by L¹ in Formula (Syn1) and the p2+1-valent group represented by L² in Formula (Syn2) include a hydrocarbon group, a heterocyclic group, —O—, —S—, —CO—, —COO—, —OCO—, —SO₂—, —NR^{L}—, NR^{L}CO—, —CONR^{L}—, —NR^{L}SO₂—, —SO₂NR^{L}—, a group of a combination of these groups. R^{L} represents a hydrogen atom, an alkyl group, or an aryl group. The hydrocarbon group may be an aliphatic hydrocarbon group or an aromatic hydrocarbon group. Examples of the hydrocarbon group include an alkylene group, an arylene group, and a group obtained by removing one or more hydrogen atoms from these groups. The number of carbon atoms in the alkylene group is preferably 1 to 30, more preferably 1 to 15, and still more preferably 1 to 10. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10. The heterocyclic group is preferably a monocyclic ring or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and still more preferably 3 to 12. The hydrocarbon group and heterocyclic group may have a substituent. Examples of the substituent include groups in the description of the substituent T described above. The number of carbon atoms in the alkyl group represented by R^{L} is preferably 1 to 20, more preferably 1 to 15, and still more preferably 1 to 8. The alkyl group may be linear, branched, or cyclic, and is preferably linear or branched and more preferably linear. The alkyl group represented by R^{L} may further have a substituent. Examples of the substituent include the substituent T described above. The number of carbon atoms in the aryl group represented by R^{L} is preferably 6 to 30, more preferably 6 to 20, and still more preferably 6 to 12. The aryl group represented by R^{L} may further have a substituent. Examples of the substituent include the above-described substituent T.

L¹ in Formula (Syn1) is preferably a p1+1-valent group. In addition, L² in Formula (Syn2) is preferably a p2+1-valent group. In addition, in the compound represented by Formula (Syn1), it is preferable that the mother nucleus and the group represented by A¹ are separated by one or more atoms through the p1+1-valent group represented by L¹, and it is more preferable to be separated by three or more atoms. In addition, in the compound represented by Formula (Syn2), it is preferable that the mother nucleus and the group represented by A² are separated by one or more atoms through the p2+1-valent group represented by L², and it is more preferable to be separated by three or more atoms. According to this aspect, more excellent dispersion stability is easily obtained.

Specific examples of the coloring agent derivative include compounds having the following structures.

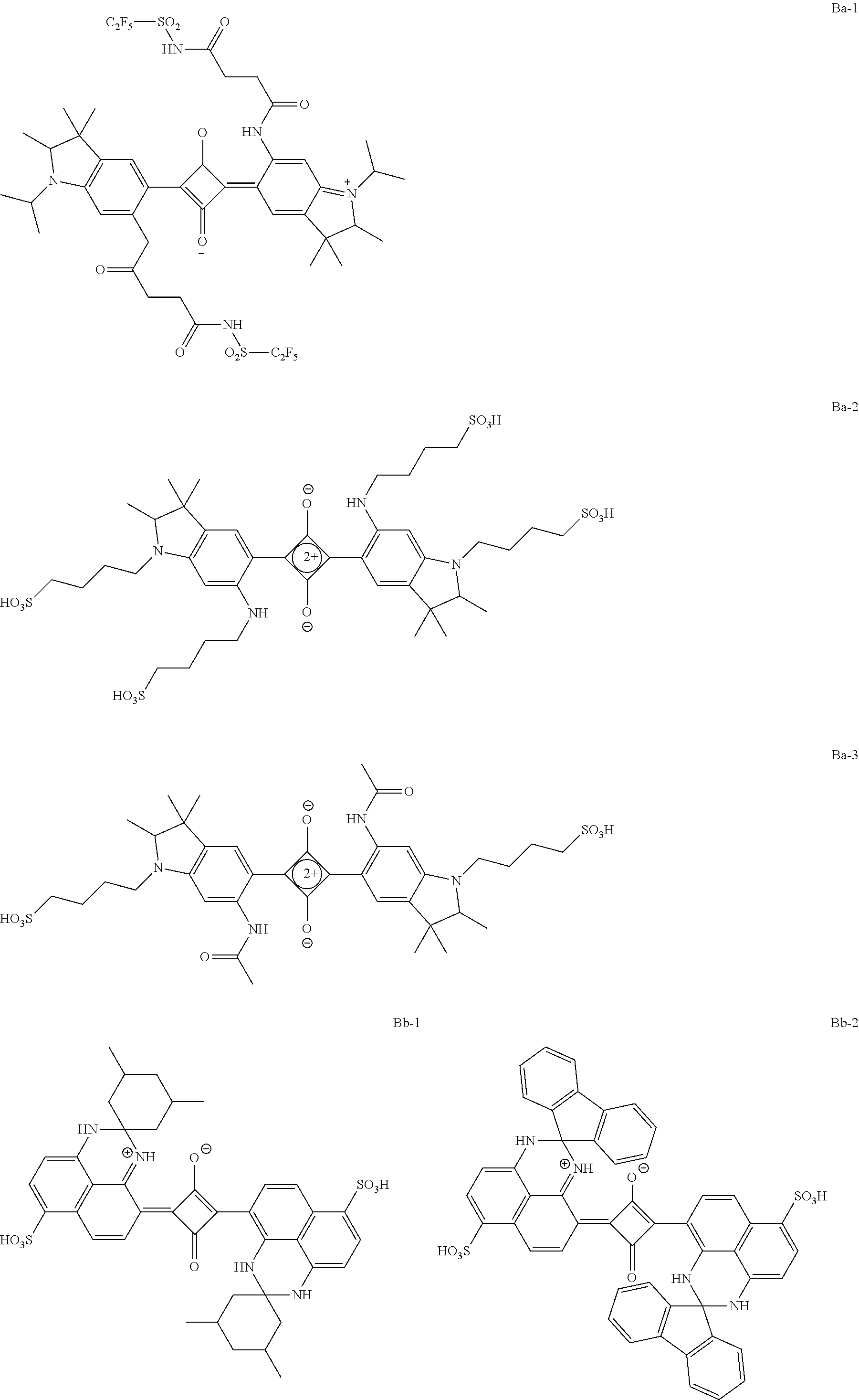

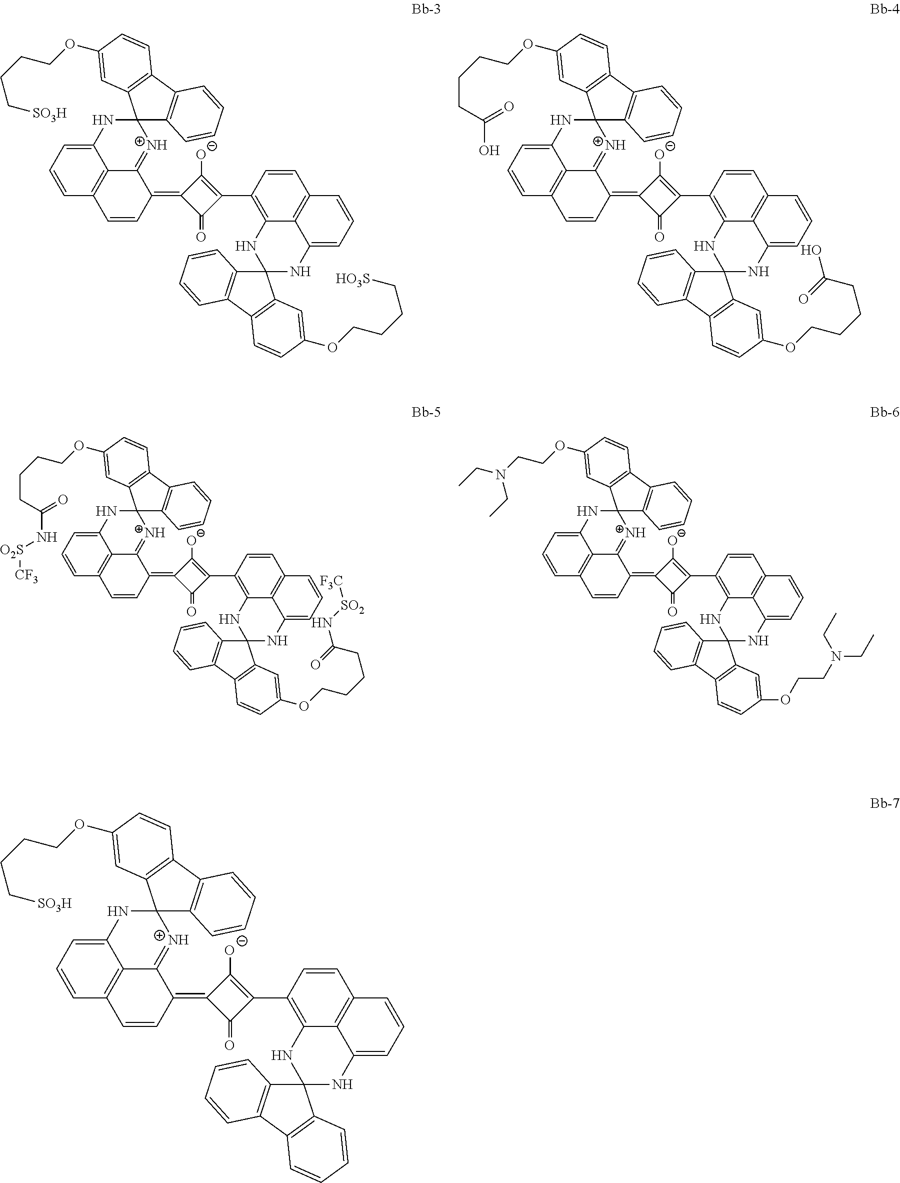

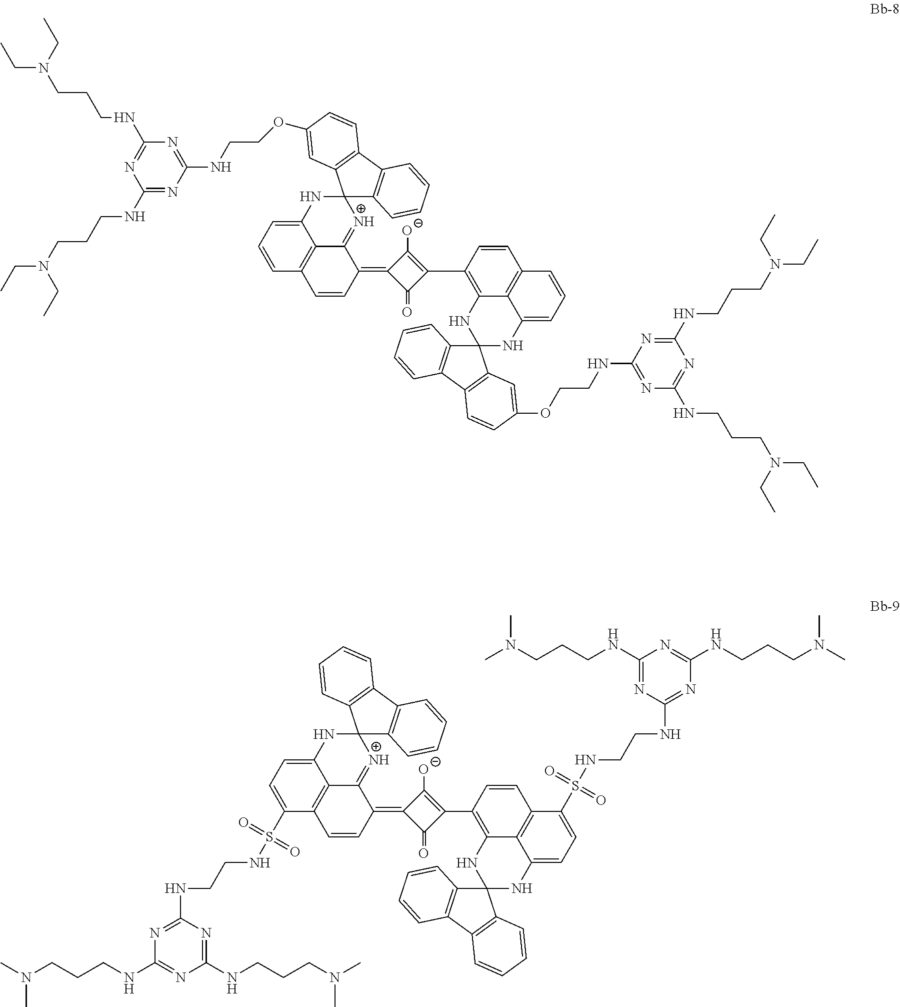

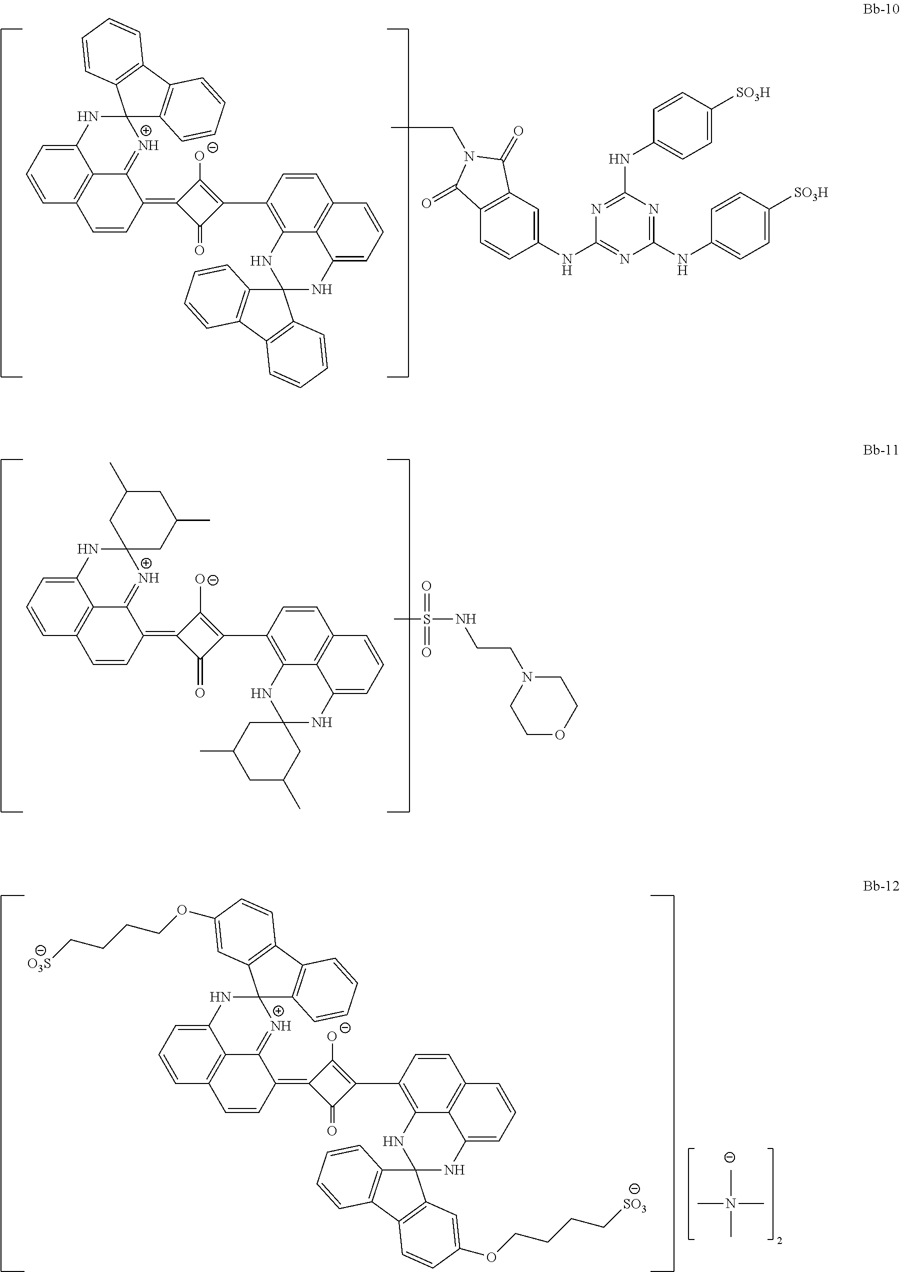

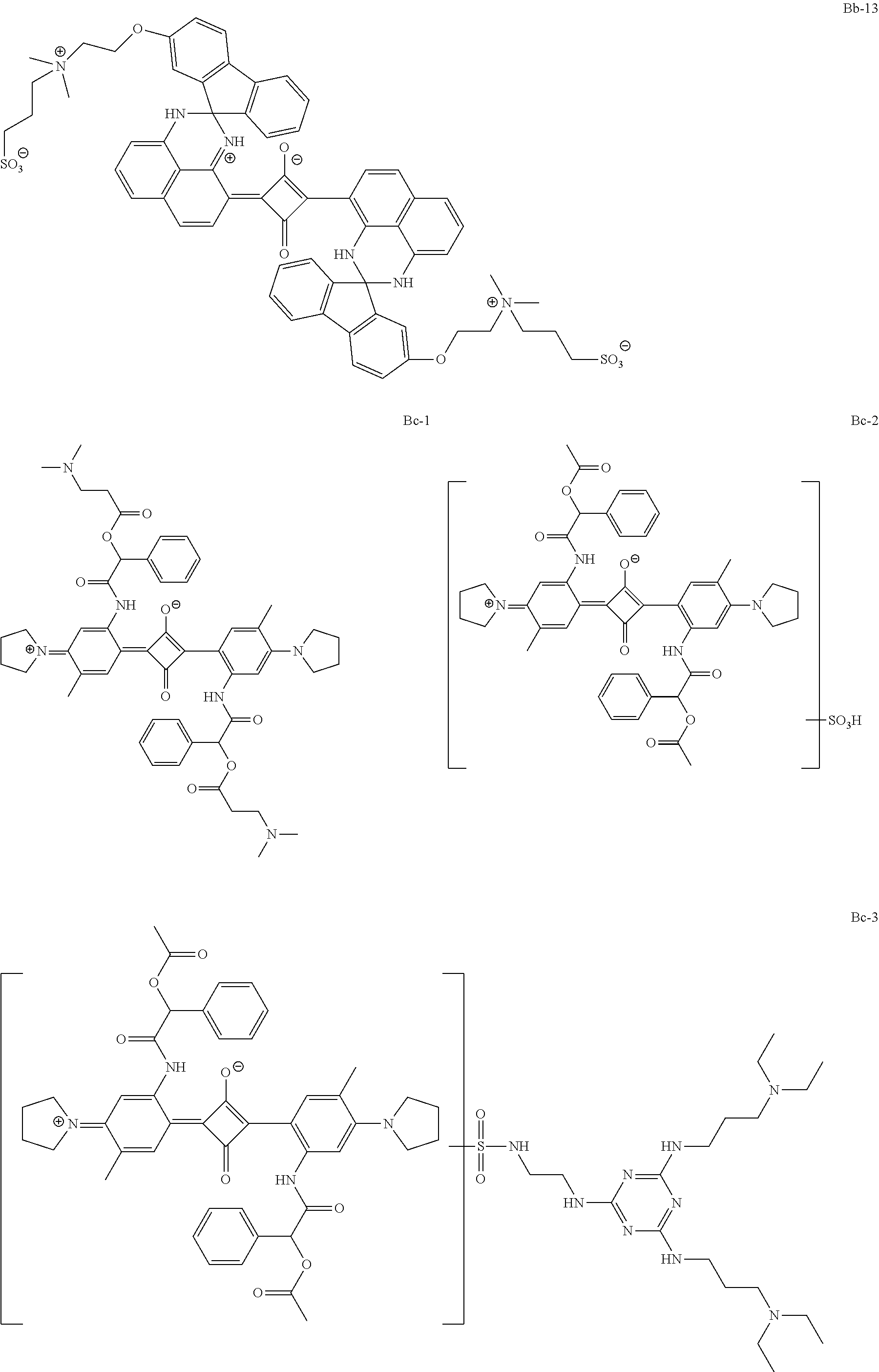

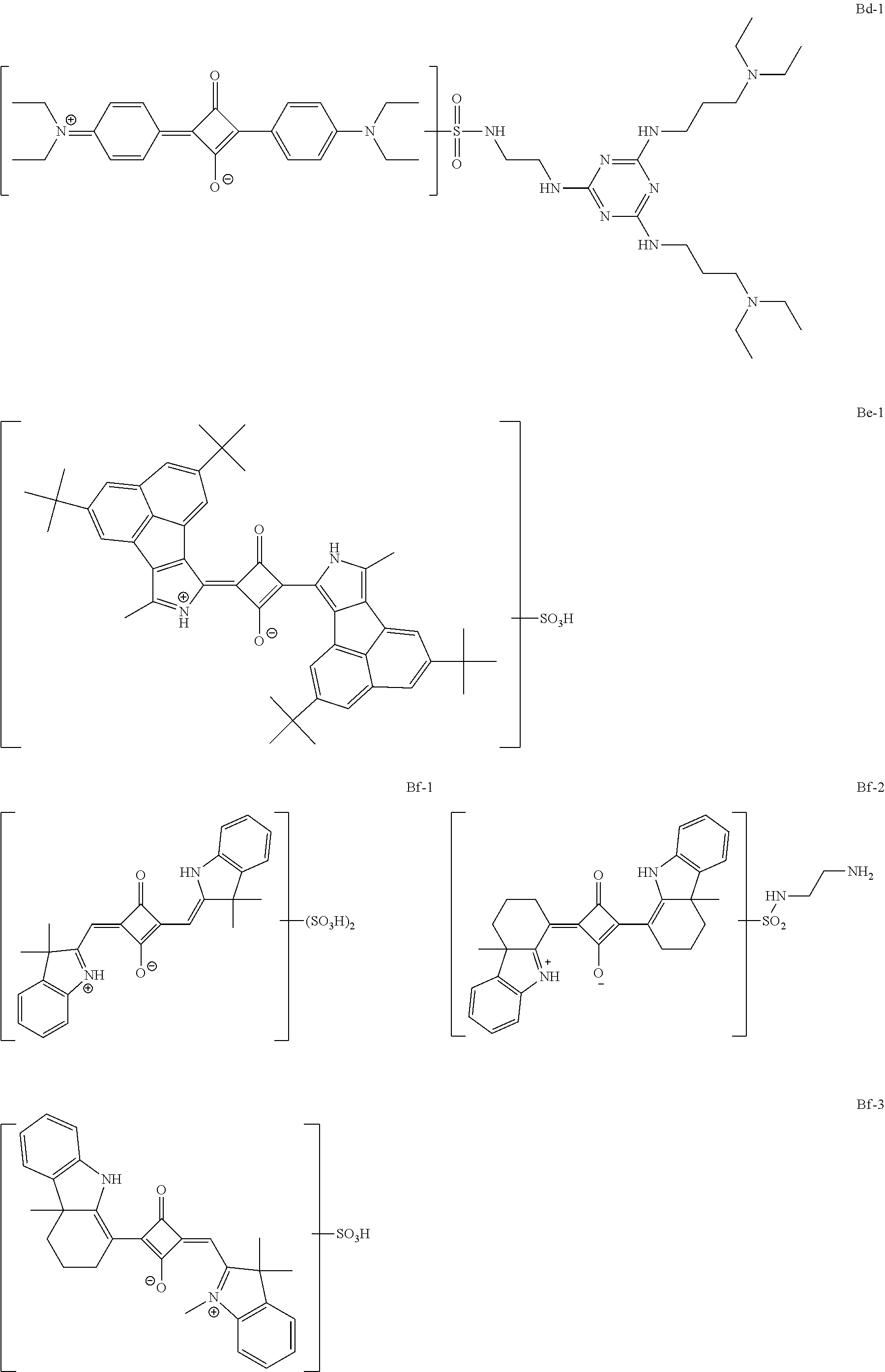

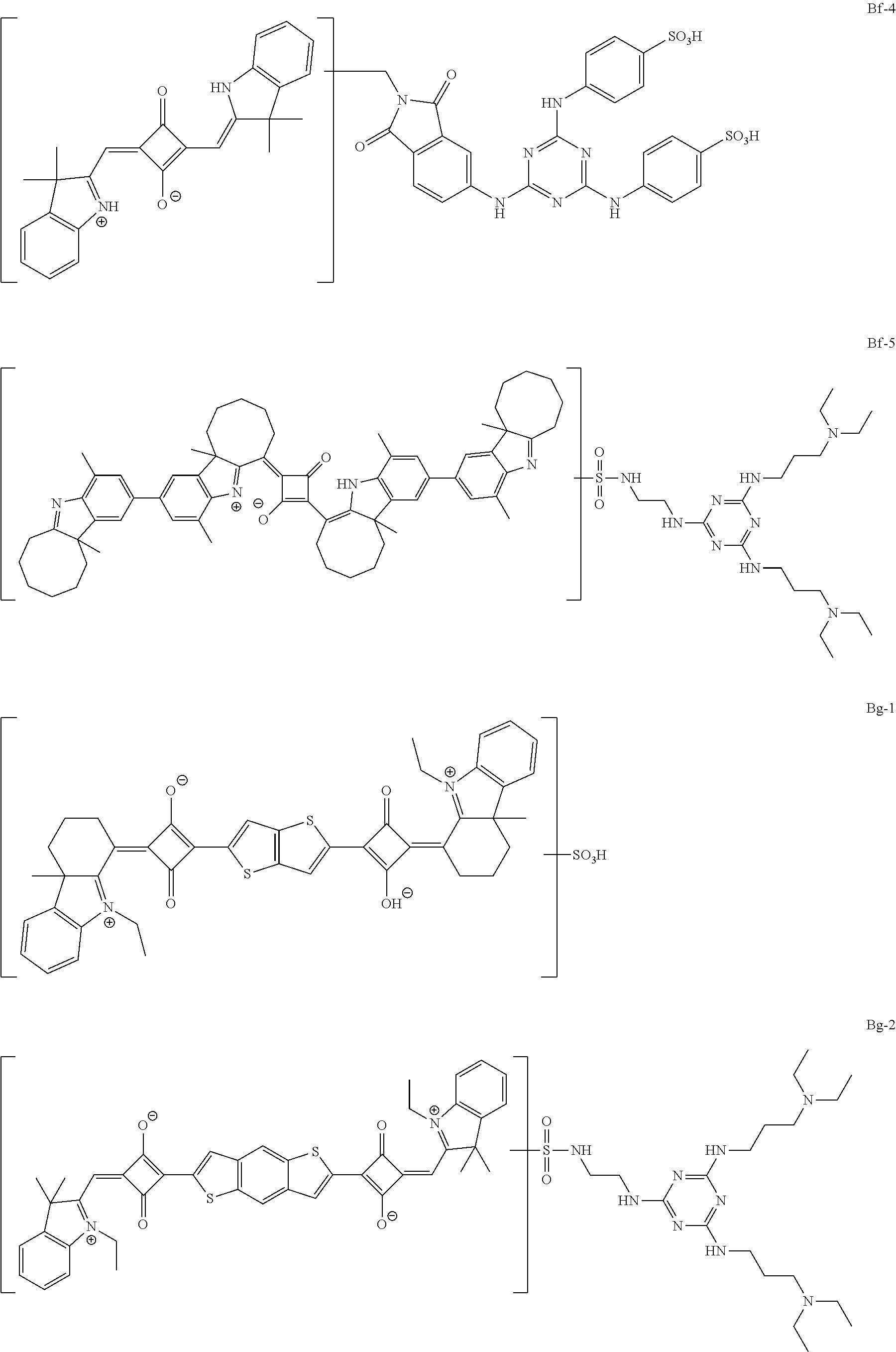

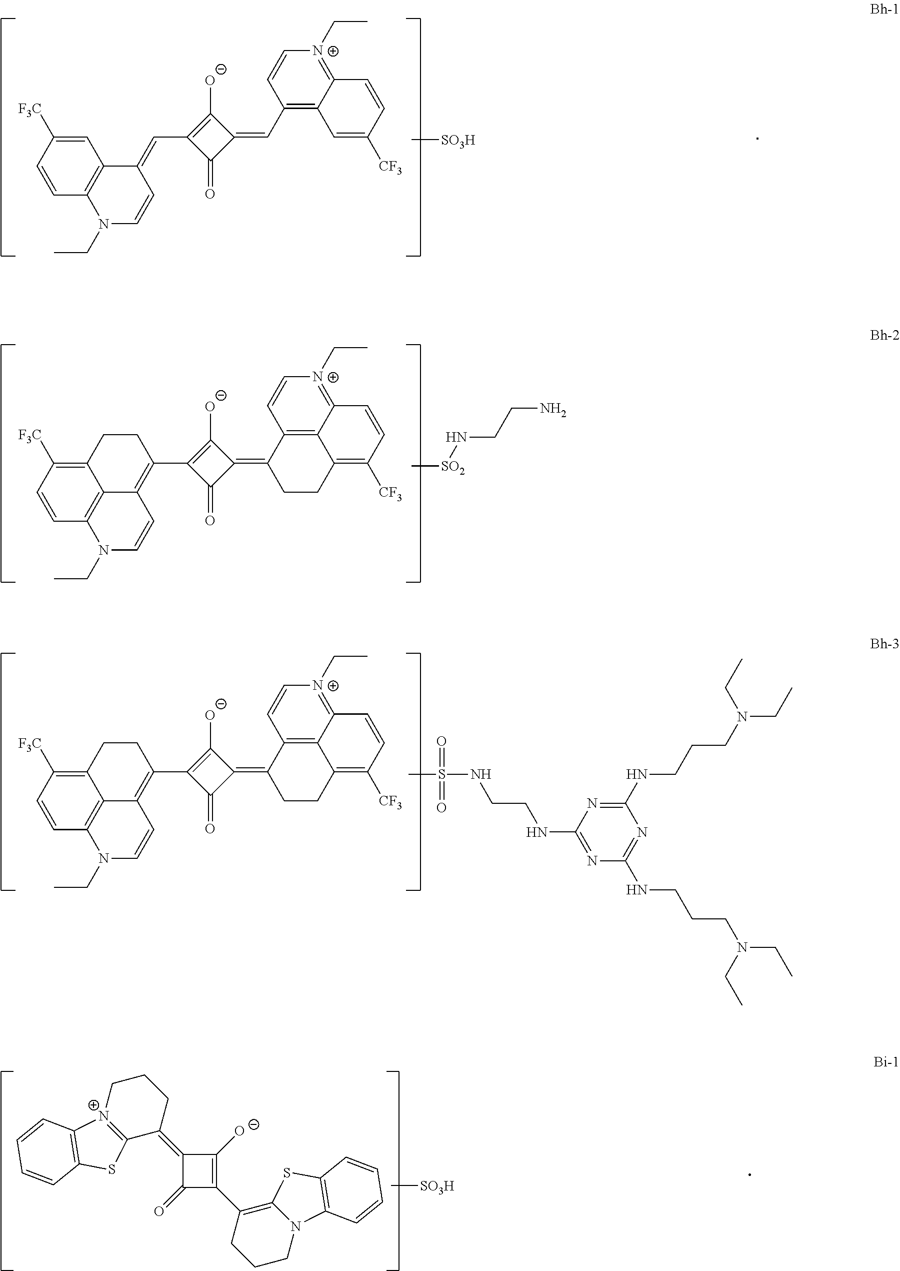

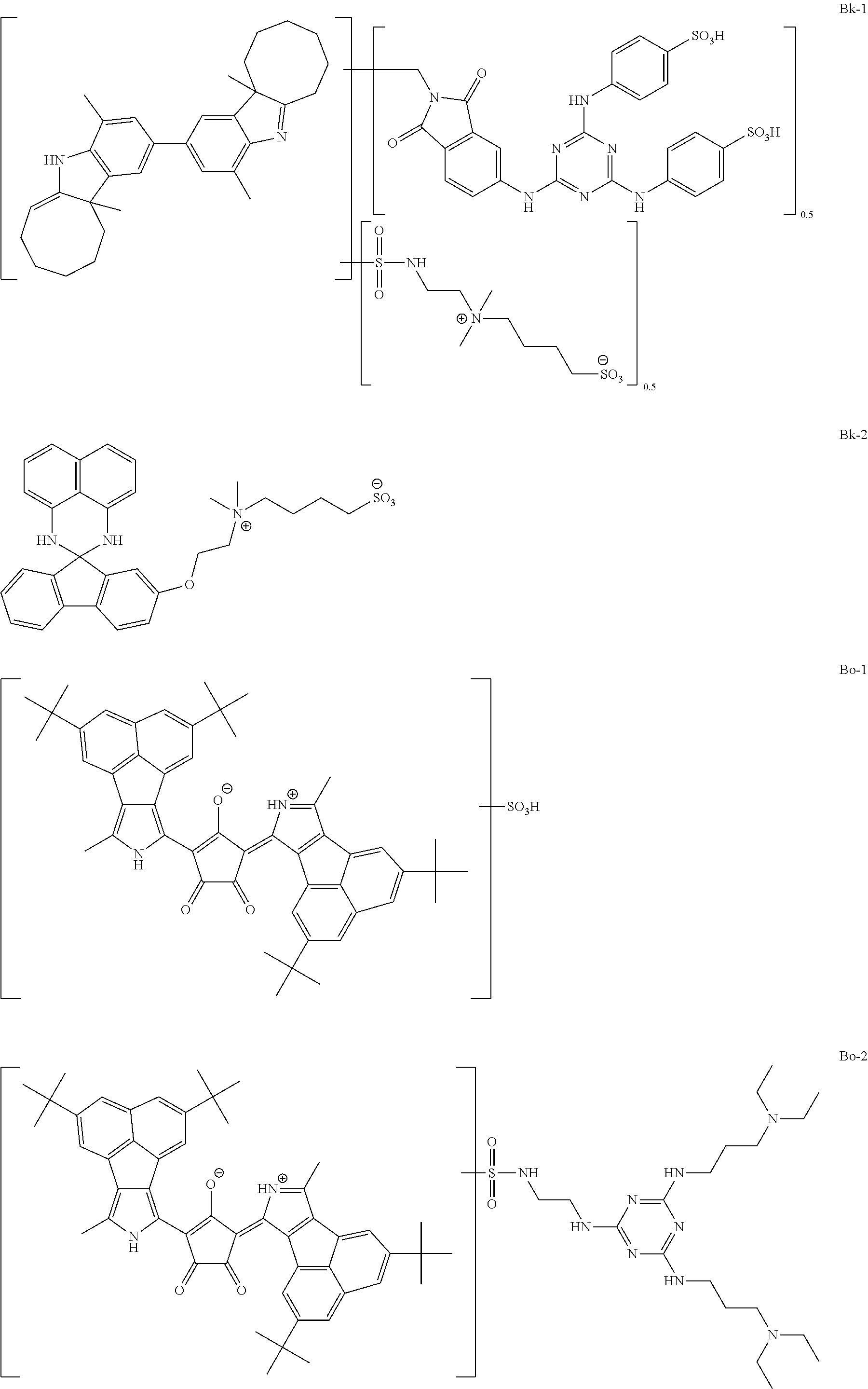

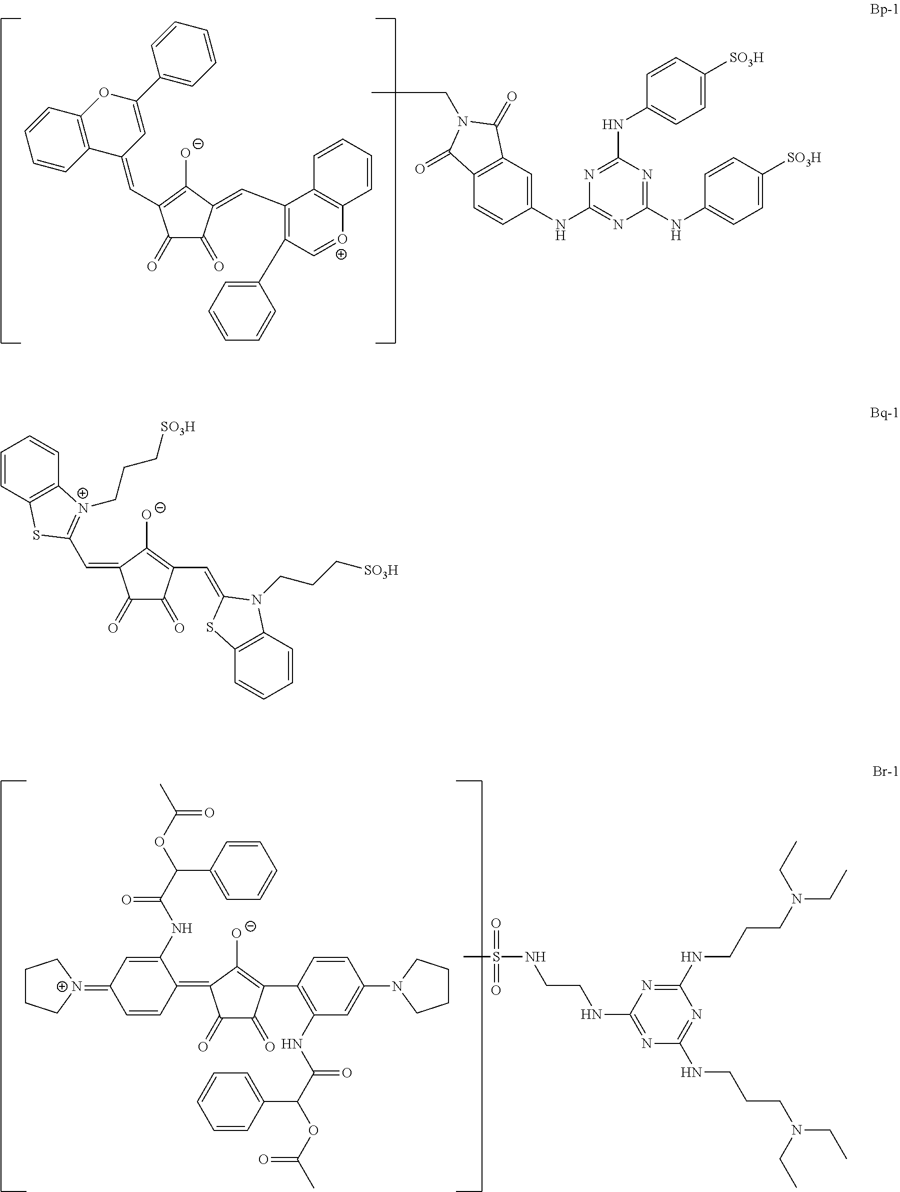

In the near-infrared absorbing composition according to the embodiment of the present invention, the content of the coloring agent derivative is 0.5 to 25 parts by mass with respect to 100 parts by mass of the near-infrared absorbing pigment. The lower limit value is preferably 1.5 parts by mass or more, more preferably 2.5 parts by mass or more, and still more preferably 3 parts by mass. The upper limit value is preferably 20 parts by mass or less, more preferably 17.5 parts by mass or less, and still more preferably 15 parts by mass. In addition, the content of the coloring agent derivative in the total solid content of the near-infrared absorbing composition is preferably 0.0005 to 17.5 mass %. The lower limit is more preferably 0.01 mass % or more and still more preferably 0.1 mass % or more. The upper limit is more preferably 15 mass % or less and still more preferably 10 mass % or less. In a case where the near-infrared absorbing composition according to the embodiment of the present invention includes two or more kinds of coloring agent derivatives, it is preferable that the total content thereof is within the above-described range.

<<Other Near-Infrared Absorbers>>

The near-infrared absorbing composition according to the embodiment of the present invention can contain a near-infrared absorber (other near-infrared absorbers) other than the above-described near-infrared absorbing pigment A. Examples of the other near-infrared absorbers include a pyrrolopyrrole compound, a cyanine compound, a phthalocyanine compound, a naphthalocyanine compound, a quaterrylene compound, a merocyanine compound, an oxonol compound, an iminium compound, a dithiol compound, a triarylmethane compound, a pyrromethene compound, an azomethine compound, an anthraquinone compound, a dibenzofuranone compound, a metal oxide, and a metal boride. Examples of the pyrrolopyrrole compound include compounds described in paragraphs “0016” to “0058” of JP2009-263614A, compounds described in paragraphs “0037” to “0052” of JP2011-068731 A, and compounds described in paragraphs “0010” to “0033” of WO2015/166873A. Examples of the squarylium compound include compounds described in paragraphs “0044” to “0049” of JP2011-208101 A, compounds described in paragraphs “0060” and “0061” of JP6065169B, compounds described in paragraph “0040” of WO2016/181987A, compounds described in JP2015-176046A, compounds described in paragraph “0072” of WO2016/190162A, compounds described in paragraphs “0196” to “0228” of JP2016-074649A, compounds described in paragraph “0124” of JP2017-067963A, compounds described in WO2017/135359A, compounds described in JP2017-114956A, compounds described in JP6197940B, and compounds described in WO2016/120166A. Examples of the cyanine compound include compounds described in paragraphs “0044” and “0045” of JP2009-108267A, compounds described in paragraphs “0026” to “0030” of JP2002-194040A, compounds described in JP2015-172004A, compounds described in JP2015-172102A, compounds described in JP2008-088426A, and compounds described in paragraph “0090” of WO2016/190162A. Examples of the iminium compound include compounds described in JP2008-528706A, compounds described in JP2012-012399A, compounds described in JP2007-092060A, and compounds described in paragraphs “0048” to “0063” of WO2018/043564A. Examples of the phthalocyanine compound include compounds described in paragraph “0093” of JP2012-077153A, oxytitanium phthalocyanine described in JP2006-343631A, and compounds described in paragraphs “0013” to “0029” of JP2013-195480A. Examples of the naphthalocyanine compound include compounds described in paragraph “0093” of JP2012-077153A. Examples of the metal oxide include indium tin oxide, antimony tin oxide, zinc oxide, Al-doped zinc oxide, fluorine-doped tin dioxide, niobium-doped titanium dioxide, and tungsten oxide. The details of tungsten oxide can be found in paragraph “0080” of JP2016-006476A, the content of which is incorporated herein by reference. Examples of the metal boride include lanthanum boride. Examples of a commercially available product of lanthanum boride include LaB6-F (manufactured by JAPAN NEW METALS CO., LTD.). In addition, as the metal boride, compounds described in WO2017/119394A can also be used. Examples of a commercially available product of indium tin oxide include F-ITO (manufactured by DOWA HIGHTECH CO., LTD.).

In a case where the near-infrared absorbing composition according to the embodiment of the present invention contains other near-infrared absorbers, the content of the other near-infrared absorbers is preferably 0.1 to 70 mass % with respect to the total solid content of the near-infrared absorbing composition according to the embodiment of the present invention. The lower limit is preferably 0.5 mass % or more and more preferably 1.0 mass % or more. The upper limit is preferably 60 mass % or less and more preferably 50 mass % or less.

In addition, the total content of the other near-infrared absorbers and the above-described near-infrared absorbing pigment A is preferably 0.1 to 70 mass % with respect to the total solid content of the near-infrared absorbing composition according to the embodiment of the present invention. The lower limit is preferably 0.5 mass % or more and more preferably 1.0 mass % or more. The upper limit is preferably 60 mass % or less and more preferably 50 mass % or less. In a case where the near-infrared absorbing composition according to the embodiment of the present invention includes two or more kinds of other near-infrared absorbers, it is preferable that the total content thereof is within the above-described range.

In addition, the near-infrared absorbing composition according to the embodiment of the present invention may be in an aspect in which the near-infrared absorbing composition according to the embodiment of the present invention does not substantially contain other near-infrared absorbers. The aspect in which the near-infrared absorbing composition according to the embodiment of the present invention does not substantially contain other near-infrared absorbers is preferably an aspect in which the content of the other near-infrared absorbers is 0.05 mass % or less with respect to the total solid content of the near-infrared absorbing composition, more preferably an aspect in which the content of the other near-infrared absorbers is 0.01 mass % or less with respect to the total solid content of the near-infrared absorbing composition, and still more preferably an aspect in which the other near-infrared absorbers are not contained.

<<Chromatic Colorant>>

The near-infrared absorbing composition according to the embodiment of the present invention may contain a chromatic colorant. In the present invention, “chromatic colorant” denotes a colorant other than a white colorant and a black colorant. Examples of the chromatic colorant include yellow colorants, orange colorants, red colorants, green colorants, violet colorants, and blue colorants. The chromatic colorant may be a pigment or a dye.

The coloring material may be used in combination of the pigment and the dye. In addition, the pigment may be either an inorganic pigment or an organic pigment. In addition, as the pigment, a material in which a part of an inorganic pigment or an organic-inorganic pigment is replaced with an organic chromophore can also be used. By replacing a part of an inorganic pigment or an organic-inorganic pigment with an organic chromophore, color tone design can be easily performed. Examples of the pigment include the following pigments:

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 231, and 232 (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, and 294 (all of which are red pigments);

C. I. Pigment Green 7, 10, 36, 37, 58, 59, 62, and 63 (all of which are green pigments);

C. I. Pigment Violet 1, 19, 23, 27, 32, 37, 42, 60, and 61 (all of which are violet pigments); and

C. I. Pigment Blue 1, 2, 15, 15:1, 15:2, 15:3, 15:4, 15:6, 16, 22, 29, 60, 64, 66, 79, 80, 87, and 88 (all of which are blue pigments).

In addition, as the green pigment, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include compounds described in WO2015/118720A. In addition, as the green pigment, compounds described in CN2010-6909027A, a phthalocyanine compound having a phosphoric acid ester as a ligand, or the like can also be used.

In addition, as the blue pigment, an aluminum phthalocyanine compound having a phosphorus atom can also be used. Specific examples thereof include compounds described in paragraphs “0022” to “0030” of JP2012-247591A and paragraph “0047” of JP2011-157478A.

In addition, as the yellow pigment, pigments described in JP2017-201003A and pigments described in JP2017-197719A can be used. In addition, as the yellow pigment, a metal azo pigment which includes at least one kind of an anion selected from an azo compound represented by Formula (I) or an azo compound having a tautomeric structure of the azo compound represented by Formula (I), two or more kinds of metal ions, and a melamine compound can also be used.

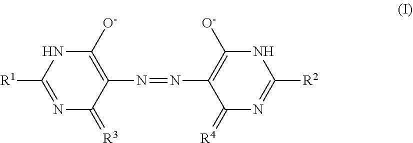

In the formula, R¹ and R² each independently represent —OH or —NR⁵R⁶, and R³ and R⁴ each independently represent ═O or ═NR⁷, in which R⁵ to R⁷ each independently represent a hydrogen atom or an alkyl group. The number of carbon atoms in the alkyl group represented by R⁵ to R⁷ is preferably 1 to 10, more preferably 1 to 6, and still more preferably 1 to 4. The alkyl group may be linear, branched, or cyclic, and is preferably linear or branched and more preferably linear. The alkyl group may have a substituent. The substituent is preferably a halogen atom, a hydroxy group, an alkoxy group, a cyano group, or an amino group.

With regard to the metal azo pigment, reference can be made to the description in paragraphs “0011” to “0062” and “0137” to “0276” of JP2017-171912A, paragraphs “0010” to “0062” and “0138” to “0295” of JP2017-171913A, paragraphs “0011” to “0062” and “0139” to “0190” of JP2017-171914A, and paragraphs “0010” to “0065” and “0142” to “0222” of JP2017-171915 A, the contents of which are incorporated herein by reference.

In addition, as the yellow pigment, compounds described in JP2018-062644A can also be used. These compounds can also be used as a pigment derivative.

As the red pigment, diketopyrrolopyrrole-based pigments described in JP2017-201384A, in which the structure has at least one substituted bromine atom, diketopyrrolopyrrole-based pigments described in paragraphs “0016” to “0022” of JP6248838B, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

As the dye, a known dye can be used without any particular limitation. Examples thereof include a pyrazoleazo-based dye, an anilinoazo-based dye, a triarylmethane-based dye, an anthraquinone-based dye, an anthrapyridone-based dye, a benzylidene-based dye, an oxonol-based dye, a pyrazolotriazoleazo-based dye, a pyridoneazo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethane-based dye. In addition, thiazole compounds described in JP2012-158649A, azo compounds described in JP2011-184493A, or azo compounds described in JP2011-145540A can also be preferably used. In addition, as yellow dyes, quinophthalone compounds described in paragraphs “0011” to “0034” of JP2013-054339A, quinophthalone compounds described in paragraphs “0013” to “0058” of JP2014-026228A, or the like can also be used.

In a case where the near-infrared absorbing composition according to the embodiment of the present invention contains a chromatic colorant, the content of the chromatic colorant is preferably 0.1 to 70 mass % with respect to the total solid content of the near-infrared absorbing composition according to the embodiment of the present invention. The lower limit is preferably 0.5 mass % or more and more preferably 1.0 mass % or more. The upper limit is preferably 60 mass % or less and more preferably 50 mass % or less.

The content of the chromatic colorant is preferably 10 to 1000 parts by mass and more preferably 50 to 800 parts by mass with respect to 100 parts by mass of the above-described near-infrared absorbing pigment A.

In addition, the total content of the chromatic colorant, the above-described near-infrared absorbing pigment A, and the above-described other near-infrared absorbers is preferably 1 to 80 mass % with respect to the total solid content of the near-infrared absorbing composition according to the embodiment of the present invention. The lower limit is preferably 5 mass % or more and more preferably 10 mass % or more. The upper limit is preferably 70 mass % or less and more preferably 60 mass % or less. In a case where the near-infrared absorbing composition according to the embodiment of the present invention includes two or more kinds of chromatic colorants, it is preferable that the total content thereof is within the above-described range.

In addition, it is also preferable that the near-infrared absorbing composition according to the embodiment of the present invention does not substantially contain the chromatic colorant. A case where the near-infrared absorbing composition according to the embodiment of the present invention does not substantially contain the chromatic colorant represents that the content of the chromatic colorant is preferably 0.05 mass % or less, more preferably 0.01 mass % or less, and still more preferably 0 mass % with respect to the total solid content of the near-infrared absorbing composition.

<<Coloring Material which allows Transmission of Infrared Light and Shields Visible Light>>

The near-infrared absorbing composition according to the embodiment of the present invention can also contain a coloring material which allows transmission of infrared light and shields visible light (hereinafter, also referred to as a “coloring material which shields visible light”).

In the present invention, it is preferable that the coloring material which shields visible light is a coloring material which absorbs light in a wavelength range of violet to red. In addition, in the present invention, it is preferable that the coloring material which shields visible light is a coloring material which shields light in a wavelength range of 450 to 650 nm.

In addition, it is preferable that the coloring material which shields visible light is a coloring material which allows transmission of light in a wavelength range of 900 to 1300 nm.

In the present invention, it is preferable that the coloring material which shields visible light satisfies at least one of the following requirement (A) or (B).

(A): coloring material which shields visible light includes two or more chromatic colorants, and a combination of the two or more chromatic colorants forms black.

(B): coloring material which shields visible light includes an organic black colorant.

Examples of the chromatic colorant include the above-described chromatic colorants. Examples of the organic black colorant include a bisbenzofuranone compound, an azomethine compound, a perylene compound, and an azo compound. Among these, a bisbenzofuranone compound or a perylene compound is preferable. Examples of the bisbenzofuranone compound include compounds described in JP2010-534726A, JP2012-515233A, JP2012-515234A, WO2014/208348A, JP2015-525260A, and the like, and the bisbenzofuranone compound is available, for example, as “Irgaphor Black” manufactured by BASF. Examples of the perylene compound include compounds described in paragraphs “0016” to “0020” of JP2017-226821 A, C. I. Pigment Black 31 and 32, and Lumogen Black FK4280. Examples of the azomethine compound include compounds described in JP1989-170601A (JP-H01-170601 A) and JP1990-034664A (JP-H02-034664A). For example, “CHROMOFINE BLACK A1103” (manufactured by Dainichiseika Color & Chemicals Mfg. Co., Ltd.) is available.

In a case where a combination of two or more chromatic colorants forms black, examples of the combination of the chromatic colorants include the following.

(1) aspect in which the coloring material which shields visible light contains a yellow colorant, a blue colorant, a violet colorant, and a red colorant

(2) aspect in which the coloring material which shields visible light contains a yellow colorant, a blue colorant, and a red colorant

(3) aspect in which the coloring material which shields visible light contains a yellow colorant, a violet colorant, and a red colorant

(4) aspect in which the coloring material which shields visible light contains a yellow colorant and a violet colorant

(5) aspect in which the coloring material which shields visible light contains a green colorant, a blue colorant, a violet colorant, and a red colorant

(6) aspect in which the coloring material which shields visible light contains a violet colorant and an orange colorant

(7) aspect in which the coloring material which shields visible light contains a green colorant, a violet colorant, and a red colorant

(8) aspect in which the coloring material which shields visible light contains a green colorant and a red colorant

In a case where the near-infrared absorbing composition according to the embodiment of the present invention contains a coloring material which shields visible light, the content of the coloring material which shields visible light is preferably 60 mass % or less, more preferably 50 mass % or less, still more preferably 30 mass % or less, even more preferably 20 mass % or less, and particularly preferably 15 mass % or less with respect to the total solid content of the near-infrared absorbing composition. The lower limit may be, for example, 0.1 mass % or more or 0.5 mass % or more.

In addition, it is also preferable that the near-infrared absorbing composition according to the embodiment of the present invention does not substantially contain the coloring material which shields visible light. A case where the near-infrared absorbing composition according to the embodiment of the present invention does not substantially contain coloring material which shields visible light represents that the content of the coloring material which shields visible light is preferably 0.05 mass % or less, more preferably 0.01 mass % or less, and still more preferably 0 mass % with respect to the total solid content of the near-infrared absorbing composition.

<<Polymerizable Compound>>

The near-infrared absorbing composition according to the embodiment of the present invention preferably contains a polymerizable compound. As the polymerizable compound, a known compound which is cross-linkable by a radical, an acid, or heat can be used. In the present invention, the polymerizable compound is preferably, for example, a compound having an ethylenically unsaturated bonding group. Examples of the ethylenically unsaturated bonding group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bonding groups, more preferably a compound including 3 to 15 ethylenically unsaturated bonding groups, and still more preferably a compound having 3 to 6 ethylenically unsaturated bonding groups. In addition, the polymerizable compound is preferably a 3-functional to 15-functional (meth)acrylate compound and more preferably a 3-functional to 6-functional (meth)acrylate compound. Specific examples of the polymerizable compound include compounds described in paragraphs “0095” to “0108” of JP2009-288705A, paragraph “0227” of JP2013-029760A, paragraphs “0254” to “0257” of JP2008-292970A, paragraphs “0034” to “0038” of JP2013-253224A, paragraph “0477” of JP2012-208494A, JP2017-048367A, JP6057891B, and JP6031807B, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which the (meth)acryloyl group of these compounds is bonded through an ethylene glycol and/or a propylene glycol residue (for example, SR454 and SR499 which are commercially available from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethylencoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, the polymerizable compound in an unexposed area is easily removed during development and the generation of the development residue can be suppressed. Examples of the acid group include a carboxyl group, a sulfo group, and a phosphoric acid group, and a carboxyl group is preferable. Examples of a commercially available product of the polymerizable compound having an acid group include ARONIX M-510, M-520, and ARONIX TO-2349 (manufactured by TOAGOSEI CO., LTD.). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

The polymerizable compound is preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a 3-functional to 6-functional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having four ethyleneoxy groups, and KAYARAD TPA-330 manufactured by Nippon Kayaku Co., Ltd, which is a trifunctional (meth)acrylate having three isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

The content of the polymerizable compound in the total solid content of the near-infrared absorbing composition is preferably 0.1 to 60 mass %. The lower limit is more preferably 0.5 mass % or more and still more preferably 1 mass % or more. The upper limit is more preferably 55 mass % or less and still more preferably 50 mass % or less. In a case where the near-infrared absorbing composition according to the embodiment of the present invention includes two or more kinds of polymerizable compounds, it is preferable that the total content thereof is within the above-described range.

<<Photopolymerization Initiator>>

The near-infrared absorbing composition according to the embodiment of the present invention preferably contains a photopolymerization initiator. The photopolymerization initiator can be appropriately selected from known photopolymerization initiators. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, and an acylphosphine compound is more preferable, and an oxime compound is still more preferable. The details of the photopolymerization initiator can be found in paragraphs “0065” to “0111” of JP2014-130173A and in JP6301489B, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all of which are manufactured by BASF). Examples of a commercially available product of the α-aminoketone compound include IRGACURE-907, IRGACURE-369, IRGACURE-379, and IRGACURE-379EG (all of which are manufactured by BASF). Examples of a commercially available product of the acylphosphine compound include IRGACURE-819 and DAROCUR-TPO (both of which are manufactured by BASF).

Examples of the oxime compound include compounds described in JP2001-233842A, compounds described in JP2000-080068A, compounds described in JP2006-342166A, compounds described in J. C. S. Perkin II (1979, pp. 1653-1660), compounds described in J. C. S. Perkin II (1979, pp. 156-162), compounds described in Journal of Photopolymer Science and Technology (1995, pp. 202-232), compounds described in JP2000-066385A, compounds described in JP2004-534797A, compounds described in JP2006-342166A, compounds described in JP2017-019766A, compounds described in JP6065596B, compounds described in WO2015/152153A, compounds described in WO2017/051680A, compounds described in JP2017-198865A, and compounds described in paragraphs “0025” to “0038” of WO2017/164127A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include IRGACURE-OXE01, IRGACURE-OXE02, IRGACURE-OXE03, and IRGACURE-OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no coloring property or a compound having high transparency and being resistant to discoloration. Examples of a commercially available product thereof include ADEKA ARKLS NCI-730, NCI-831, and NCI-930 (all of which are manufactured by ADEKA Corporation).

In the present invention, an oxime compound having a fluorene ring can also be used as the photopolymerization initiator. Specific examples of the oxime compound having a fluorene ring include compounds described in JP2014-137466A. The content thereof is incorporated herein by reference.

In the present invention, an oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A. The content thereof is incorporated herein by reference.

In the present invention, an oxime compound having a nitro group can be used as the photopolymerization initiator. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and ADEKA ARKLS NCI-831 (manufactured by ADEKA Corporation).

In the present invention, an oxime compound having a benzofixran skeleton can also be used as the photopolymerization initiator. Specific examples thereof include OE-01 to OE-75 described in WO2015/036910A.

Specific examples of the oxime compound which are preferably used in the present invention are shown below, but the present invention is not limited thereto.

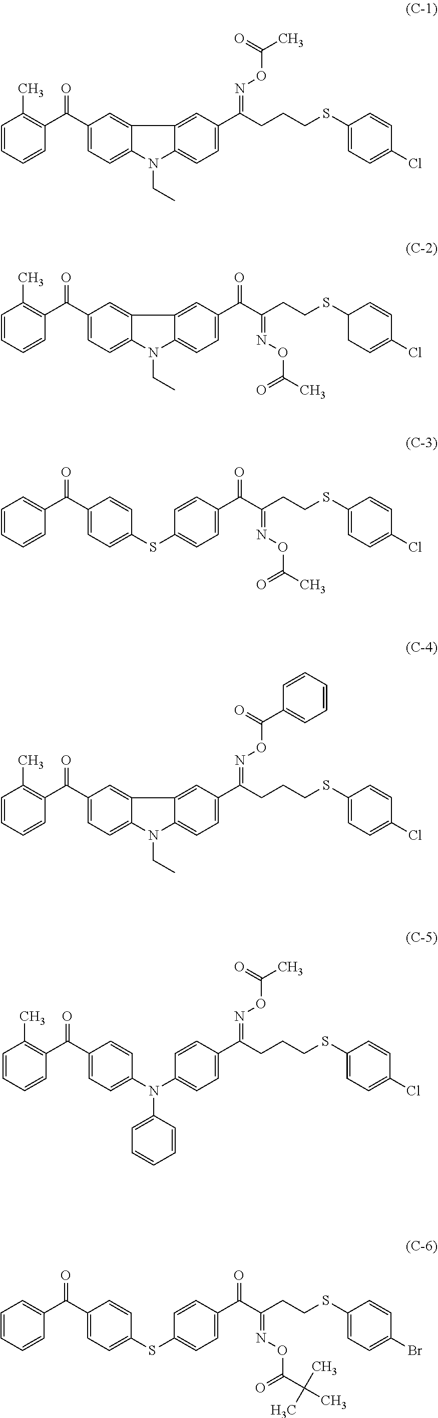 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSC3C=CC(Cl)=CC3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

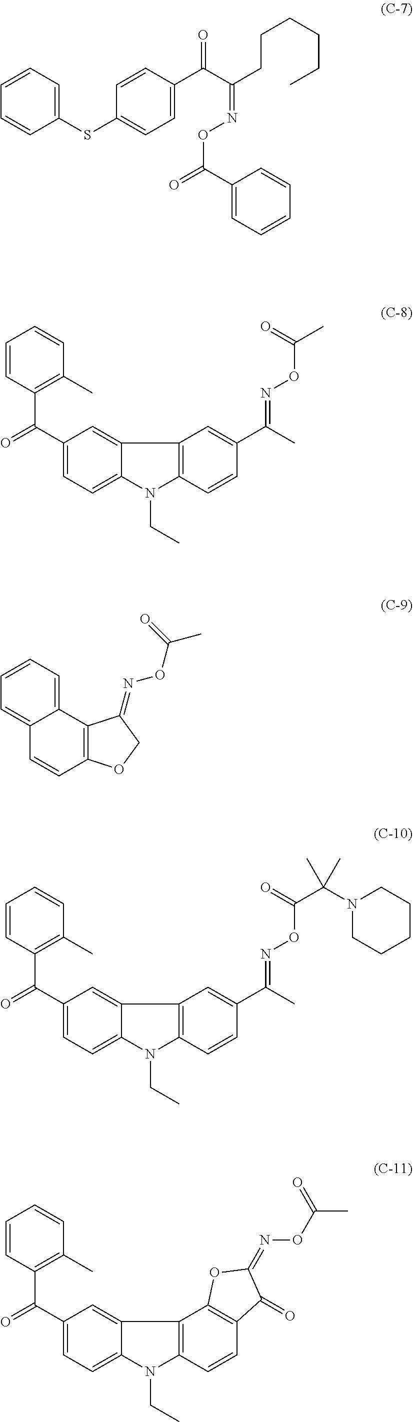 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

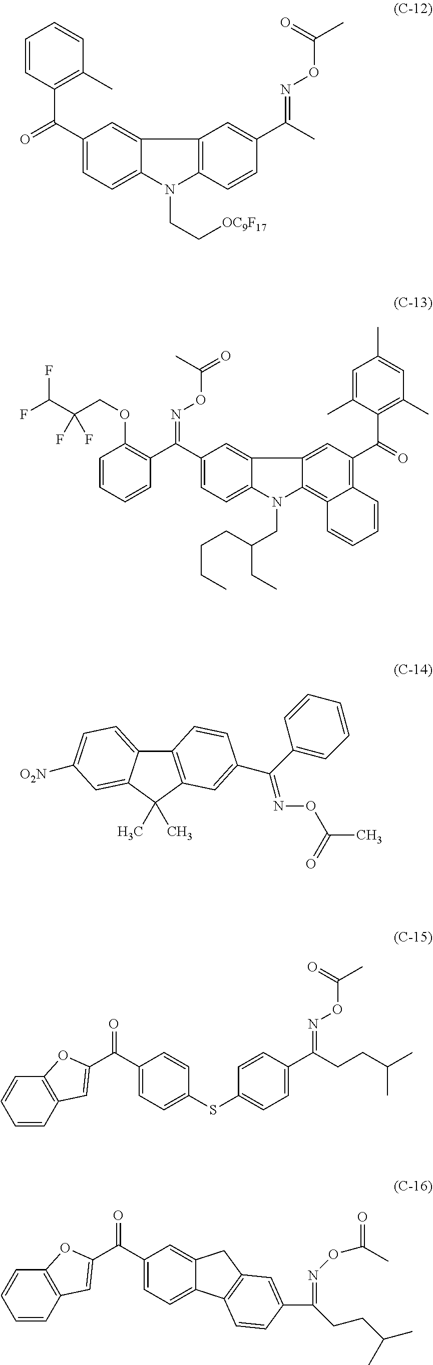

The oxime compound is preferably a compound having a maximum absorption wavelength in a wavelength range of 350 to 500 nm and more preferably a compound having a maximum absorption wavelength in a wavelength range of 360 to 480 nm. In addition, from the viewpoint of sensitivity, the molar absorption coefficient of the oxime compound at a wavelength of 365 nm or at a wavelength of 405 nm is preferably high, more preferably 1,000 to 300,000, still more preferably 2,000 to 300,000, and particularly preferably 5,000 to 200,000. The molar absorption coefficient of a compound can be measured using a well-known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

In the present invention, as the photopolymerization initiator, a bifunctional or tri- or more functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the composition can be improved. Specific examples of the bifunctional or tri- or more functional photoradical polymerization initiator include dimers of the oxime compounds described in JP2010-527339A, JP2011-524436A, WO2015/004565A, paragraphs “0407” to “0412” of JP2016-532675A, and paragraphs “0039” to “0055” of WO2017/033680A; the compound (E) and compound (G) described in JP2013-522445A; Cmpd 1 to 7 described in WO2016/034963A; the oxime ester photoinitiators described in paragraph “0007” of JP2017-523465A; the photoinitiators described in paragraphs “0020” to “0033” of JP2017-167399A; and the photopolymerization initiator (A) described in paragraphs “0017” to “0026” of JP2017-151342A.

It is also preferable that the photopolymerization initiator includes an oxime compound and an α-aminoketone compound. By using the oxime compound and the α-aminoketone compound in combination, developability is improved, and a pattern having excellent rectangularity is likely to be formed. In a case where an oxime compound and an α-aminoketone compound are used in combination, the content of the α-aminoketone compound is preferably 50 to 600 parts by mass and more preferably 150 to 400 parts by mass with respect to 100 parts by mass of the oxime compound.

The content of the photopolymerization initiator in the total solid content of the near-infrared absorbing composition is preferably 0.1 to 50 mass %, more preferably 0.5 to 30 mass %, and still more preferably 1 to 20 mass %. In a case where the content of the photopolymerization initiator is within the above-described range, better sensitivity and pattern formability can be obtained. In a case where the near-infrared absorbing composition according to the embodiment of the present invention includes two or more kinds of photopolymerization initiators, it is preferable that the total content thereof is within the above-described range.

<<Solvent>>

The near-infrared absorbing composition according to the embodiment of the present invention contains a solvent. Examples of the solvent include an organic solvent. Basically, the solvent is not particularly limited as long as it satisfies the solubility of the respective components and the application properties of the near-infrared absorbing composition. Examples of the organic solvent include esters, ethers, ketones, and aromatic hydrocarbons. The details of the organic solvent can be found in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In the present invention, as the organic solvent, one kind may be used alone, or two or more kinds may be used in combination. In addition, 3-methoxy-N,N-dimethylpropanamide and 3-butoxy-N,N-dimethylpropanamide are also preferable from the viewpoint of improving solubility. In this case, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total amount of the organic solvent) in consideration of environmental aspects and the like.

In the present invention, a solvent having a low metal content is preferably used. For example, the metal content in the solvent is preferably 10 mass parts per billion (ppb) or less. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method for removing impurities such as a metal from the solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The solvent may include isomers (compounds having the same number of atoms and different structures). In addition, only one kind of isomers may be included, or a plurality of isomers may be included.

In the present invention, as the organic solvent, an organic solvent containing 0.8 mmol/L or less of a peroxide is preferable, and an organic solvent containing substantially no peroxide is more preferable.

The content of the solvent is preferably 10 to 90 mass % with respect to the total amount of the near-infrared absorbing composition according to the embodiment of the present invention. The lower limit is preferably 20 mass % or more, more preferably 30 mass % or more, still more preferably 40 mass % or more, even more preferably 50 mass % or more, and particularly preferably 60 mass % or more.

In addition, from the viewpoint of environmental regulation, it is preferable that the near-infrared absorbing composition according to the embodiment of the present invention does not substantially contain environmentally regulated substances. In the present invention, the description “does not substantially contain environmentally regulated substances” means that the content of the environmentally regulated substances in the near-infrared absorbing composition is 50 ppm by mass or less, preferably 30 ppm by mass or less, still more preferably 10 ppm by mass or less, and particularly preferably 1 ppm by mass or less.

Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the near-infrared absorbing composition according to the embodiment of the present invention, and may be incorporated into the near-infrared absorbing composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, or near-infrared absorbing composition produced by mixing these compounds.

<<Resin>>

The near-infrared absorbing composition according to the embodiment of the present invention contains a resin. The resin is blended in, for example, an application for dispersing particles such as a pigment in a near-infrared absorbing composition or an application as a binder. The resin which is mainly used to disperse particles of the pigments and the like will also be called a dispersant. However, such applications of the resin are merely exemplary, and the resin can also be used for other purposes in addition to such applications.

The weight-average molecular weight (Mw) of the resin is preferably 3000 to 2000000. The upper limit is preferably 1000000 or less and more preferably 500000 or less. The lower limit is preferably 4000 or more and more preferably 5000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. Among these resins, one kind may be used alone, or a mixture of two or more kinds may be used. In addition, resins described in paragraphs “0041” to “0060” of JP2017-206689A, and resins described in paragraphs “0022” to “007” of JP2018-010856A can also be used.

In the present invention, as the resin, a resin having an acid group can be preferably used. According to this aspect, developability of the near-infrared absorbing composition can be improved, and pixels having excellent rectangularity can be easily formed. Examples of the acid group include a carboxyl group, a phosphoric acid group, a sulfo group, and a phenolic hydroxy group, and a carboxyl group is preferable. The resin having an acid group can be used, for example, as an alkali-soluble resin.

The resin having an acid group preferably includes a repeating unit having an acid group in the side chain, and more preferably includes 5 to 70 mol % of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

It is also preferable that the resin having an acid group includes a repeating unit having an ethylenically unsaturated bonding group in the side chain. According to this aspect, a film having excellent solvent resistance while having excellent developability is easily obtained.

Examples of the ethylenically unsaturated bonding group include a vinyl group, a (meth)allyl group, and a (meth)acryloyl group.

It is also preferable that the resin having an acid group includes a repeating unit derived from a monomer component including a compound represented by Formula (EDI) and/or a compound represented by Formula (ED2) (hereinafter, these compounds may be referred to as an “ether dimer”).

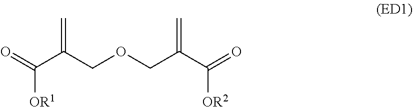

In Formula (EDI), R¹ and R² each independently represent a hydrogen atom or a hydrocarbon group having 1 to 25 carbon atoms which may have a substituent.

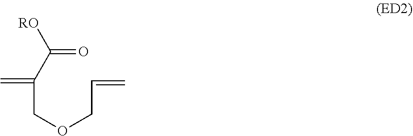

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

Specific examples of the ether dimer can be found in paragraph “0317” of JP2013-029760A, the content of which is incorporated herein by reference.

It is also preferable that the resin used in the present invention includes a repeating unit derived from a compound represented by Formula (X).

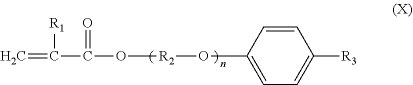

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring, n represents an integer of 1 to 15.

With regard to the resin having an acid group, reference can be made to the description in paragraphs “0558” to “0571” of JP2012-208494A (paragraphs “0685” to “0700” of the corresponding US2012/0235099A) and the description in paragraphs “0076” to “0099” of JP2012-198408A, the contents of which are incorporated herein by reference. In addition, as the resin having an acid group, a commercially available product may also be used.

The acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less. The weight-average molecular weight (Mw) of the resin having an acid group is preferably 5000 to 100000. In addition, the number-average molecular weight (Mn) of the resin having an acid group is preferably 1000 to 20000.

Examples of the resin having an acid group include resins having the following structures.

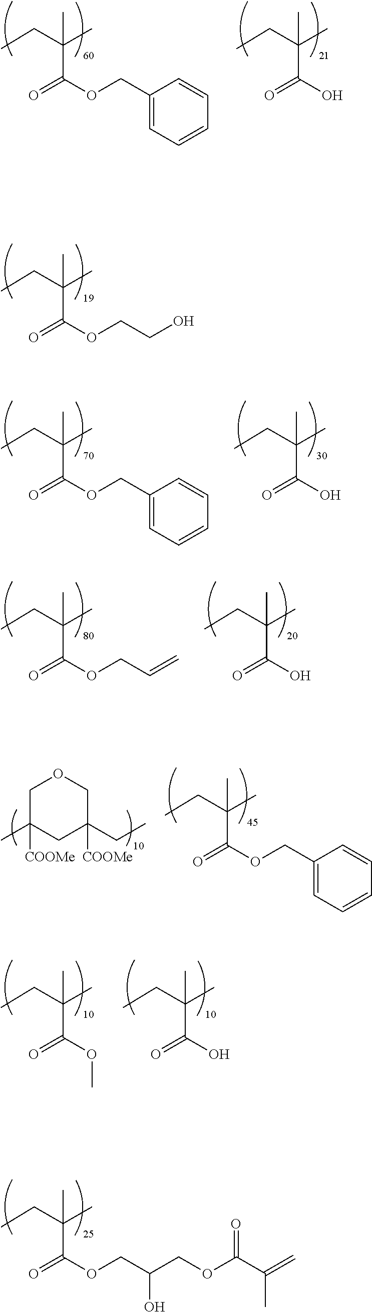

The near-infrared absorbing composition according to the embodiment of the present invention can also include a resin as a dispersant. Examples of the dispersant include an acidic dispersant (acidic resin) and a basic dispersant (basic resin), and an acidic dispersant is preferable. Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total content of the acid group and the basic group is 100 mol %, and more preferably a resin substantially consisting of only an acid group. The acid group in the acidic dispersant (acidic resin) is preferably a carboxyl group. The acid value of the acidic dispersant (acidic resin) is preferably 40 mgKOH/g or more, more preferably 50 mgKOH/g or more, still more preferably 60 mgKOH/g or more, even more preferably 70 mgKOH/g or more, and particularly preferably 80 mgKOH/g or more. The upper limit is preferably 200 mgKOH/g or less and still more preferably 150 mgKOH/g or less. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total content of the acid group and the basic group is 100 mol %. The basic group in the basic dispersant is preferably an amino group.

It is preferable that the resin used as a dispersant includes a repeating unit having an acid group. In a case where the resin used as a dispersant includes a repeating unit having an acid group, the generation of the development residue can be further suppressed in the formation of a pattern by a photolithography method.

It is also preferable that the resin used as a dispersant is a graft resin. With regard to details of the graft resin, reference can be made to the description in paragraphs “0025” to “0094” of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraphs “0102” to “0166” of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraphs “0196” to “0209” of JP2013-043962A.

In addition, the above-described resin (alkali-soluble resin) having an acid group can also be used as a dispersant.

In addition, it is also preferable that the resin used as a dispersant is a resin including a repeating unit having an ethylenically unsaturated bonding group in the side chain. According to this aspect, a film having excellent solvent resistance while having excellent developability is easily obtained. Examples of the ethylenically unsaturated bonding group include a vinyl group, a (meth)allyl group, and a (meth)acryloyl group. The content of the repeating unit having an ethylenically unsaturated bonding group in the side chain is preferably 10 mol % or more, more preferably 10 to 80 mol %, and still more preferably 20 to 70 mol % with respect to all the repeating units of the resin.

A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. In addition, pigment dispersants described in paragraphs “0041” to “0130” of JP2014-130338A can also be used, the contents of which are incorporated herein by reference. The resin described as a dispersant can be used for an application other than the dispersant. For example, the resin can also be used as a binder.

The content of the resin in the total solid content of the near-infrared absorbing composition is preferably 5 to 60 mass %. The lower limit is preferably 10 mass % or more and more preferably 15 mass % or more. The upper limit is preferably 50 mass % or less, more preferably 45 mass % or less, and still more preferably 40 mass % or less.

In addition, the content of the resin (alkali-soluble resin) having an acid group in the total solid content of the near-infrared absorbing composition is preferably 5 to 60 mass %. The lower limit is preferably 10 mass % or more and more preferably 15 mass % or more. The upper limit is preferably 50 mass % or less, more preferably 45 mass % or less, and still more preferably 40 mass % or less.

In addition, from the reason that excellent developability is easily obtained, the content of the resin (alkali-soluble resin) having an acid group in the total amount of the resin is preferably 30 mass % or more, more preferably 50 mass % or more, still more preferably 70 mass % or more, and particularly preferably 80 mass % or more. The upper limit may be 100 mass %, 95 mass %, or 90 mass % or less.

In a case where the near-infrared absorbing composition according to the embodiment of the present invention includes two or more kinds of resins, it is preferable that the total content thereof is within the above-described range.

In addition, the total content of the polymerizable compound and the resin in the total solid content of the near-infrared absorbing composition is preferably 0.1 to 80 mass %. The lower limit is preferably 0.5 mass % or more, more preferably 1.0 mass % or more, and still more preferably 2.0 mass % or more. The upper limit is preferably 75 mass % or less, more preferably 70 mass % or less, and still more preferably 60 mass % or less.

In addition, the near-infrared absorbing composition according to the embodiment of the present invention preferably contains 10 to 1000 parts by mass of the resin having an acid group with respect to 100 parts by mass of the polymerizable compound. The lower limit is preferably 20 parts by mass or more and more preferably 30 parts by mass or more. The upper limit is preferably 900 parts by mass or less and more preferably 500 parts by mass or less. According to this aspect, excellent developability is easily obtained.

<<Compound Having Epoxy Group>>

The near-infrared absorbing composition according to the embodiment of the present invention may contain a compound having an epoxy group (hereinafter, also referred to as an epoxy compound). Examples of the epoxy compound include a compound having one or more epoxy groups in one molecule, and a compound two or more epoxy groups in one molecule is preferable. The epoxy compound preferably has 1 to 100 epoxy groups in one molecule. The upper limit of the number of epoxy groups may be, for example, 10 or less or 5 or less. The lower limit of the number of epoxy groups is preferably 2 or more. As the epoxy compound, compounds described in paragraphs “0034” to “0036” of JP2013-011869A, paragraphs “0147” to “0156” of JP2014-043556A, and paragraphs “0085” to “0092” of JP2014-089408A, and compounds described in JP2017-179172A can also be used. The contents thereof are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). The weight-average molecular weight of the epoxy compound is preferably 200 to 100000 and more preferably 500 to 50000. The upper limit of the weight-average molecular weight is preferably 10000 or less, more preferably 5000 or less, and still more preferably 3000 or less.

Examples of a commercially available product of the epoxy compound include EHPE3150 (manufactured by Daicel Corporation) and EPICLON N-695 (manufactured by DIC Corporation).

In a case where the near-infrared absorbing composition according to the embodiment of the present invention contains an epoxy compound, the content of the epoxy compound in the total solid content of the near-infrared absorbing composition is preferably 0.1 to 20 mass %. The lower limit is, for example, preferably 0.5 mass % or more, and more preferably 1 mass % or more. The upper limit is, for example, preferably 15 mass % or less and still more preferably 10 mass % or less. The epoxy compound contained in the near-infrared absorbing composition may be only one kind or two or more kinds thereof. In a case of using two or more kinds thereof, it is preferable that the total content thereof is within the above-described range.

<<Silane Coupling Agent>>

The near-infrared absorbing composition according to the embodiment of the present invention may contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group. Among these, an amino group, a (meth)acryloyl group, or an epoxy group is preferable. Specific examples of the silane coupling agent include compounds described in paragraphs “0018” to “0036” of JP2009-288703A and compounds described in paragraphs “0056” to “0066” of JP2009-242604A, the contents of which are incorporated herein by reference.

In a case where the near-infrared absorbing composition according to the embodiment of the present invention contains a silane coupling agent, the content of the silane coupling agent in the total solid content of the near-infrared absorbing composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof. In a case of using two or more kinds thereof, it is preferable that the total content thereof is within the above-described range.

<<Polymerization Inhibitor>>

The near-infrared absorbing composition according to the embodiment of the present invention may contain a polymerization inhibitor. Examples of the polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol), an N-nitrosophenylhydroxyamine salt (an ammonium salt, a cerous salt, or the like), and 2,2,6,6-tetramethylpiperidine 1-oxyl. The content of the polymerization inhibitor in the total solid content of the near-infrared absorbing composition is preferably 0.0001 to 5 mass %. In a case where the near-infrared absorbing composition according to the embodiment of the present invention includes two or more kinds of polymerization inhibitors, it is preferable that the total content thereof is within the above-described range.

<<Surfactant>>

The near-infrared absorbing composition according to the embodiment of the present invention may contain a surfactant. As the surfactant, various surfactants such as a fluorine surfactant, a nonionic surfactant, a cationic surfactant, an anionic surfactant, or a silicon-based surfactant can be used. With regard to the surfactant, reference can be made to the description in paragraphs “0238” to “0245” of WO2015/166779A, the contents of which are incorporated herein by reference.

In the present invention, it is preferable that the surfactant is a fluorine surfactant. By containing a fluorine surfactant in the near-infrared absorbing composition, liquid characteristics (particularly, fluidity) are further improved, and liquid saving properties can be further improved. In addition, it is possible to form a film with a small thickness unevenness.

The fluorine content in the fluorine surfactant is preferably 3 to 40 mass %, more preferably 5 to 30 mass %, and still more preferably 7 to 25 mass %. The fluorine surfactant in which the fluorine content is within the above-described range is effective in terms of the evenness of the thickness of the coating film or liquid saving properties and the solubility of the surfactant in the near-infrared absorbing composition is also good.

Examples of the fluorine surfactant include surfactants described in paragraphs “0060” to “0064” of JP2014-041318A (paragraphs “0060” to “0064” of the corresponding WO2014/017669A) and the like, and surfactants described in paragraphs “0117” to “0132” of JP2011-132503A, the contents of which are incorporated herein by reference. Examples of a commercially available product of the fluorine surfactant include: MEGAFACE FI71, FI72, F173, F176, F177, F141, F142, F143, F144, R³⁰, F437, F475, F479, F482, F554, F780, EXP, MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, an acrylic compound which has a molecular structure having a functional group containing a fluorine atom and in which, by applying heat to the molecular structure, the functional group containing a fluorine atom is broken to volatilize a fluorine atom can be used. Examples of such a fluorine surfactant include MEGAFACE DS series manufactured by DIC Corporation (for example, MEGAFACE DS-21).

In addition, as the fluorine surfactant, a copolymer of a fluorine atom-containing vinyl ether compound having a fluorinated alkyl group or a fluorinated alkylene ether group, and a hydrophilic vinyl ether compound can be used. With regard to such a fluorine surfactant, reference can be made to the description in JP2016-216602A, the contents of which are incorporated herein by reference.

As the fluorine surfactant, a block polymer can also be used. Examples of the block polymer include compounds described in JP2011-089090A. In addition, as the fluorine surfactant, a fluorine-containing copolymer including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can be used. For example, the following compound can also be used as the fluorine surfactant used in the present invention.

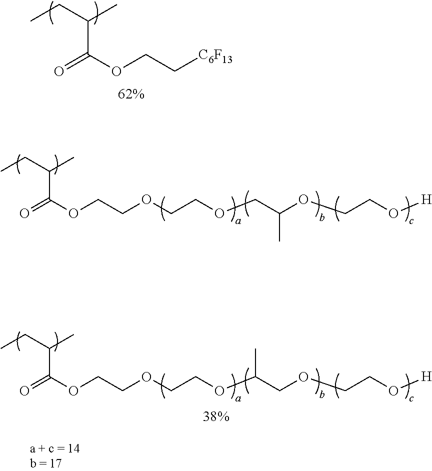

The weight-average molecular weight of the compound is preferably 3000 to 50000 and, for example, 14000. In the compound, “%” representing the proportion of a repeating unit is mol %.

In addition, as the fluorine surfactant, a fluorine-containing copolymer including a repeating unit having an ethylenically unsaturated group in the side chain can be used.

Specific examples thereof include compounds described in paragraphs “0050” to “0090” and paragraphs “0289” to “0295” of JP2010-164965A, and MEGAFACE RS-101, RS-102, RS-718K, and RS-72-K manufactured by DIC Corporation. In addition, as the fluorine surfactant, compounds described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by Wako Pure Chemical Industries, Ltd.), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie). The content of the surfactant in the total solid content of the near-infrared absorbing composition is preferably 0.001 to 5.0 mass % and more preferably 0.005 to 3.0 mass %. In a case where the near-infrared absorbing composition according to the embodiment of the present invention includes two or more kinds of surfactants, it is preferable that the total content thereof is within the above-described range.

<<Ultraviolet Absorber>>

The near-infrared absorbing composition according to the embodiment of the present invention may contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, and the like can be used. With regard to details thereof, reference can be made to the description in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraphs “0049” to “0059” of JP6268967B can also be used. The content of the ultraviolet absorber in the total solid content of the near-infrared absorbing composition is preferably 0.01 to 10 mass % and more preferably 0.01 to 5 mass %. In a case where the near-infrared absorbing composition according to the embodiment of the present invention includes two or more kinds of ultraviolet absorbers, it is preferable that the total content thereof is within the above-described range.

<<Other Additives>

Various additives such as a filler, an adhesion promoter, an antioxidant, a potential antioxidant, and an aggregation inhibitor can be blended into the near-infrared absorbing composition according to the embodiment of the present invention as necessary. Examples of these additives include additives described in paragraphs “0155” and “0156” of JP2004-295116A, the contents of which are incorporated herein by reference. In addition, examples of the antioxidant include a phenol compound, a phosphorus-based compound (for example, compounds described in paragraphs “0042” of JP2011-090147A), a thioether compound. In addition, antioxidants described in WO2017/164024A can also be used. Examples of a commercially available product of the antioxidant include ADK STAB series (AO-20, AO-30, AO-40, AO-50, AO-50F, AO-60, AO-60G, AO-80, AO-330, and the like) manufactured by ADEKA Corporation. Examples of the potential antioxidant include a compound in which a portion that functions as the antioxidant is protected by a protective group and the protective group is desorbed by heating the compound at 100° C. to 250° C. or by heating the compound at 80° C. to 200° C. in the presence of an acid/a base catalyst. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation).

In addition, in order to adjust the refractive index of the film to be obtained, the near-infrared absorbing composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and most preferably 5 to 50 nm. The metal oxide may have a core-shell structure, and in this case, the core portion may be hollow.

In addition, the near-infrared absorbing composition according to the embodiment of the present invention may include a light-resistance improver. Examples of the light-resistance improver include the compounds described in paragraphs “0036” and “0037” of JP2017-198787A, the compounds described in paragraphs “0029” to “0034” of JP2017-146350A, the compounds described in paragraphs “0036” and “0037”, and “0049” to “0052” of JP2017-129774A, the compounds described in paragraphs “0031” to “0034”, “0058”, and “0059” of JP2017-129674A, the compounds described in paragraphs “0036” and “0037”, and “0051” to “0054” of JP2017-122803A, the compounds described in paragraphs “0025” to “0039” of WO2017/164127A, the compounds described in paragraphs “0034” to “0047” of JP2017-186546A, the compounds described in paragraphs “0019” to “0041” of JP2015-025116A, the compounds described in paragraphs “0101” to “0125” of JP2012-145604A, the compounds described in paragraphs “0018” to “0021” of JP2012-103475A, the compounds described in paragraphs “0015” to “0018” of JP2011-257591A, the compounds described in paragraphs “0017” to “0021” of JP2011-191483A, the compounds described in paragraphs “0108” to “0116” of JP2011-145668A, and the compounds described in paragraphs “0103” to “0153” of JP2011-253174A.

The viscosity (at 25° C.) of the near-infrared absorbing composition according to the embodiment of the present invention is preferably 1 to 100 mPa×s. The lower limit is more preferably 2 mPa×s or more and still more preferably 3 mPa×s or more. The upper limit is more preferably 50 mPa×s or less, still more preferably 30 mPa×s or less, and particularly preferably 15 mPa×s or less.

In the near-infrared absorbing composition according to the embodiment of the present invention, the content of free metal which is not bonded to or coordinated with a pigment or the like is preferably 100 ppm or less, more preferably 50 ppm or less, and still more preferably 10 ppm or less, it is particularly preferable to not contain the free metal substantially. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. Furthermore, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521 A, and the like can also be obtained. Examples of the types of the above-described free metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the near-infrared absorbing composition according to the embodiment of the present invention, the content of free halogen which is not bonded to or coordinated with a pigment or the like is preferably 100 ppm or less, more preferably 50 ppm or less, and still more preferably 10 ppm or less, it is particularly preferable to not contain the free halogen substantially. Examples of a method for reducing free metals and halogens in the near-infrared absorbing composition include washing with ion exchange water, filtration, ultrafiltration, and purification with an ion exchange resin.

A storage container of the near-infrared absorbing composition according to the embodiment of the present invention is not particularly limited, and a known storage container can be used. In addition, as the storage container, in order to suppress infiltration of impurities into the raw materials or the composition, a multilayer bottle in which a container inner wall having a six-layer structure is formed of six kinds of resins or a bottle in which a container inner wall having a seven-layer structure is formed of six kinds of resins is preferably used. Examples of such a container include a container described in JP2015-123351 A. In addition, storage conditions of the near-infrared absorbing composition according to the embodiment of the present invention is not particularly limited, and a known method in the related art can be used. In addition, a method described in JP2016-180058A can be used.

<Method for Producing Dispersion Liquid>

Next, a method for producing a dispersion liquid according to an embodiment of the present invention will be described.

The method for producing a dispersion liquid according to an embodiment of the present invention includes a step of dispersing a near-infrared absorbing pigment having an oxocarbon skeleton in a presence of a coloring agent derivative, a resin, and a solvent, in which the coloring agent derivative is a compound having a cation and an anion in a molecule, and 0.5 to 25 parts by mass of the coloring agent derivative is used with respect to 100 parts by mass of the near-infrared absorbing pigment.

As the near-infrared absorbing pigment, the coloring agent derivative, the resin, and the solvent, materials described in the section of the near-infrared absorbing pigment, coloring agent derivative, and solvent of the near-infrared absorbing composition according to the embodiment of the present invention described above are used.

In the method for producing a dispersion liquid according to the embodiment of the present invention, 0.5 to 25 parts by mass of the above-described coloring agent derivative is used with respect to 100 parts by mass of the above-described near-infrared absorbing pigment. The lower limit is preferably 1.5 parts by mass or more, more preferably 2.5 parts by mass or more, and still more preferably 3 parts by mass or more. The upper limit is preferably 20 parts by mass or less, more preferably 17.5 parts by mass or less, and still more preferably 15 parts by mass or less.

In the method for producing a dispersion liquid according to the embodiment of the present invention, 1 to 100 parts by mass of the resin is used with respect to 100 parts by mass of the near-infrared absorbing pigment. The lower limit is preferably 1.5 parts by mass or more, more preferably 2.5 parts by mass or more, and still more preferably 5 parts by mass or more. The upper limit is preferably 95 parts by mass or less, more preferably 90 parts by mass or less, and still more preferably 85 parts by mass or less. In addition, it is preferable that 4 to 2000 parts by mass of the resin is used with respect to 100 parts by mass of the coloring agent derivative. The lower limit is preferably 10 parts by mass or more, more preferably 20 parts by mass or more, and still more preferably 30 parts by mass or more. The upper limit is preferably 1900 parts by mass or less, more preferably 1800 parts by mass or less, and still more preferably 1700 parts by mass or less.

Examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In the method for producing a dispersion liquid, for the purpose of removing foreign matter or reducing defects, it is also preferable to filter with a filter. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Advantec Toyo Kaisha, Ltd., Nihon Entegris G.K. (formerly Nippon Microlith Co., Ltd.), Kitz Microfilter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used.

The dispersion liquid produced by the method for producing a dispersion liquid according to the embodiment of the present invention can be used as a raw material for the near-infrared absorbing composition according to the embodiment of the present invention. For example, in a case where the near-infrared absorbing composition according to the embodiment of the present invention includes other components (for example, a polymerizable compound, a photopolymerization initiator, and the like) in addition to the near-infrared absorbing pigment having an oxocarbon skeleton, the coloring agent derivative, the resin, and the solvent, the near-infrared absorbing composition according to the embodiment of the present invention can be obtained by mixing the obtained dispersion liquid with the other components. In addition, the obtained dispersion liquid itself can also be used as a near-infrared absorbing composition.

<Film>

Next, a film according to an embodiment of the present invention will be described.

The film according to an embodiment of the present invention is obtained from the above-described near-infrared absorbing composition according to the embodiment of the present invention. The film according to the embodiment of the present invention can be preferably used as a near-infrared cut filter, a near-infrared transmitting filter, and the like.

The film according to the embodiment of the present invention may be used in a state where it is laminated on a support, or may be used in a state where it is peeled off from a support. Examples of the support include a semiconductor base material such as silicon and a transparent base material. The transparent base material is not particularly limited as long as it is formed of a material which can allow transmission of at least visible light. Examples thereof include a base material formed of a material such as glass, crystal, and resin. Glass is preferable as the material of the transparent base material. That is, the transparent base material is preferably a glass base material. Examples of the glass include soda lime glass, borosilicate glass, non-alkali glass, quartz glass, and copper-containing glass. Examples of the copper-containing glass include a phosphate glass containing copper and a fluorophosphate glass containing copper. Examples of a commercially available product of the copper-containing glass include NF-50 (manufactured by AGC Techno Glass Co., Ltd.).

Examples of the crystal include rock crystal, lithium niobate, and sapphire. Examples of the resin include polyester resins such as polyethylene terephthalate and polybutylene terephthalate, polyolefin resins such as polyethylene, polypropylene, and ethylene vinyl acetate copolymer, norbornene resin, acrylic resins such as polyacrylate and polymethylmethacrylate, urethane resin, vinyl chloride resin, fluororesin, polycarbonate resin, polyvinyl butyral resin, and polyvinyl alcohol resin. In addition, in order to enhance adhesiveness between the support and the film according to the embodiment of the present invention, an underlayer or the like may be provided on the surface of the support.

In a case where the film according to the embodiment of the present invention is used as a near-infrared cut filter, it is preferable that the film according to the embodiment of the present invention has a maximum absorption wavelength in a range of 700 to 1200 nm. The average light transmittance in a wavelength range of 400 to 550 nm is preferably 70% or more, more preferably 80% or more, still more preferably 85% or more, and particularly preferably 90% or more. In addition, the light transmittance in the entire wavelength range of 400 to 550 nm is preferably 70% or more, more preferably 80% or more, and still more preferably 90% or more. In addition, the light transmittance at least one point in a wavelength range of 700 to 1000 nm is preferably 20% or less, more preferably 15% or less, and still more preferably 10% or less.

In a case where the film according to the embodiment of the present invention is used as a near-infrared transmitting filter, it is preferable that the film according to the embodiment of the present invention has, for example, any one of the following spectral characteristic (1) or (2).

(1): film in which the maximum value of the light transmittance of the film in a thickness direction in a wavelength range of 400 to 830 nm is 20% or less (preferably 15% or less and more preferably 10% or less) and the minimum value of the light transmittance of the film in a thickness direction in a wavelength range of 1000 to 1300 nm is 70% or more (preferably 75% or more and more preferably 80% or more). This film can shield light having the wavelength range of 400 to 830 nm and can transmit light having a wavelength exceeding 940 nm.

(2): film in which the maximum value of the light transmittance of the film in a thickness direction in a wavelength range of 400 to 950 nm is 20% or less (preferably 15% or less and more preferably 10% or less) and the minimum value of the light transmittance of the film in a thickness direction in a wavelength range of 1100 to 1300 nm is 70% or more (preferably 75% or more and more preferably 80% or more). This film can shield light having the wavelength range of 400 to 950 nm and can transmit light having a wavelength exceeding 1040 nm.

The film according to the embodiment of the present invention can be used in combination with a color filter which includes a chromatic colorant. The color filter can be manufactured using a coloring composition including a chromatic colorant. Examples of the chromatic colorant include the chromatic colorant described above. The coloring composition can further contain a curable compound, a photopolymerization initiator, a surfactant, a solvent, a polymerization inhibitor, an ultraviolet absorber, and the like. Examples of the details thereof include the above-described materials, and these can be used.

In a case where the film according to the embodiment of the present invention is used as a near-infrared cut filter and used in combination with a color filter, it is preferable that the color filter is disposed on an optical path of light through the film according to the embodiment of the present invention. For example, the film according to the embodiment of the present invention and the color filter can be laminated to be used as a laminate. In the laminate, the film according to the embodiment of the present invention and the color filter may be or may not be adjacent to each other in a thickness direction. In a case where the film according to the embodiment of the present invention is not adjacent to the color filter in the thickness direction, the film according to the embodiment of the present invention may be formed on another support other than a support on which the color filter is formed, or another member (for example, a microlens or a planarizing layer) constituting a solid-state imaging element may be interposed between the film according to the embodiment of the present invention and the color filter.

The thickness of the film according to the embodiment of the present invention can be a adjusted according to the purpose. The thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

In the present invention, a near-infrared cut filter refers to a filter which allows transmission of light (visible light) in the visible range and shields at least a part of light (near infrared light) in the near infrared range. The near-infrared cut filter may be a filter which allows transmission of light in the entire wavelength range of the visible range, or may be a filter which allows transmission of light in a specific wavelength range of the visible range and shields light in another specific wavelength range of the visible range. In addition, in the present invention, a color filter refers to a filter which allows transmission of light in a specific wavelength range of the visible range and shields light in another specific wavelength range of the visible range. In addition, in the present invention, a near-infrared transmitting filter refers to a filter which shields visible light and allows transmission of at least a part of near infrared light.

<Optical Filter>

Next, an optical filter according to an embodiment of the present invention will be described. The optical filter according to an embodiment of the present invention has the film according to the embodiment of the present invention. Examples of the optical filter include a near-infrared cut filter and a near-infrared transmitting filter.

In a case where the optical filter according to the embodiment of the present invention is used as a near-infrared transmitting filter, examples of the near-infrared transmitting filter include a filter which shields visible light and transmits light having a wavelength of 900 nm or more.

In the optical filter, the thickness of the film according to the embodiment of the present invention can be appropriately adjusted according to the purpose. The thickness is preferably 20 μm or less, more preferably 10 μm or less, and still more preferably 5 μm or less. The lower limit is preferably 0.1 μm or more, more preferably 0.2 μm or more, and still more preferably 0.3 μm or more.

In a case where the optical filter according to the embodiment of the present invention is used as a near-infrared cut filter, the near-infrared cut filter may further have a dielectric multilayer film, an ultraviolet absorbing layer, and the like, in addition to the film according to the embodiment of the present invention. The details of the ultraviolet absorbing layer can be found in the description of an absorbing layer described in paragraphs “0040” to “0070” and “0119” to “0145” of WO2015/099060A, the content of which is incorporated herein by reference. Examples of the dielectric multilayer film include dielectric multilayer films described in paragraphs “0255” to “0259” of JP2014-041318A, the content of which is incorporated herein by reference.

In addition, in the optical filter according to the embodiment of the present invention, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near infrared rays, and the like) having a specific wavelength can be imparted. The thickness of the protective layer is preferably 0.01 to 10 μm and still more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an inkjet method can be used. As the organic solvent contained in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

Optionally, the protective layer may contain an additive such as organic or inorganic fine particles, an absorber of a specific wavelength (for example, ultraviolet rays, near infrared rays, and the like), a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of a specific wavelength, a known absorber can be used. Examples of the ultraviolet absorber and near-infrared absorber include the above-described materials. The content of these additives can be appropriately adjusted, but is preferably 0.1 to 70 mass % and still more preferably 1 to 60 mass % with respect to the total weight of the protective layer.

In addition, as the protective layer, the protective layers described in paragraphs “0073” to “0092” of JP2017-151176A can also be used.

The optical filter according to the embodiment of the present invention can be used in various devices including a solid-state imaging element such as a charge coupled device (CCD) or a complementary metal-oxide semiconductor (CMOS), an infrared sensor, or an image display device.

In addition, it is also preferable that the optical filter according to the embodiment of the present invention has a pixel of the film according to the embodiment of the present invention, and at least one pixel selected from a red pixel, a green pixel, a blue pixel, a magenta pixel, a yellow pixel, a cyan pixel, a black pixel, or an achromatic pixel.

It is also preferable that the optical filter according to the embodiment of the present invention has a pixel (pattern) of the film obtained using the near-infrared absorbing composition according to the embodiment of the present invention, and at least one pixel (pattern) selected from a red pixel, a green pixel, a blue pixel, a magenta pixel, a yellow pixel, a cyan pixel, a black pixel, or an achromatic pixel.

<Method for Forming Pattern>

Next, a method for forming a pattern according to an embodiment of the present invention will be described. The method for forming a pattern according to an embodiment of the present invention includes a step of forming a composition layer on a support using the above-described near-infrared absorbing composition according to the embodiment of the present invention, and a step of forming a pattern on the composition layer by a photolithography method or a dry etching method.

(Photolithography Method)

First, a case of forming a pattern by a photolithography method will be described. Pattern formation by a photolithography method preferably includes a step of forming a composition layer on a support using the near-infrared absorbing composition according to the embodiment of the present invention, a step of patternwise exposing the composition layer, and a step of removing an unexposed area of the composition layer by development to form a pattern (pixel). Optionally, a step (pre-baking step) of baking the composition layer and a step (post-baking step) of baking the developed pattern (pixel) may be provided.

In the step of forming a composition layer, the composition layer is formed on a support using the near-infrared absorbing composition according to the embodiment of the present invention. The support is not particularly limited, and examples thereof include a semiconductor base material such as silicon and the above-described transparent base material. An organic film or an inorganic film may be formed on the support. In addition, a charge coupled device (CCD), a complementary metal-oxide semiconductor (CMOS), a transparent conductive film, or the like may be formed on the support. In addition, a black matrix which separates respective pixels from each other may be formed on the support. In addition, optionally, an undercoat layer may be provided on the support to improve adhesiveness with a layer above the support, to prevent diffusion of substances, or to make the surface of the support flat. In addition, in a case where a glass base material is used as the support, it is preferable that an inorganic film is formed on the surface of the glass base material, or the glass base material is dealkalized to be used.

As a method of applying the near-infrared absorbing composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an inkjet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet—Infinite Possibilities in Patent-” (published in February, 2005, S.B. Research Co., Ltd.) and methods described in JP2003-262716A, JP2003-185831A, JP2003-261827A, JP2012-126830A, and JP2006-169325A. In addition, with regard to the method of applying the near-infrared absorbing composition, reference can be made to the description in WO2017/030174A and WO2017/018419A, the contents of which are incorporated herein by reference.

The composition layer formed by applying the near-infrared absorbing composition may be dried (pre-baked). In a case where pre-baking is performed, the pre-baking temperature is preferably 150° C. or lower, more preferably 120° C. or lower, and still more preferably 110° C. or lower. The lower limit may be, for example, 50° C. or higher or 80° C. or higher. By performing the pre-baking at the temperature of 150° C. or lower, even in a case where, for example, a photoelectric conversion film of an image sensor is formed of an organic material, the characteristics of the organic material can be more effectively maintained. The pre-baking time is preferably 10 to 3000 seconds, more preferably 40 to 2500 seconds, and still more preferably 80 to 220 seconds. Pre-baking can be performed using a hot plate, an oven, or the like.

Next, the composition layer is patternwise exposed. For example, the composition layer can be patternwise exposed using a stepper exposure device, a scanner exposure device, or the like through a mask having a predetermined mask pattern. As a result, an exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50000000 W/m² or more, more preferably 100000000 W/m² or more, and still more preferably 200000000 W/m² or more. In addition, the upper limit of the maximum instantaneous illuminance is preferably 1000000000 W/m² or less, more preferably 800000000 W/m² or less, and still more preferably 500000000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure dose) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the unexposed area of the composition layer is removed by development to form a pattern (pixel). The unexposed area of the composition layer can be removed by development using a developer. Thus, the composition layer of the unexposed area in the exposure step is eluted into the developer, and as a result, only a photocured portion remains. Examples of the developer include an organic solvent and an alkali developer. For example, the temperature of the developer is preferably 20° C. to 30° C. The development time is preferably 20 to 180 seconds. In addition, in order to further improve residues removing properties, a step of shaking the developer off per 60 seconds and supplying a new developer may be repeated multiple times.

As the developer, an alkaline aqueous solution (alkali developer) obtained by diluting an alkaline agent with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium carbonate, sodium bicarbonate, sodium silicate, and sodium metasilicate. In consideration of environmental aspects and safety aspects, the alkaline agent is preferably a compound having a high molecular weight. The concentration of the alkaline agent in the alkaline aqueous solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the composition layer after development while rotating the support on which the composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is also preferable to perform an additional exposure treatment or a heat treatment (post-baking) after carrying out drying. The additional exposure treatment or post-baking is a curing treatment which is performed after development to complete the curing. The heating temperature in the post-baking is, for example, preferably 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be performed by the method described in KR10-2017-122130A.

(Dry Etching Method)

Next, a case of forming pattern by a dry etching method will be described. The formation of a pattern using a dry etching method can be performed using a method including: a step of forming a composition layer on a support using the near-infrared absorbing composition according to the embodiment of the present invention and curing the entire composition layer to form a cured composition layer; a step of forming a photoresist layer on this cured composition layer; a step of patternwise exposing the photoresist layer and then developing the photoresist layer to form a resist pattern; and a step of dry-etching the cured composition layer with an etching gas using this resist pattern as a mask. It is preferable that pre-baking treatment is further performed in order to form the photoresist layer. In particular, as the forming process of the photoresist layer, it is desirable that a heat treatment after exposure and a heat treatment after development (post-baking treatment) are performed. The details of the pattern formation using the dry etching method can be found in paragraphs “0010” to “0067” of JP2013-064993A, the content of which is incorporated herein by reference.

<Solid-State Imaging Element>

A solid-state imaging element according to an embodiment of the present invention has the film according to the embodiment of the present invention. The configuration of the solid-state imaging element according to the embodiment of the present invention is not particularly limited as long as it has the film according to the embodiment of the present invention and functions as a solid-state imaging element. For example, the following configuration can be adopted.

The solid-state imaging element includes a plurality of photodiodes and transfer electrodes on the support, the photodiodes constituting a light receiving area of the solid-state imaging element, and the transfer electrode consisting of polysilicon or the like. In the solid-state imaging element, a light-shielding film consisting of tungsten or the like which has openings through only light receiving sections of the photodiodes is provided on the photodiodes and the transfer electrodes, a device protective film consisting of silicon nitride or the like is formed on the light-shielding film so as to cover the entire surface of the light-shielding film and the light receiving sections of the photodiodes, and the film according to the embodiment of the present invention is formed on the device protective film. Furthermore, a configuration in which a light collecting unit (for example, a microlens; hereinafter, the same shall be applied) is provided above the device protective film and below the film according to the embodiment of the present invention (on a side thereof close the support), or a configuration in which a light collecting unit is provided on the film according to the embodiment of the present invention may be adopted. In addition, the pixels of each color in the color filter may be embedded in a space partitioned by a partition wall, for example, a space partitioned in a lattice form. In this case, it is preferable that the partition wall has a lower refractive index than each pixel. Examples of an imaging device having such a structure include devices described in JP2012-227478A and JP2014-179577A.

<Image Display Device>

An image display device according to an embodiment of the present invention has the film according to the embodiment of the present invention. Examples of the image display device include a liquid crystal display device or an organic electroluminescence (organic EL) display device. The definition and details of the image display device can be found in, for example, “Electronic Display Device (written by Akiya Sasaki, Kogyo Chosakai Publishing Co., Ltd., published in 1990)” or “Display Device (written by Sumiaki Ibuki, Sangyo Tosho Co., Ltd., published in 1989). In addition, the details of a liquid crystal display device can be found in, for example, “Next-Generation Liquid Crystal Display Techniques (Edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”. The image display device may be an image display device having a white organic EL element. It is preferable that the white organic EL element has a tandem structure. The tandem structure of the organic EL element is described in, for example, JP2003-045676A, or pp. 326 to 328 of “Forefront of Organic EL Technology Development-Know-How Collection of High Brightness, High Precision, and Long Life” (Technical Information Institute, 2008). It is preferable that a spectrum of white light emitted from the organic EL element has high maximum emission peaks in a blue range (430 to 485 nm), a green range (530 to 580 nm), and a yellow range (580 to 620 nm). It is more preferable that the spectrum has a maximum emission peak in a red range (650 to 700 nm) in addition to the above-described emission peaks.

<Infrared Sensor>

An infrared sensor according to an embodiment of the present invention has the above-described film according to the embodiment of the present invention. The configuration of the infrared sensor is not particularly limited as long as it functions as an infrared sensor. Hereinafter, an embodiment of the infrared sensor according to the present invention will be described using the drawings.

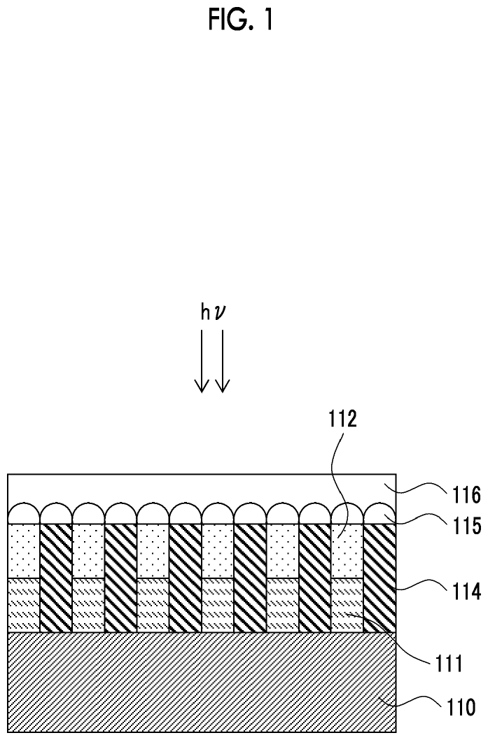

In FIG. 1, reference numeral 110 represents a solid-state imaging element. In an imaging region provided on the solid-state imaging element 110, near-infrared cut filters 111 and near-infrared transmitting filters 114 are provided. In addition, color filters 112 are laminated on the near-infrared cut filters 111. Microlenses 115 are disposed on an incidence ray hv side of the color filters 112 and the near-infrared transmitting filters 114. A planarizing layer 116 is formed so as to cover the microlenses 115.

The near-infrared cut filter 111 can be formed using the near-infrared absorbing composition according to the embodiment of the present invention. Spectral characteristics of the near-infrared cut filters 111 can be selected according to the emission wavelength of an infrared light emitting diode (infrared LED) to be used. The color filters 112 is not particularly limited as long as pixels which allow transmission of light having a specific wavelength in a visible range and absorbs the light are formed therein, and a known color filter in the related art for forming a pixel can be used. For example, pixels of red (R), green (G), and blue (B) are formed in the color filters. For example, the details of the color filters can be found in paragraphs “0214” to “0263” of JP2014-043556A, the content of which is incorporated herein by reference. Characteristics of the near-infrared transmitting filter 114 can be selected according to the emission wavelength of the infrared LED to be used. The near-infrared transmitting filters 114 can also be formed using the near-infrared absorbing composition according to the embodiment of the present invention.

In the infrared sensor shown in FIG. 1, a near-infrared cut filter (other near-infrared cut filters) other than the near-infrared cut filter 111 may be further disposed on the planarizing layer 116. As the other near-infrared cut filters, for example, a layer containing copper and/or a dielectric multilayer film may be provided. In addition, as the other near-infrared cut filters, a dual band pass filter may be used. In addition, in the infrared sensor shown in FIG. 1, the positions of the near-infrared cut filter 111 and the color filter 112 may be switched. In addition, another layer may be disposed between the solid-state imaging element 110 and the near-infrared cut filter 111, and/or between the solid-state imaging element 110 and the near-infrared transmitting filter 114. Examples of another layer include an organic layer formed using a composition including a curable compound. In addition, a planarizing layer may be formed on the color filter 112.

### EXAMPLES

Hereinafter, the present invention will be described in detail using Examples. Materials, used amounts, proportions, treatment details, treatment procedures, and the like shown in the following examples can be appropriately changed within a range not departing from the scope of the present invention. Accordingly, the scope of the present invention is not limited to the following specific examples.

<Preparation of Near-Infrared Absorbing Composition>

Raw materials shown in the following tables were mixed to prepare a near-infrared absorbing composition. As the dispersion liquid, a dispersion liquid prepared as follows was used.

A pigment, a pigment derivative, a dispersant, and a solvent 1 described in the column of Dispersion liquid of the following tables were mixed with each other in part by mass shown in the column of Dispersion liquid of the following tables, 230 parts by mass of zirconia beads having a diameter of 0.3 mm was further added thereto, the mixture was dispersed using a paint shaker for 5 hours, and the beads were separated by filtration, thereby producing a dispersion liquid.

TABLE 1

| | Dispersion liquid | | | | | | | | | | | | | |
|---|---|---|---|---|---|---|---|---|---|---|---|---|---|---|
| | | | Coloring agent | | | | | | | | | | | |
| | Pigment | | derivative | | Dispersant | | Solvent 1 | | Resin | | Monomer | | Initiator | |
| | | Part | | Part | | Part | | Part | | Part | | Part | | Part |
| | | by | | by | | by | | by | | by | | by | | by |
| Name | Compound | mass | Type | mass | Type | mass | Type | mass | Type | mass | Type | mass | Type | mass |
| Example 1 | Aa-1 | 2.61 | Ba-1 | 0.39 | C2 | 1.8 | S1 | 38.97 | D2 | 5.5 | M1 | 4.8 | F1 | 1 |
| | | | | | | | | | | | M2 | 1.6 | | |
| Example 2 | Ab-1 | 2.61 | Bb-1 | 0.39 | C2 | 1.8 | S1 | 38.97 | D2 | 5.5 | M1 | 4.8 | F1 | 1 |
| | | | | | | | | | | | M2 | 1.6 | | |
| Example 3 | Ab-9 | 2.61 | Bb-11 | 0.39 | C2 | 1.8 | S1 | 38.97 | D2 | 5.5 | M1 | 4.8 | F1 | 1 |
| | | | | | | | | | | | M2 | 1.6 | | |
| Example 4 | Ab-10 | 2.61 | Bb-8 | 0.39 | C1 | 1.8 | S1 | 38.97 | D2 | 5.5 | M1 | 4.8 | F1 | 1 |
| | | | | | | | | | | | M2 | 1.6 | | |
| Example 5 | Ab-12 | 2.61 | Bb-2 | 0.39 | C2 | 1.8 | S1 | 38.97 | D2 | 5.5 | M1 | 4.8 | F1 | 1 |
| | | | | | | | | | | | M2 | 1.6 | | |
| Example 6 | Ab-14 | 2.61 | Bb-5 | 0.39 | C2 | 1.8 | S1 | 38.97 | D2 | 5.5 | M1 | 4.8 | F1 | 1 |
| | | | | | | | | | | | M2 | 1.6 | | |
| Example 7 | Ac-4 | 2.61 | Bc-1 | 0.39 | C1 | 1.8 | S1 | 38.97 | D2 | 5.5 | M1 | 4.8 | F1 | 1 |
| | | | | | | | | | | | M2 | 1.6 | | |
| Example 8 | Ac-2 | 2.61 | Bc-3 | 0.39 | C1 | 1.8 | S1 | 38.97 | D2 | 5.5 | M1 | 4.8 | F1 | 1 |
| | | | | | | | | | | | M2 | 1.6 | | |
| Example 9 | Ac-3 | 2.61 | Bc-2 | 0.39 | C2 | 1.8 | S1 | 38.97 | D2 | 5.5 | M1 | 4.8 | F1 | 1 |
| | | | | | | | | | | | M2 | 1.6 | | |
| Example 10 | Ac-5 | 2.61 | Bc-1 | 0.39 | C1 | 1.8 | S5 | 38.97 | D2 | 5.5 | M1 | 4.8 | F1 | 1 |
| | | | | | | | | | | | M2 | 1.6 | | |
| Example 11 | Ac-6 | 2.61 | Bc-1 | 0.39 | C1 | 1.8 | S5 | 38.97 | D2 | 5.5 | M1 | 4.8 | F1 | 1 |
| | | | | | | | | | | | M2 | 1.6 | | |
| Example 12 | Af-1 | 2.61 | Bf-3 | 0.39 | C2 | 1.8 | S1 | 38.97 | D2 | 5.5 | M1 | 4.8 | F1 | 1 |
| | | | | | | | | | | | M2 | 1.6 | | |
| Example 13 | Af-3 | 2.61 | Bf-2 | 0.39 | C1 | 1.8 | S1 | 38.97 | D2 | 5.5 | M1 | 4.8 | F1 | 1 |
| | | | | | | | | | | | M2 | 1.6 | | |
| Example 14 | Af-4 | 2.61 | Bf-1 | 0.39 | C1 | 1.8 | S1 | 38.97 | D2 | 5.5 | M1 | 4.8 | F1 | 1 |
| | | | | | | | | | | | M2 | 1.6 | | |
| Example 15 | Af-6 | 2.61 | Bf-5 | 0.39 | C2 | 1.8 | S1 | 38.97 | D2 | 5.5 | M1 | 4.8 | F1 | 1 |
| | | | | | | | | | | | M2 | 1.6 | | |
| Example 16 | Af-8 | 2.61 | Bf-2 | 0.39 | C1 | 1.8 | S1 | 38.97 | D2 | 5.5 | M1 | 4.8 | F1 | 1 |
| | | | | | | | | | | | M2 | 1.6 | | |
| Example 17 | Ag-1 | 2.61 | Bg-1 | 0.39 | C2 | 1.8 | S1 | 38.97 | D2 | 5.5 | M1 | 4.8 | F1 | 1 |
| | | | | | | | | | | | M2 | 1.6 | | |
| Example 18 | Ag-2 | 2.61 | Bg-1 | 0.39 | C2 | 1.8 | S1 | 38.97 | D2 | 5.5 | M1 | 4.8 | F1 | 1 |
| | | | | | | | | | | | M2 | 1.6 | | |
| Example 19 | Ag-3 | 2.61 | Bg-2 | 0.39 | C1 | 1.8 | S1 | 38.97 | D2 | 5.5 | M1 | 4.8 | F1 | 1 |
| | | | | | | | | | | | M2 | 1.6 | | |

| | Ultraviolet | | | | Polymerization | | | | | |
|---|---|---|---|---|---|---|---|---|---|---|
| | absorber | | Surfactant | | inhibitor | | Antioxidant | | Solvent 2 | |
| | | Part | | Part | | Part | | Part | | Part |
| | | by | | by | | by | | by | | by |
| Name | Type | mass | Type | mass | Type | mass | Type | mass | Type | mass |
| Example 1 | UV1 | 1.6 | W1 | 0.025 | H1 | 0.003 | I1 | 0.002 | S1 | 41.7 |
| Example 2 | UV1 | 1.6 | W1 | 0.025 | H1 | 0.003 | I1 | 0.002 | S1 | 41.7 |
| Example 3 | UV1 | 1.6 | W1 | 0.025 | H1 | 0.003 | I1 | 0.002 | S1 | 41.7 |
| Example 4 | UV1 | 1.6 | W1 | 0.025 | H1 | 0.003 | I1 | 0.002 | S1 | 41.7 |
| Example 5 | UV1 | 1.6 | W1 | 0.025 | H1 | 0.003 | I1 | 0.002 | S1 | 41.7 |
| Example 6 | UV1 | 1.6 | W1 | 0.025 | H1 | 0.003 | I1 | 0.002 | S1 | 41.7 |
| Example 7 | UV1 | 1.6 | W1 | 0.025 | H1 | 0.003 | I1 | 0.002 | S1 | 41.7 |
| Example 8 | UV1 | 1.6 | W1 | 0.025 | H1 | 0.003 | I1 | 0.002 | S1 | 41.7 |
| Example 9 | UV1 | 1.6 | W1 | 0.025 | H1 | 0.003 | I1 | 0.002 | S1 | 41.7 |
| Example 10 | UV1 | 1.6 | W1 | 0.025 | H1 | 0.003 | I1 | 0.002 | S1 | 41.7 |
| Example 11 | UV1 | 1.6 | W1 | 0.025 | H1 | 0.003 | I1 | 0.002 | S1 | 41.7 |
| Example 12 | UV1 | 1.6 | W1 | 0.025 | H1 | 0.003 | I1 | 0.002 | S1 | 41.7 |
| Example 13 | UV1 | 1.6 | W1 | 0.025 | H1 | 0.003 | I1 | 0.002 | S1 | 41.7 |
| Example 14 | UV1 | 1.6 | Wl | 0.025 | H1 | 0.003 | I1 | 0.002 | S1 | 41.7 |
| Example 15 | UV1 | 1.6 | W1 | 0.025 | H1 | 0.003 | I1 | 0.002 | S1 | 41.7 |
| Example 16 | UV1 | 1.6 | W1 | 0.025 | H1 | 0.003 | I1 | 0.002 | S1 | 41.7 |
| Example 17 | UV1 | 1.6 | W1 | 0.025 | H1 | 0.003 | I1 | 0.002 | S1 | 41.7 |
| Example 18 | UV1 | 1.6 | W1 | 0.025 | H1 | 0.003 | I1 | 0.002 | S1 | 41.7 |
| Example 19 | UV1 | 1.6 | W1 | 0.025 | H1 | 0.003 | I1 | 0.002 | S1 | 41.7 |

TABLE 2

| | Dispersion liquid | | | | | | | | | | | | | |
|---|---|---|---|---|---|---|---|---|---|---|---|---|---|---|
| | | | Coloring agent | | | | | | | | | | | |
| | Pigment | | derivative | | Dispersant | | Solvent 1 | | Resin | | Monomer | | Initiator | |
| | | Part | | Part | | Part | | Part | | Part | | Part | | Part |
| | | by | | by | | by | | by | | by | | by | | by |
| Name | Compound | mass | Type | mass | Type | mass | Type | mass | Type | mass | Type | mass | Type | mass |
| Example 20 | Ag-4 | 2.61 | Bg-1 | 0.39 | C2 | 1.8 | S1 | 38.97 | D2 | 5.5 | M1 | 4.8 | F1 | 1 |
| | | | | | | | | | | | M2 | 1.6 | | |
| Example 21 | Ah-1 | 2.61 | Bh-1 | 0.39 | C2 | 1.8 | S1 | 38.97 | D2 | 5.5 | M1 | 4.8 | F1 | 1 |
| | | | | | | | | | | | M2 | 1.6 | | |
| Example 22 | Ah-2 | 2.61 | Bh-3 | 0.39 | C1 | 1.8 | S1 | 38.97 | D5 | 5.5 | M1 | 4.8 | F1 | 1 |
| | | | | | | | | | | | M2 | 1.6 | | |
| Example 23 | Ab-10 | 2.61 | Bb-9 | 0.39 | C1 | 1.8 | S1 | 38.97 | D1 | 5.5 | M1 | 6.4 | F1 | 1 |
| Example 24 | Ab-10 | 2.61 | Bb-10 | 0.39 | C2 | 1.8 | S1 | 38.97 | D3 | 5.5 | M1 | 4.8 | F1 | 1 |
| | | | | | | | | | | | M3 | 1.6 | | |
| Example 25 | Ab-10 | 2.61 | Bk-1 | 0.39 | C1 | 1.8 | S1 | 38.97 | D2 | 5.5 | M1 | 4.8 | F2 | 1 |
| | | | | | | | | | | | M3 | 1.6 | | |
| Example 26 | Ac-4 | 2.61 | Ba-1 | 0.39 | C2 | 1.8 | S5 | 38.97 | D2 | 5.5 | M1 | 4.8 | F3 | 1 |
| | | | | | | | | | | | M2 | 1.6 | | |
| Example 27 | Ac-6 | 2.61 | Bf-1 | 0.39 | C1 | 1.8 | S1 | 38.97 | D2 | 5.5 | M1 | 4.8 | F1 | 0.5 |
| | | | | | | | | | | | M2 | 1.6 | F3 | 0.5 |
| Example 28 | Ab-10 | 2.61 | Bb-3 | 0.39 | C3 | 1.8 | S1 | 38.97 | D4 | 5.5 | M1 | 4.8 | F1 | 1 |
| | | | | | | | S4 | | | | M2 | 1.6 | | |
| Example 29 | Ab-10 | 2.61 | Bb-3 | 0.39 | C4 | 1.8 | S1 | 38.97 | D2 | 5.5 | M1 | 4.8 | F1 | 1 |
| | | | | | | | S4 | | | | M2 | 1.6 | | |
| Example 30 | Ab-10 | 2.61 | Bb-8 | 0.39 | C7 | 1.8 | S1 | 38.97 | D2 | 5.5 | M1 | 4.8 | F1 | 1 |
| | | | | | | | | | | | M4 | 1.6 | | |
| Example 31 | Ab-10 | 2.61 | Bb-8 | 0.39 | C5 | 1.8 | S1 | 38.97 | D2 | 5.5 | M1 | 4.8 | F1 | 1 |
| | | | | | | | | | | | M2 | 1.6 | | |
| Example 31 | Ab-10 | 2.61 | Bb-8 | 0.39 | C6 | 1.8 | S1 | 38.97 | D2 | 5.5 | M1 | 4.8 | F1 | 1 |
| | | | | | | | | | | | M2 | 1.6 | | |
| Example 32 | Ab-10 | 2.61 | Bb-8 | 0.39 | C2 | 1.8 | S2 | 38.97 | D2 | 5.5 | M1 | 4.8 | F1 | 1 |
| | | | | | | | | | | | M2 | 1.6 | | |
| Example 33 | Ab-10 | 2.61 | Bb-8 | 0.39 | C2 | 1.8 | S3 | 38.97 | D2 | 5.5 | M1 | 4.8 | F1 | 1 |
| | | | | | | | | | | | M2 | 1.6 | | |
| Example 34 | Ab-10 | 2.61 | Bb-8 | 0.39 | C2 | 1.8 | S4 | 38.97 | D5 | 5.5 | M1 | 4.8 | F1 | 1 |
| | | | | | | | | | | | M2 | 1.6 | | |
| Example 35 | Ab-10 | 2.61 | Bb-8 | 0.39 | C2 | 1.8 | S1 | 30 | D2 | 5.5 | M1 | 4.8 | F1 | 1 |
| | | | | | | | S5 | 8.97 | | | M2 | 1.6 | | |
| Example 36 | Ab-10 | 2.61 | Bb-8 | 0.39 | C2 | 1.8 | S6 | 38.97 | D2 | 5.5 | M1 | 4.8 | F1 | 1 |
| | | | | | | | | | | | M2 | 1.6 | | |
| Example 37 | Ab-10 | 1.31 | Bb-8 | 0.39 | C2 | 1.8 | S1 | 38.97 | D2 | 5.5 | M1 | 4.8 | F1 | 1 |
| | Ab-12 | 1.3 | | | | | | | | | M2 | 1.6 | | |
| Example 38 | Ac-4 | 1.31 | Bc-1 | 0.39 | C2 | 1.8 | S1 | 38.97 | D2 | 5.5 | M1 | 4.8 | F1 | 1 |
| | Af-3 | 1.3 | | | | | | | | | M2 | 1.6 | | |

| | Ultraviolet | | | | Polymerization | | | | | |
|---|---|---|---|---|---|---|---|---|---|---|
| | absorber | | Surfactant | | inhibitor | | Antioxidant | | Solvent 2 | |
| | | Part | | Part | | Part | | Part | | Part |
| | | by | | by | | by | | by | | by |
| Name | Type | mass | Type | mass | Type | mass | Type | mass | Type | mass |
| Example 20 | UV1 | 1.6 | W1 | 0.025 | H1 | 0.003 | I1 | 0.002 | S1 | 41.7 |
| Example 21 | UV1 | 1.6 | W1 | 0.025 | H1 | 0.003 | I1 | 0.002 | S1 | 41.7 |
| Example 22 | UV1 | 1.6 | W1 | 0.025 | H1 | 0.003 | I1 | 0.002 | S1 | 41.7 |
| Example 23 | UV1 | 1.6 | W1 | 0.025 | H1 | 0.003 | I1 | 0.002 | S1 | 20 |
| | | | | | | | | | S3 | 21.7 |
| Example 24 | UV1 | 1.6 | W1 | 0.025 | H1 | 0.003 | I1 | 0.002 | S1 | 41.7 |
| Example 25 | UV2 | 1.6 | W1 | 0.025 | H1 | 0.003 | I1 | 0.002 | S1 | 40 |
| | | | | | | | | | S2 | 1.7 |
| Example 26 | UV1 | 0.8 | W1 | 0.025 | H1 | 0.003 | I1 | 0.002 | S1 | 41.7 |
| | UV2 | 0.8 | | | | | | | | |
| Example 27 | UV1 | 1.6 | W1 | 0.025 | H1 | 0.003 | I1 | 0.002 | S1 | 41.7 |
| Example 28 | UV1 | 1.6 | W1 | 0.025 | H1 | 0.003 | I1 | 0.002 | S1 | 20 |
| | | | | | | | | | S4 | 21.7 |
| Example 29 | UV1 | 1.6 | W1 | 0.025 | H1 | 0.003 | I1 | 0.002 | S1 | 20 |
| | | | | | | | | | S4 | 21.7 |
| Example 30 | UV1 | 1.6 | W1 | 0.025 | H1 | 0.003 | I1 | 0.002 | S1 | 20 |
| | | | | | | | | | S4 | 21.7 |
| Example 31 | UV1 | 1.6 | W1 | 0.025 | H1 | 0.003 | I1 | 0.002 | S1 | 20 |
| | | | | | | | | | | 21.7 |
| Example 31 | UV1 | 1.6 | W1 | 0.025 | H1 | 0.003 | I1 | 0.002 | S1 | 20 |
| | | | | | | | | | | 21.7 |
| Example 32 | UV1 | 1.6 | W1 | 0.025 | H1 | 0.003 | I1 | 0.002 | S1 | 41.7 |
| Example 33 | UV1 | 1.6 | W1 | 0.025 | H1 | 0.003 | I1 | 0.002 | S1 | 41.7 |
| Example 34 | UV1 | 1.6 | W1 | 0.025 | H1 | 0.003 | I1 | 0.002 | S1 | 41.7 |
| Example 35 | UV1 | 1.6 | W1 | 0.025 | H1 | 0.003 | I1 | 0.002 | S1 | 41.7 |
| Example 36 | UV1 | 1.6 | W1 | 0.025 | H1 | 0.003 | I1 | 0.002 | S1 | 41.7 |
| Example 37 | UV1 | 1.6 | W1 | 0.025 | H1 | 0.003 | I1 | 0.002 | S1 | 41.7 |
| Example 38 | UV1 | 1.6 | W1 | 0.025 | H1 | 0.003 | I1 | 0.002 | S1 | 41.7 |

TABLE 3

| | Dispersion liquid | | | | | | | | | | | | | |
|---|---|---|---|---|---|---|---|---|---|---|---|---|---|---|
| | | | Coloring agent | | | | | | | | | | | |
| | Pigment | | derivative | | Dispersant | | Solvent 1 | | Resin | | Monomer | | Initiator | |
| | | Part | | Part | | Part | | Part | | Part | | Part | | Part |
| | | by | | by | | by | | by | | by | | by | | by |
| Name | Compound | mass | Type | mass | Type | mass | Type | mass | Type | mass | Type | mass | Type | mass |
| Example 39 | Af-8 | 2 | Bf-2 | 0.39 | C2 | 1.8 | S1 | 38.97 | D2 | 5.5 | M1 | 4.8 | F1 | 1 |
| | Ah-1 | 0.61 | | | | | | | | | M2 | 1.6 | | |
| Example 40 | Ab-10 | 2.61 | Bo-1 | 0.39 | C2 | 1.8 | S1 | 38.97 | D2 | 5.5 | M1 | 4.8 | F1 | 1 |
| | | | | | | | | | | | M2 | 1.6 | | |
| Example 41 | Ab-10 | 1.31 | Bb-8 | 0.39 | C2 | 1.8 | S1 | 38.97 | D2 | 5.5 | M1 | 4.8 | F1 | 1 |
| | Ao-6 | 1.3 | | | | | | | | | M2 | 1.6 | | |
| Example 42 | Ab-10 | 2.56 | Bb-8 | 0.44 | C2 | 1.8 | S1 | 38.97 | D2 | 5.5 | M1 | 4.8 | F1 | 1 |
| | | | | | | | | | | | M2 | 1.6 | | |
| Example 43 | Ab-10 | 2.5 | Bb-8 | 0.5 | C2 | 1.8 | S1 | 38.97 | D2 | 5.5 | M1 | 4.8 | F1 | 1 |
| | | | | | | | | | | | M2 | 1.6 | | |
| Example 101 | Ao-1 | 2.61 | Bo-1 | 0.39 | C2 | 1.8 | S1 | 38.97 | D2 | 5.5 | M1 | 4.8 | F1 | 1 |
| | | | | | | | | | | | M2 | 1.6 | | |
| Example 102 | Ao-2 | 2.61 | Bo-2 | 0.39 | C2 | 1.8 | S1 | 38.97 | D2 | 5.5 | M1 | 4.8 | F1 | 1 |
| | | | | | | | | | | | M2 | 1.6 | | |
| Example 103 | Aq-1 | 2.61 | Bq-1 | 0.39 | C2 | 1.8 | S1 | 38.97 | D2 | 5.5 | M1 | 4.8 | F1 | 1 |
| | | | | | | | | | | | M2 | 1.6 | | |
| Comparative | Ab-10 | 2.30 | Bb-8 | 0.70 | C1 | 1.8 | S1 | 38.97 | D2 | 5.5 | M1 | 4.8 | F1 | 1 |
| Example 1 | | | | | | | | | | | M2 | 1.6 | | |
| Comparative | Ab-10 | 3 | — | — | C1 | 1.8 | S1 | 38.97 | D2 | 5.5 | M1 | 4.8 | F1 | 1 |
| Example 2 | | | | | | | | | | | M2 | 1.6 | | |
| Comparative | Ab-1 | 2.61 | b2 | 0.39 | C1 | 1.8 | S1 | 38.97 | D2 | 5.5 | M1 | 4.8 | F1 | 1 |
| Example 3 | | | | | | | | | | | M2 | 1.6 | | |

| | Ultraviolet | | | | Polymerization | | | | | |
|---|---|---|---|---|---|---|---|---|---|---|
| | absorber | | Surfactant | | inhibitor | | Antioxidant | | Solvent 2 | |
| | | Part | | Part | | Part | | Part | | Part |
| | | by | | by | | by | | by | | by |
| Name | Type | mass | Type | mass | Type | mass | Type | mass | Type | mass |
| Example 39 | UV1 | 1.6 | W1 | 0.025 | H1 | 0.003 | I1 | 0.002 | S1 | 41.7 |
| Example 40 | UV1 | 1.6 | W1 | 0.025 | H1 | 0.003 | I1 | 0.002 | S1 | 41.7 |
| Example 41 | UV1 | 1.6 | W1 | 0.025 | H1 | 0.003 | I1 | 0.002 | S1 | 41.7 |
| Example 42 | UV1 | 1.6 | W1 | 0.025 | H1 | 0.003 | I1 | 0.002 | S1 | 41.7 |
| Example 43 | UV1 | 1.6 | W1 | 0.025 | H1 | 0.003 | I1 | 0.002 | S1 | 41.7 |
| Example 101 | UV1 | 1.6 | W1 | 0.025 | H1 | 0.003 | I1 | 0.002 | S1 | 41.7 |
| Example 102 | UV1 | 1.6 | W1 | 0.025 | H1 | 0.003 | I1 | 0.002 | S1 | 41.7 |
| Example 103 | UV1 | 1.6 | W1 | 0.025 | H1 | 0.003 | I1 | 0.002 | S1 | 41.7 |
| Comparative | UV1 | 1.6 | W1 | 0.025 | H1 | 0.003 | I1 | 0.002 | S1 | 41.7 |
| Example 1 | | | | | | | | | | |
| Comparative | UV1 | 1.6 | W1 | 0.025 | H1 | 0.003 | I1 | 0.002 | S1 | 41.7 |
| Example 2 | | | | | | | | | | |
| Comparative | UV1 | 1.6 | W1 | 0.025 | H1 | 0.003 | I1 | 0.002 | S1 | 41.7 |
| Example 3 | | | | | | | | | | |

The raw materials described in the above tables are as follows.

(Pigment)

Aa-1, Ab-1, Ab-9, Ab-10, Ab-12, Ab-14, Ac-2, Ac-3, Ac-4, Ac-5, Ac-6, Af-1, Af-3, Af-4, Af-6, Af-8, Ag-1, Ag-2, Ag-3, Ag-4, Ah-1, Ah-2, Ao-1, Ao-2, Ao-6, Aq-1: compounds Aa-1, Ab-1, Ab-9, Ab-10, Ab-12, Ab-14, Ac-2, Ac-3, Ac-4, Ac-5, Ac-6, Af-1, Af-3, Af-4, Af-6, Af-8, Ag-1, Ag-2, Ag-3, Ag-4, Ah-1, Ah-2, Ao-1, Ao-2, Ao-6, and Aq-1 having the structure shown in the specific examples of the near-infrared absorbing pigment A described above

(Coloring Agent Derivative)

Ba-1, Bb-1, Bb-2, Bb-3, Bb-5, Bb-8, Bb-9, Bb-10, Bb-11, Bc-1, Bc-2, Bc-3, Bf-1, Bf-2, Bf-3, Bf-5, Bg-1, Bg-2, Bh-1, Bh-3, Bk-1, Bo-1, Bo-2, Bq-1: compounds Ba-1, Bb-1, Bb-2, Bb-3, Bb-5, Bb-8, Bb-9, Bb-10, Bb-11, Bc-1, Bc-2, Bc-3, Bf-1, Bf-2, Bf-3, Bf-5, Bg-1, Bg-2, Bh-1, Bh-3, Bk-1, Bo-1, Bo-2, and Bq-1 having the structure shown in the specific examples of the coloring agent derivative described above

b2: Compound Having the Following Structure

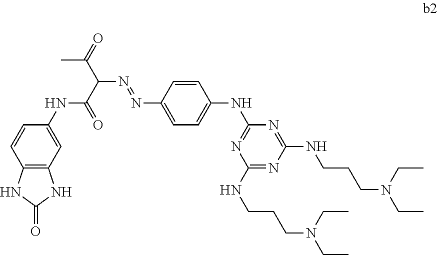 [SMILES: CCN(CC)CCCNc1nc(NCCCN(CC)CC)nc(Nc2ccc(/N=N/C(C(C)=O)C(=O)Nc3ccc4[nH]c(=O)[nH]c4c3)cc2)n1]

(Dispersant)

C1: resin having the following structure (a numerical value added to a main chain represents a molar ratio, and a numerical value added to a side chain represents the number of repeating units; Mw=38,000, acid value=99.1 mgKOH/g)

C2: resin having the following structure (a numerical value added to a main chain represents a molar ratio, and a numerical value added to a side chain represents the number of repeating units; Mw=21,000, acid value=36.0 mgKOH/g, amine value=47.0 mgKOH/g)

C3: block resin having the following structure (amine value=90 mgKOH/g, quaternary ammonium salt value=30 mgKOH/g, weight-average molecular weight=9800), a numerical value added to a main chain represents a molar ratio of a repeating unit.

C4: resin having the following structure (a numerical value added to a main chain represents a molar ratio, and a numerical value added to a side chain represents the number of repeating units; Mw=22,900, acid value=32.3 mgKOH/g, amine value=45.0 mgKOH/g)

C5: resin having the following structure (acid value=87.0 mgKOH/g, weight-average molecular weight=18000), a numerical value added to a main chain represents a molar ratio of a repeating unit and a numerical value added to a side chain represents the number of repeating units.

C6: resin having the following structure (acid value=85.0 mgKOH/g, weight-average molecular weight=22000), a numerical value added to a main chain represents a molar ratio of a repeating unit and a numerical value added to a side chain represents the number of repeating units.

C7: resin having the following structure (acid value=43 mgKOH/g, weight-average molecular weight=9000), a numerical value added to a side chain represents a molar ratio of a repeating unit.

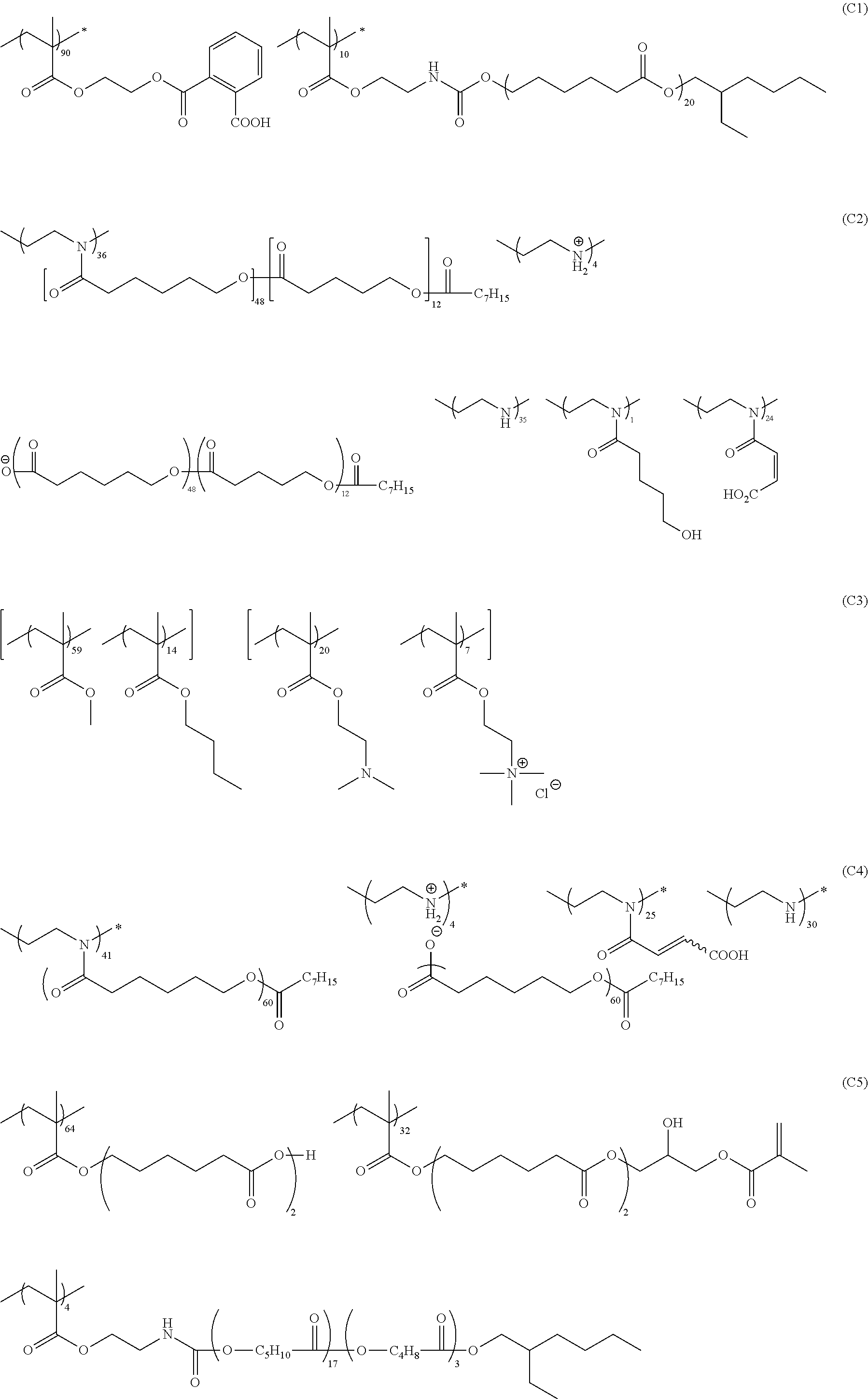

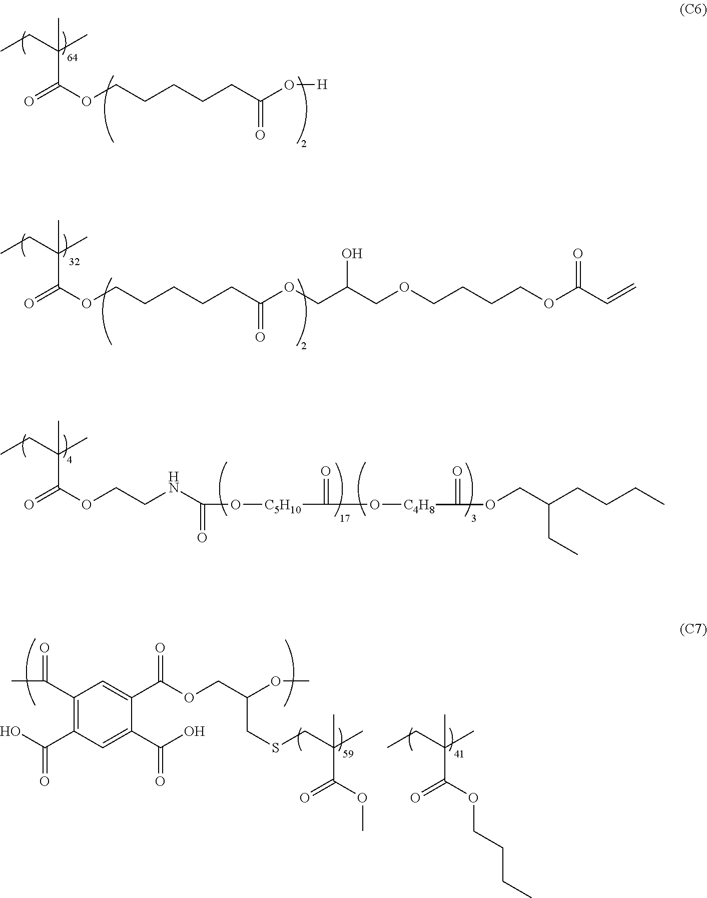

(Solvents 1 and 2)

S1: propylene glycol monomethyl ether acetate (PGMEA)

S2: cyclohexanone

S3: butyl acetate

S4: ethyl lactate (EL)

S5: propylene glycol monomethyl ether (PGME)

S6: cycloheptanone

(Resin)

D1: resin having the following structure (a numerical value added to a main chain represents a molar ratio; Mw=41,000, acid value=91.3 mgKOH/g)

D2: resin having the following structure (a numerical value added to a main chain represents a molar ratio; Mw=10,000, acid value=69.2 mgKOH/g)

D3: resin having the following structure (a numerical value added to a main chain represents a molar ratio; Mw=17,000, acid value=77 mgKOH/g)

D4: resin having the following structure (acid value=110 mgKOH/g, weight-average molecular weight=10000), a numerical value added to a main chain represents a molar ratio of a repeating unit.

D5: resin having the following structure (acid value=184 mgKOH/g, weight-average molecular weight=9700), a numerical value added to a main chain represents a molar ratio of a repeating unit.

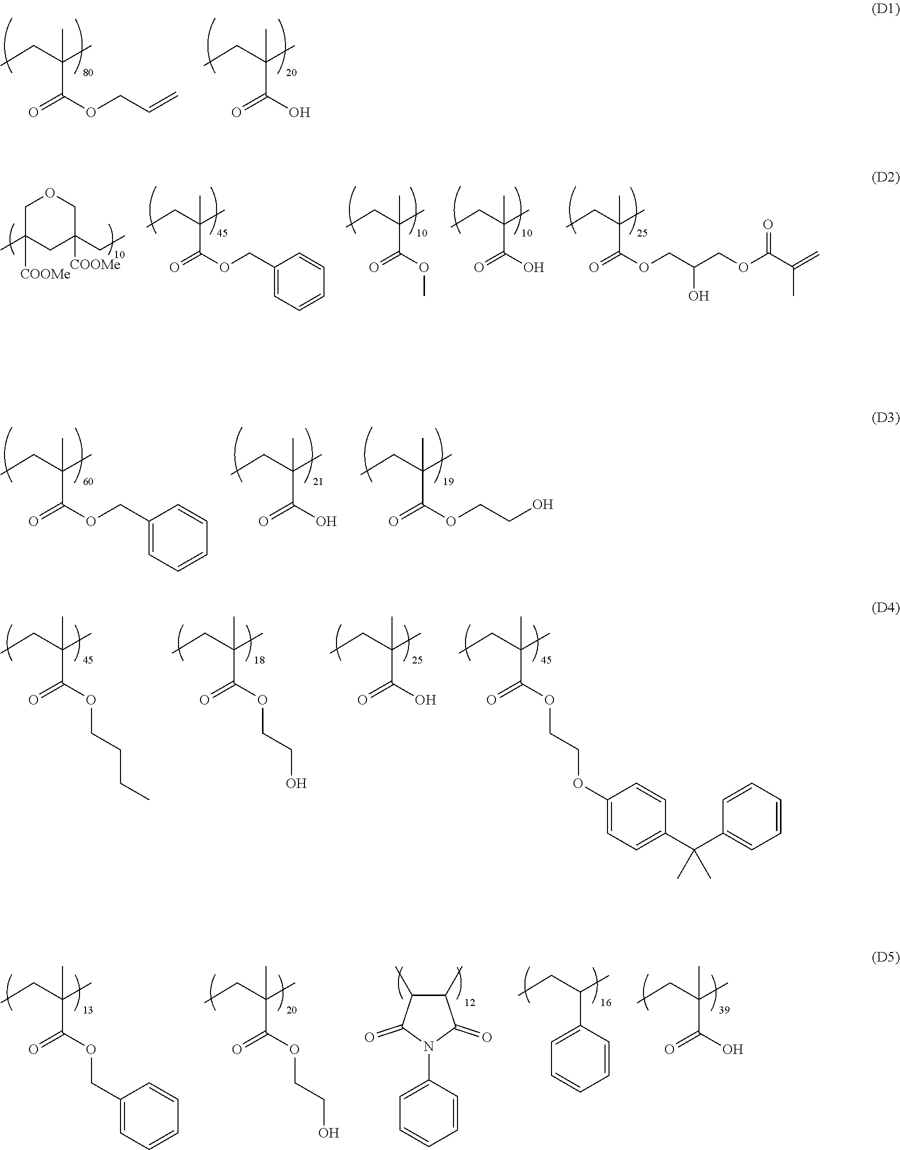

(Monomer)

M1: compound having the following structure

M2: mixture of compounds having the following structures (containing 55 to 63 mol % of a left compound)

M3: compound having the following structure

M4: mixture of compounds having the following structures (a molar ratio between a left compound and a right compound is 7:3)

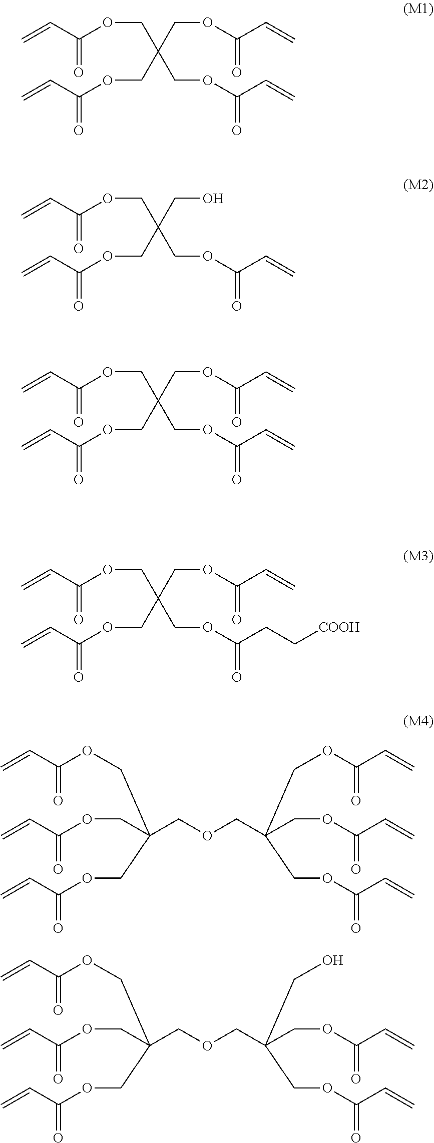

(Initiator)

F1 to F3: compounds having the following structures

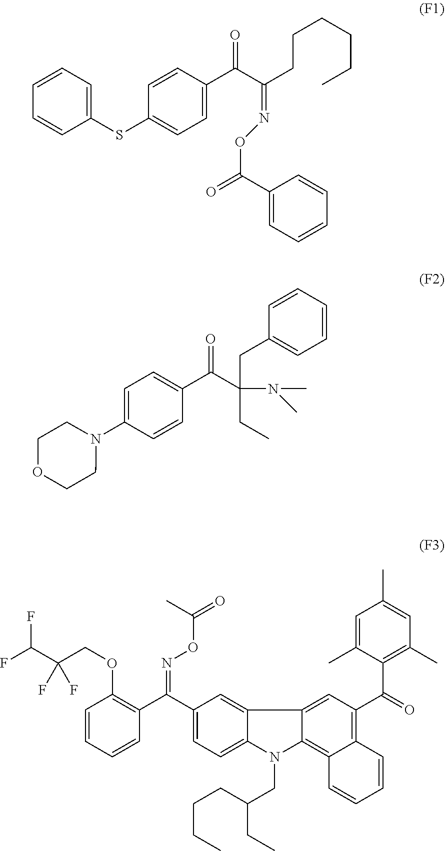 [SMILES: CCCCCC/C(=N/OC(=O)c1ccccc1)C(=O)c1ccc(Sc2ccccc2)cc1 ; CCC(Cc1ccccc1)(C(=O)c1ccc(N2CCOCC2)cc1)N(C)C ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

(Ultraviolet Absorber)

UV1: compound having the following structure

UV2: compound having the following structure

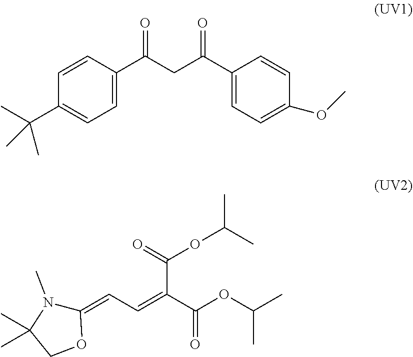

(Surfactant)

W1: compound having the following structure (Mw=14000, fluorine surfactant), “%” representing the proportion of a repeating unit is mass %.

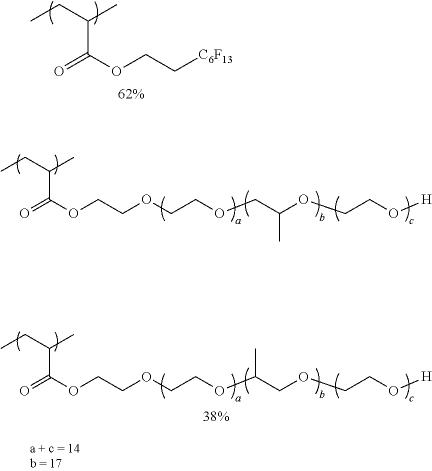

(Polymerization Inhibitor)

H1: p-methoxyphenol

(Antioxidant)

I1: ADK STAB AO-80 (manufactured by ADEKA Corporation)

<Evaluation of Dispersion Stability>

The viscosity of the near-infrared absorbing composition immediately after formation was measured. The near-infrared absorbing composition of which the viscosity was measured was stored in a constant-temperature tank at 45° C. for 72 hours, and then the viscosity thereof was measured. The viscosity was measured by adjusting the temperature of the near-infrared absorbing composition to 23° C. The thickening rate was obtained based on the following expression to evaluate dispersion stability.

Thickening rate (%)=((Viscosity of Near-infrared absorbing composition stored in constant-temperature tank at 45° C. for 72 hours/Viscosity of near-infrared absorbing composition immediately after formation)−1)*100

5: thickening rate was 5% or less.

4: thickening rate was more than 5% and 7% or less.

3: thickening rate was more than 7% and 10% or less.

2: thickening rate was more than 10% and 15% or less.

1: thickening rate was more than 15%.

<Evaluation of Defects>

Each of the near-infrared absorbing compositions immediately after formation was applied to an 8-inch (20.32 cm) silicon wafer by CLEAN TRACK ACT-8 (manufactured by Tokyo Electron Limited.), and then pre-baked at 100° C. for 120 seconds to form a film having a film thickness of 0.8 μm. The silicon wafer on which the film had been formed was inspected by a defect inspection apparatus ComPLUS3 manufactured by Applied Materials, Inc. to detect a defective portion, and the number of defects having a size of 1 μm or more in 2462 cm² was extracted.

5: 5 or less

4: more than 5 and 20 or less

3: more than 20 and 50 or less

2: more than 50 and 100 or less

1: more than 100

<Evaluation of Visible Transparency>

Each of the near-infrared absorbing compositions was applied to a glass substrate using a spin coater (manufactured by Mikasa Co., Ltd.) such that the thickness of a film after pre-baking was 0.8 μm. As a result, a coating film was formed. Next, the coating film was heated (pre-baked) using a hot plate at 100° C. for 120 seconds, the entire surface of the coating film was exposed using an i-ray stepper exposure device FPA-3000 i5+(manufactured by Canon Corporation) at an exposure dose of 1000 mJ/cm², and then was heated (post-baked) again using a hot plate at 200° C. for 300 seconds. As a result, a film was obtained. Regarding the obtained film, the absorbance of light in a wavelength range of 400 to 1300 nm was measured, a ratio A₁/A₂ of a maximum value A₁ of an absorbance in a wavelength range of 400 to 600 nm to an absorbance A₂ at an maximum absorption wavelength in a range of 700 to 1300 nm was calculated, and then the spectral performance was evaluated based on the following standard.

A: A₁/A₂ was 0.3 or less.

B: A₁/A₂ was more than 0.3.

<Evaluation of Heat Resistance>

A 5 cm×5 cm glass substrate was coated with the near-infrared absorbing composition using a spin coater so that the thickness of a film after drying was 0.6 μm, and pre-baking was performed at 100° C. for 120 seconds to obtain a film. The glass substrate on which this film had been formed was placed on a hot plate at 200° C. such that the substrate surface was in contact with the hot plate, and was heated for 1 hour. After that, using a colorimeter MCPD-1000 (manufactured by OTSUKA ELECTRONICS Co., Ltd.), the color difference (ΔE*ab value) of the film before and after heating was measured, and the heat resistance was evaluated according to the following judgement standard. As the ΔE*ab value is smaller, the heat resistance is better. The ΔE*ab value is a value acquired using the following color difference expression based on the CIE1976 (L*, a*, b*) space color system (The Color Science Handbook (1985), new edition, p. 266, edited by The Color Science Association of Japan).

ΔE*ab={(ΔL*)²+(Δa*)²+(Δb*)²}^{1/2}

[Evaluation Standard]

A: ΔE*ab value was less than 1.0.

B: ΔE*ab value was 1.0 or more and less than 3.0.

C: ΔE*ab value was 3.0 or more.

<Evaluation of Light Resistance>

A 5 cm×5 cm glass substrate was coated with the near-infrared absorbing composition using a spin coater so that the thickness of a film after drying was 0.6 μm, and pre-baking was performed at 100° C. for 120 seconds to obtain a film. A SiO₂ layer having a thickness of 100 nm was formed on this film by a chemical vapor deposition method. For the purpose of cutting off light of 380 nm or less, a sharp cut filter L38 manufactured by HOYA Corporation was placed on the obtained film, and the obtained film was irradiated with light of a xenon lamp at 100000 for 20 hours (equivalent to 2000000 lux×h). The color difference (ΔE*ab value) of the film before and after irradiation with xenon lamp was measured.

[Evaluation Standard]

A: ΔE*ab value was less than 5.0.

B: ΔE*ab value was 5.0 or more and less than 10.0.

C: ΔE*ab value was 10.0 or more.

TABLE 4

| | Evaluation result | | | | |
|---|---|---|---|---|---|
| | Dispersion | | Visible | Heat | Light |
| Name | Stability | Defects | transparency | resistance | resistance |
| Example 1 | 3 | 4 | B | B | B |
| Example 2 | 4 | 5 | A | A | A |
| Example 3 | 4 | 5 | A | A | A |
| Example 4 | 5 | 5 | A | A | A |
| Example 5 | 5 | 5 | A | A | A |
| Example 6 | 5 | 5 | A | A | A |
| Example 7 | 5 | 5 | B | A | A |
| Example 8 | 5 | 5 | B | A | A |
| Example 9 | 5 | 5 | B | A | A |
| Example 10 | 5 | 5 | A | A | A |
| Example 11 | 3 | 4 | A | B | B |
| Example 12 | 3 | 4 | B | B | B |
| Example 13 | 4 | 4 | A | A | A |
| Example 14 | 3 | 4 | A | A | A |
| Example 15 | 4 | 4 | A | A | A |
| Example 16 | 5 | 5 | A | A | A |
| Example 17 | 4 | 4 | B | A | A |
| Example 18 | 4 | 4 | A | A | A |
| Example 19 | 4 | 4 | B | A | A |
| Example 20 | 4 | 4 | B | B | B |
| Example 21 | 5 | 5 | B | B | A |
| Example 22 | 5 | 5 | A | A | A |
| Example 23 | 5 | 5 | A | A | A |
| Example 24 | 5 | 5 | A | A | A |
| Example 25 | 4 | 4 | A | A | A |

TABLE 5

| | Evaluation result | | | | |
|---|---|---|---|---|---|
| | Dispersion | | Visible | Heat | Light |
| Name | Stability | Defects | transparency | resistance | resistance |
| Example 26 | 4 | 4 | B | B | B |
| Example 27 | 3 | 4 | A | A | A |
| Example 28 | 5 | 5 | A | A | A |
| Example 29 | 5 | 5 | A | A | A |
| Example 30 | 5 | 5 | A | A | A |
| Example 31 | 5 | 5 | A | A | A |
| Example 32 | 5 | 5 | A | A | A |
| Example 33 | 5 | 5 | A | A | A |
| Example 34 | 5 | 5 | A | A | A |
| Example 35 | 5 | 5 | A | A | A |
| Example 36 | 5 | 5 | A | A | A |
| Example 37 | 5 | 5 | A | A | A |
| Example 38 | 4 | 4 | A | A | A |
| Example 39 | 5 | 5 | A | A | A |
| Example 40 | 3 | 4 | A | A | A |
| Example 41 | 3 | 4 | A | A | A |
| Example 42 | 4 | 4 | B | A | A |
| Example 43 | 4 | 4 | B | B | B |
| Example 101 | 4 | 5 | B | A | A |
| Example 102 | 4 | 5 | B | A | A |
| Example 103 | 4 | 5 | B | A | A |
| Comparative | 4 | 2 | B | C | C |
| Example 1 | | | | | |
| Comparative | 1 | 1 | B | A | A |
| Example 2 | | | | | |
| Comparative | 2 | 2 | B | B | B |
| Example 3 | | | | | |

As shown in the above tables, in the examples, it was possible to form a film having good dispersion stability, few defects, and excellent heat resistance and light resistance.

### EXPLANATION OF REFERENCES

110: solid-state imaging element
111: near-infrared cut filter
112: color filter
114: near-infrared transmitting filter
115: microlens
116: planarizing layer

What is claimed is:

1. A near-infrared absorbing composition comprising:
a near-infrared absorbing pigment having an oxocarbon skeleton;
a coloring agent derivative;
a resin; and
a solvent,
wherein the coloring agent derivative is a compound having a cation and an anion in a molecule, and
the near-infrared absorbing composition contains 0.5 to 25 parts by mass of the coloring agent derivative with respect to 100 parts by mass of the near-infrared absorbing pigment.

2. The near-infrared absorbing composition according to claim 1,
wherein the near-infrared absorbing pigment has a maximum absorption wavelength in a range of 700 to 1200 nm.

3. The near-infrared absorbing composition according to claim 1,
wherein an absolute value of a difference between an amount of the near-infrared absorbing pigment dissolved in 100 g of propylene glycol methyl ether acetate at 25° C. and an amount of the coloring agent derivative dissolved in 100 g of propylene glycol methyl ether acetate at 25° C. is 10 g or less.

4. The near-infrared absorbing composition according to claim 1,
wherein the near-infrared absorbing pigment is at least one selected from a compound represented by Formula (SQ1) or a compound represented by Formula (CR1), 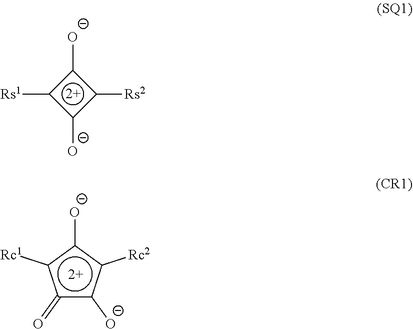
in Formula (SQ1), Rs¹ and Rs² each independently represent an organic group, and
in Formula (CR1), Rc¹ and Rc² each independently represent an organic group.

5. The near-infrared absorbing composition according to claim 4,
wherein Rs¹ and Rs² in Formula (SQ1) each independently represent an aryl group, a heteroaryl group, or a group represented by Formula (R1), and
Rc¹ and Rc² in Formula (CR1) each independently represent an aryl group, a heteroaryl group, or a group represented by Formula (R1), 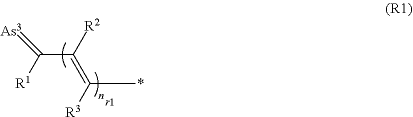
in Formula (R1), R¹ to R³ each independently represent a hydrogen atom or a substituent, As³ represents a heteroaryl group, nᵣ₁ represents an integer of 0 or more, R¹ and R² may be bonded to each other to form a ring, R¹ and As³ may be bonded to each other to form a ring, R² and R³ may be bonded to each other to form a ring, in which in a case where nᵣ₁ is 2 or more, a plurality of R²'s and R³'s each may be the same or different from each other, and * represents a bonding hand.

6. The near-infrared absorbing composition according to claim 4,
wherein at least one of Rs¹ or Rs² in Formula (SQ1) is a group represented by Formula (1), and
at least one of Rc¹ or Rc² in Formula (CR1) is a group represented by Formula (1), 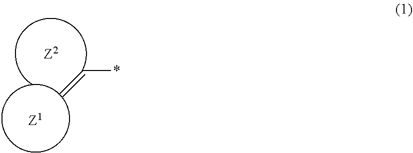 [SMILES: *C=C]
in Formula (1), a ring Z¹ represents an aromatic heterocyclic ring or a fused ring including an aromatic heterocyclic ring, which may have one or a plurality of substituents,
a ring Z² represents a 4-membered to 9-membered hydrocarbon ring or heterocyclic ring, which may have one or a plurality of substituents,
in a case where the ring Z¹ and the ring Z² have a plurality of substituents, the plurality of substituents may be the same or different from each other, and
* represents a bonding hand.

7. The near-infrared absorbing composition according to claim 4,
wherein at least one of Rs¹ or Rs² in Formula (SQ1) is a group represented by Formula (10), and
at least one of Rc¹ or Rc² of Formula (CR1) is a group represented by Formula (10), 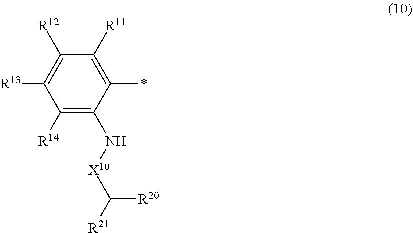
in Formula (10), R¹¹ to R¹⁴ each independently represent a hydrogen atom or a substituent, and two adjacent groups of R¹¹ to R¹⁴ may be bonded to each other to form a ring,
R²⁰ represents an aryl group or a heteroaryl group,
R²¹ represents a substituent, and
X¹⁰ represents CO or SO₂.

8. The near-infrared absorbing composition according to claim 4,
wherein at least one of Rs¹ or Rs² in Formula (SQ1) represents a group represented by Formula (20), and
at least one of Rc¹ or Rc² in Formula (CR1) represents a group represented by Formula (20), 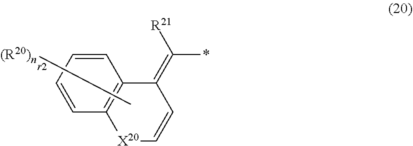
in Formula (20), R²⁰ and R²¹ each independently represent a hydrogen atom or a substituent, and R²⁰ and R²¹ may be bonded to each other to form a ring,
X²⁰ represents an oxygen atom, a sulfur atom, NR²², a selenium atom, or a tellurium atom, in which R²² represents a hydrogen atom or a substituent, and in a case where X²⁰ is NR²², R²² and R²⁰ may be bonded to each other to form a ring,
nᵣ₂ represents an integer of 0 to 5,
in a case where nᵣ₂ is 2 or more, a plurality of R²⁰'s may be the same or different from each other, and two R²⁰'s of the plurality of R²⁰'s may be bonded to each other to form a ring, and
* represents a bonding hand.

9. The near-infrared absorbing composition according to claim 4,
wherein at least one of Rs¹ or Rs² in Formula (SQ1) represents a group represented by Formula (30) or Formula (40), and
at least one of Rc¹ or Rc² in Formula (CR1) represents a group represented by Formula (30) or Formula (40), 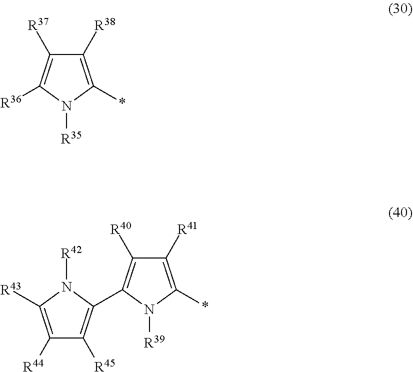
in Formula (30), R³⁵ to R³⁸ each independently represent a hydrogen atom or a substituent, R³⁵ and R³⁶, R³⁶ and R³⁷, or R³⁷ and R³⁸ may be bonded to each other to form a ring, and * represents a bonding hand; and
in Formula (40), R³⁹ to R⁴⁵ each independently represent a hydrogen atom or a substituent, R³⁹ and R⁴⁵, R⁴⁰ and R⁴¹, R⁴⁰ and R⁴², R⁴² and R⁴³, R⁴³ and R⁴⁴, or R⁴⁴ and R⁴⁵ may be bonded to each other to form a ring, and * represents a bonding hand.

10. The near-infrared absorbing composition according to claim 1,
wherein the near-infrared absorbing pigment is a compound represented by Formula (SQ2) or Formula (SQ3), 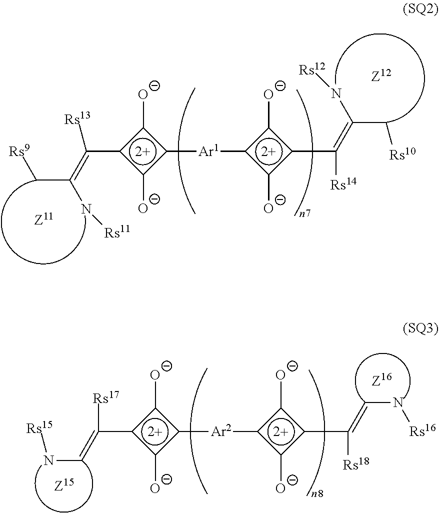
in Formula (SQ2), a ring Z¹¹ and a ring Z¹² each independently represent a polycyclic aromatic ring having a nitrogen-containing heterocyclic ring, which may have one or a plurality of substituents,
in a case where the ring Z¹¹ and the ring Z¹² have a plurality of substituents, the plurality of substituents may be the same or different from each other,
Rs⁹ to Rs¹⁴ each independently represent a hydrogen atom or a substituent,
Ar¹ represents a group represented by any one of Formulae (Ar-1) to (Ar-4),
n7 represents an integer of 0 to 2, and
Rs⁹ and Rs¹³, or Rs¹⁰ and Rs¹⁴ may be bonded to each other to form a ring; and
in Formula (SQ3), a ring Z¹⁵ and a ring Z¹⁶ each independently represent a polycyclic aromatic ring having a nitrogen-containing heterocyclic ring, which may have one or a plurality of substituents,
in a case where the ring Z¹⁵ and the ring Z¹⁶ have a plurality of substituents, the plurality of substituents may be the same or different from each other,
Rs¹⁵ to Rs¹⁸ each independently represent a hydrogen atom or a substituent,
Ar² represents a group represented by any one of Formulae (Ar-1) to (Ar-4),
n8 represents an integer of 0 to 2, and
Rs¹⁵ and Rs¹⁷, or Rs¹⁶ and Rs¹⁸ may be bonded to each other to form a ring, 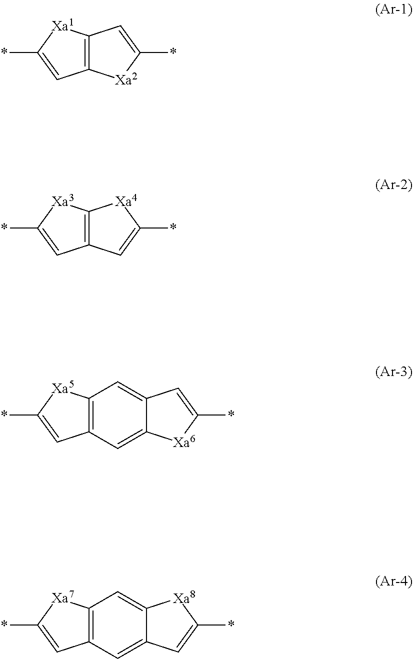
in the formulae, Xa¹ to Xa⁸ each independently represent a sulfur atom, an oxygen atom, or NRx^{a}, in which Rx^{a} represents a hydrogen atom or a substituent, and * represents a bonding hand.

11. The near-infrared absorbing composition according to claim 1,
wherein the near-infrared absorbing pigment is a compound represented by Formula (SQ10), 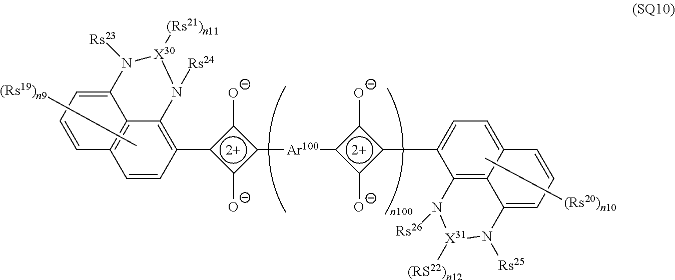
in Formula (SQ10), Rs¹⁹ and Rs²⁰ each independently represent a substituent,
Rs²¹ to Rs²⁶ each independently represent a hydrogen atom or a substituent,
X³⁰ and X³¹ each independently represent a carbon atom, a boron atom, or C(═O),
n11 is 2 in a case where X³⁰ is a carbon atom, n11 is 1 in a case where X³⁰ is a boron atom, and n11 is 0 in a case where X³⁰ is C(═O),
n12 is 2 in a case where X³¹ is a carbon atom, n12 is 1 in a case where X³¹ is a boron atom, and n12 is 0 in a case where X³¹ is C(═O),
n9 and n10 each independently represent an integer of 0 to 5,
in a case where n9 is 2 or more, a plurality of Rs¹⁹'s may be the same or different from each other, and two Rs¹⁹'s of the plurality of Rs¹⁹'s may be bonded to each other to form a ring,
in a case where n10 is 2 or more, a plurality of Rs²⁰'s may be the same or different from each other, and two Rs²⁰'s of the plurality of Rs²⁰'s may be bonded to each other to form a ring,
in a case where n11 is 2, two Rs²¹'s may be the same or different from each other and may be bonded to each other to form a ring,
in a case where n12 is 2, two Rs²²'s may be the same or different from each other and may be bonded to each other to form a ring,
Ar¹⁰⁰ represents a group represented by any one of Formulae (Ar-1) to (Ar-4), and
n100 represents an integer of 0 to 2, 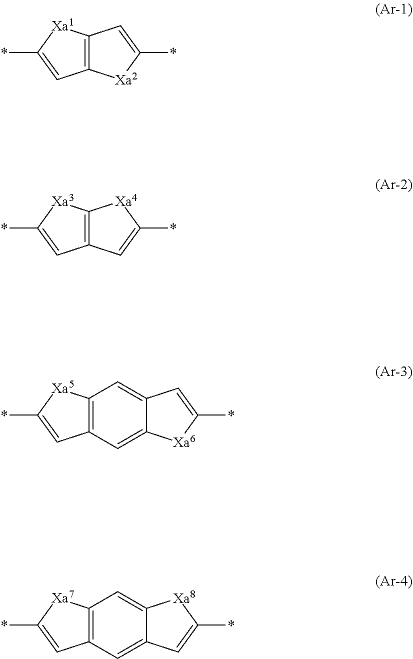
in the formulae, Xa¹ to Xa⁸ each independently represent a sulfur atom, an oxygen atom, or NRx^{a}, in which Rx^{a} represents a hydrogen atom or a substituent, and * represents a bonding hand.

12. The near-infrared absorbing composition according to claim 1,
wherein the near-infrared absorbing pigment is a compound represented by Formula (SQ20), 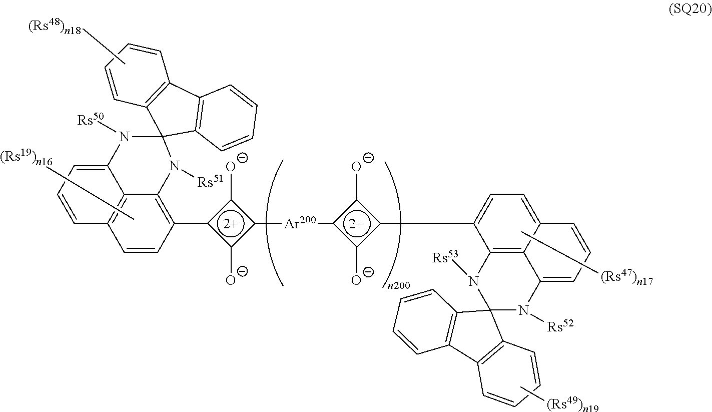
in Formula (SQ20), Rs⁴⁶ and Rs⁴⁹ each independently represent a substituent,
Rs⁵⁰ to Rs⁵³ each independently represent a hydrogen atom or a substituent,
n16 and n17 each independently represent an integer of 0 to 5,
n18 and n19 each independently represent an integer of 0 to 6,
in a case where n16 is 2 or more, a plurality of Rs⁴⁶'s may be the same or different from each other, and two Rs⁴⁶'s of the plurality of Rs⁴⁶'s may be bonded to each other to form a ring,
in a case where n17 is 2 or more, a plurality of Rs⁴⁷'s may be the same or different from each other, and two Rs⁴⁷'s of the plurality of Rs⁴⁷'s may be bonded to each other to form a ring,
in a case where n18 is 2 or more, a plurality of Rs⁴⁸'s may be the same or different from each other, and two Rs⁴⁸'s of the plurality of Rs⁴⁸'s may be bonded to each other to form a ring,
in a case where n19 is 2 or more, a plurality of Rs⁴⁹'s may be the same or different from each other, and two Rs⁴⁹'s of the plurality of Rs⁴⁹'s may be bonded to each other to form a ring,
Ar²⁰⁰ represents a group represented by any one of Formulae (Ar-1) to (Ar-4), and
n200 represents an integer of 0 to 2, 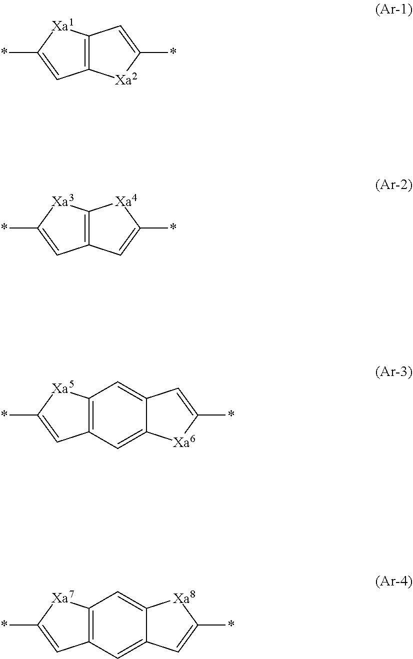
in the formulae, Xa¹ to Xa⁸ each independently represent a sulfur atom, an oxygen atom, or NRx^{a}, in which Rx^{a} represents a hydrogen atom or a substituent, and * represents a bonding hand.

13. The near-infrared absorbing composition according to claim 1,
wherein the near-infrared absorbing pigment is a compound represented by Formula (SQ30), 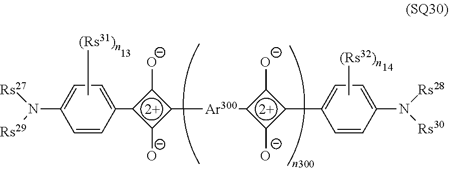
in Formula (SQ30), Rs²⁷ to Rs³⁰ each independently represent a hydrogen atom or a substituent,
Rs³¹ and Rs³² each independently represent a substituent or a group represented by Formula (100),
Rs²⁷ and Rs²⁹, Rs²⁷ and Rs³¹, Rs²⁹ and Rs³¹, Rs²⁸ and Rs³⁰, Rs²⁸ and Rs³², or Rs³⁰ and Rs³² may be bonded to each other to form a ring,
Rs³¹ and Rs³² may be linked through a single bond or a linking group,
n13 and n14 each independently represent an integer of 0 to 4,
in a case where n13 is 2 or more, a plurality of Rs³¹'s may be the same or different from each other, and two Rs³¹'s of the plurality of Rs³¹'s may be bonded to each other to form a ring,
in a case where n14 is 2 or more, a plurality of Rs³²'s may be the same or different from each other, and two Rs³²'s of the plurality of Rs³²'s may be bonded to each other to form a ring,
Ar³⁰⁰ represents a group represented by any one of Formulae (Ar-1) to (Ar-4), and
n300 represents an integer of 0 to 2; 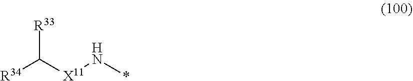
in Formula (100), R³³ represents an aryl group or a heteroaryl group, R³⁴ represents a hydrogen atom or a substituent, and X¹¹ represents CO or SO₂; and 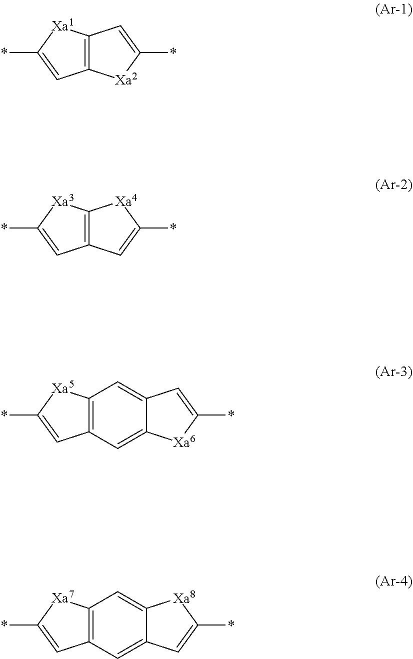
in the formulae, Xa¹ to Xa⁸ each independently represent a sulfur atom, an oxygen atom, or NRx^{a}, in which Rx^{a} represents a hydrogen atom or a substituent, and * represents a bonding hand.

14. The near-infrared absorbing composition according to claim 13,
wherein the compound represented by Formula (SQ30) is a compound represented by Formula (SQ30-1), 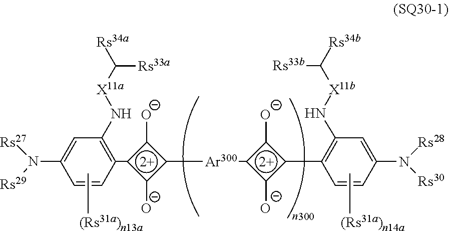
in Formula (SQ30-1), Rs²⁷ to Rs³⁰ each independently represent a hydrogen atom or a substituent,
Rs^{31a} and Rs^{32a} each independently represent a substituent,
Rs^{33a} and Rs^{33b} each independently represent an aryl group or a heteroaryl group,
Rs^{34a} and Rs^{34b} each independently represent a hydrogen atom or a substituent,
Rs²⁷ and Rs²⁹, Rs²⁷ and Rs^{31a}, Rs²⁹ and Rs^{31a}, Rs²⁷ and Rs^{34a}, Rs²⁹ and Rs^{34a}, Rs²⁸ and Rs³⁰, Rs²⁸ and Rs^{32a}, Rs³⁰ and Rs^{32a}, Rs²⁸ and Rs^{34b}, or Rs³⁰ and Rs^{34b} may be bonded to each other to form a ring,
Rs^{34a} and Rs^{34b} may be linked through a single bond or a linking group,
X^{11a} and X^{11b} each independently represent CO or SO₂,
n13a and n14a each independently represent an integer of 0 to 3,
in a case where n13a is 2 or more, a plurality of Rs^{31a}'s may be the same or different from each other, and two Rs^{31a}'s of the plurality of Rs^{31a}'s may be bonded to each other to form a ring,
in a case where n14a is 2 or more, a plurality of Rs^{32a}'s may be the same or different from each other, and two Rs^{32a}, s of the plurality of Rs^{32a}, s may be bonded to each other to form a ring,
Ar³⁰⁰ represents a group represented by any one of Formulae (Ar-1) to (Ar-4), and
n300 represents an integer of 0 to 2.

15. The near-infrared absorbing composition according to claim 1,
wherein the coloring agent derivative is a compound having at least one group selected from an acid group, a basic group, and a hydrogen-bonding group.

16. The near-infrared absorbing composition according to claim 1,
wherein the coloring agent derivative has at least one group selected from a sulfo group, a carboxyl group, a phosphoric acid group, a boronic acid group, a sulfonimide group, a sulfonamide group, an amino group, a pyridinyl group, salts of these groups, and a desalted structure of these salts.

17. The near-infrared absorbing composition according to claim 1,
wherein the near-infrared absorbing pigment and the coloring agent derivative have the same π-conjugated plane.

18. The near-infrared absorbing composition according to claim 1,
wherein the near-infrared absorbing pigment and the coloring agent derivative respectively have a π-conjugated plane including a partial structure represented by Formula (SQ-a), or respectively have a π-conjugated plane including a partial structure represented by Formula (CR-a), 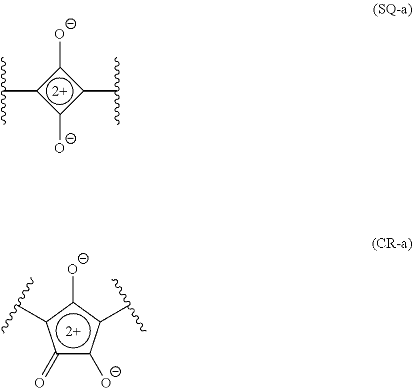
in the formulae, a wavy line represents a bonding hand.

19. The near-infrared absorbing composition according to claim 1, further comprising:
a polymerizable compound; and
a photopolymerization initiator.

20. The near-infrared absorbing composition according to claim 1,
wherein the resin includes a resin having an acid group.

21. A method for producing a dispersion liquid, comprising:
dispersing a near-infrared absorbing pigment having an oxocarbon skeleton in a presence of a coloring agent derivative, a resin, and a solvent,
wherein the coloring agent derivative is a compound having a cation and an anion in a molecule, and
0.5 to 25 parts by mass of the coloring agent derivative is used with respect to 100 parts by mass of the near-infrared absorbing pigment.

22. A film formed by using the near-infrared absorbing composition according to claim 1.

23. An optical filter comprising:
the film according to claim 22.

24. The optical filter according to claim 23,
wherein the optical filter is a near-infrared cut filter or a near-infrared transmitting filter.

25. A method for forming a pattern, comprising:
forming a composition layer on a support using the near-infrared absorbing composition according to claim 1; and
forming a pattern on the composition layer by a photolithography method or a dry etching method.

26. A laminate comprising:
the film according to claim 22; and
a color filter including a chromatic colorant.

27. A solid-state imaging element comprising:
the film according to claim 22.

28. An image display device comprising:
the film according to claim 22.

29. An infrared sensor comprising:
the film according to claim 22.
